(19) United States
(12) Patent Application Publication
(10) Pub. No.: US 2017/0139253 A1
(43) Pub. Date: May 18, 2017

(54) DISPLAY DEVICE, INPUT/OUTPUT DEVICE, AND DATA PROCESSING DEVICE

(71) Applicant: Semiconductor Energy Laboratory Co., Ltd., Atsugi-shi (JP)

(72) Inventors: Yoshiharu HIRAKATA, Tochigi (JP); Shunpei YAMAZAKI, Tokyo (JP)

(21) Appl. No.: 15/345,819

(22) Filed: Nov. 8, 2016

(30) Foreign Application Priority Data
Nov. 13, 2015 (JP) 2015-223025

(51) Int. Cl. G02F 1/1333; H01L 27/32; G06F 3/041; G02F 1/1362; G02F 1/1368; G06F 3/044; G02F 1/1335; H01L 27/12

(52) U.S. Cl. CPC G02F 1/13338; G02F 1/133553; H01L 27/323; H01L 27/3232; H01L 27/3267; H01L 27/3262; H01L 27/1214; H01L 27/1248; H01L 27/3258; G02F 1/1336; G02F 1/136286; G02F 1/136227; G02F 1/1368; G02F 1/133504; G02F 1/133528; G02F 1/133512; G06F 3/044; G06F 3/0412; G02F 2001/133541; G06F 2203/04103

(57) ABSTRACT

A signal line, a pixel connected to the signal line, a first conductive film connected to the pixel, a second conductive film including a region overlapping with the first conductive film, and a first insulating film including a region sandwiched between the first conductive film and the second conductive film and a second opening in the sandwiched region are included. The pixel includes a pixel circuit connected to the signal line, a third conductive film connected to the pixel circuit, a fourth conductive film including a region overlapping with the third conductive film, a second insulating film including a region sandwiched between the fourth conductive film and the third conductive film and an opening in the sandwiched region, a first display element electrically connected to the fourth conductive film, and a second display element connected to the pixel circuit.

### TECHNICAL FIELD

One embodiment of the present invention relates to a display device, an input/output device, a data processing device, or a semiconductor device.

Note that one embodiment of the present invention is not limited to the above technical field. The technical field of one embodiment of the invention disclosed in this specification and the like relates to an object, a method, or a manufacturing method. Furthermore, one embodiment of the present invention relates to a process, a machine, manufacture, or a composition of matter. Specifically, examples of the technical field of one embodiment of the present invention disclosed in this specification include a semiconductor device, a display device, a light-emitting device, a power storage device, a memory device, a method for driving any of them, and a method for manufacturing any of them.

### BACKGROUND ART

A liquid crystal display device in which a light-condensing means and a pixel electrode are provided on the same surface side of a substrate and a region transmitting visible light in the pixel electrode is provided to overlap with an optical axis of the light-condensing means, and a liquid crystal display device which includes an anisotropic light-condensing means having a condensing direction X and a non-condensing direction Y that is along a longitudinal direction of a region transmitting visible light in the pixel electrode are known (Patent Document 1).

### REFERENCE

### Patent Document

[Patent Document 1] Japanese Published Patent Application No. 2011-191750

### DISCLOSURE OF INVENTION

An object of one embodiment of the present invention is to provide a novel display device that is highly convenient or reliable. Another object is to provide a novel input/output device that is highly convenient or reliable. Another object of one embodiment of the present invention is to provide a novel data processing device that is highly convenient or reliable. Another object is to provide a novel display device, a novel input/output device, a novel data processing device, or a novel semiconductor device.

Note that the descriptions of these objects do not disturb the existence of other objects. In one embodiment of the present invention, there is no need to achieve all the objects. Other objects will be apparent from and can be derived from the description of the specification, the drawings, the claims, and the like.

(1) One embodiment of the present invention is a display device including a signal line, a pixel, a first conductive film, a second conductive film, and a first insulating film.

The pixel is electrically connected to the signal line, the first conductive film is electrically connected to the pixel, and the second conductive film includes a region overlapping with the first conductive film.

The first insulating film includes a region sandwiched between the first conductive film and the second conductive film, and the first insulating film includes a second opening in aregion sandwiched between the first conductive film and the second conductive film.

The second conductive film is electrically connected to the first conductive film through the second opening.

The pixel includes a pixel circuit, a third conductive film, a fourth conductive film, a second insulating film, a first display element, and a second display element.

The pixel circuit is electrically connected to the signal line, the third conductive film is electrically connected to the pixel circuit, and the fourth conductive film includes a region overlapping with the third conductive film.

The second insulating film includes a region sandwiched between the third conductive film and the fourth conductive film, and the second insulating film includes an opening in a region sandwiched between the fourth conductive film and the third conductive film.

The third conductive film is electrically connected to the fourth conductive film through the opening.

The first display element is electrically connected to the fourth conductive film, and the second display element is electrically connected to the pixel circuit.

(2) One embodiment of the present invention is the above-described display device further including a first transistor and a second transistor.

The first transistor includes a region overlapping with the first insulating film, and the first transistor is electrically connected to the first conductive film.

The second transistor includes a region overlapping with the first insulating film, and the second transistor is electrically connected to the second conductive film.

The first transistor includes a first semiconductor film, the second transistor includes a second semiconductor film, and the second semiconductor film is different from the first semiconductor film.

Thus, the first display element and the second display element which performs display using a method different from that of the first display element can be driven using the first transistor and the second transistor which is formed in a process different from that of the first transistor, for example. Consequently, a novel display device that is highly convenient or reliable can be provided.

(3) One embodiment of the present invention is the display device, in which the second transistor includes a region overlapping with the first transistor.

Accordingly, the display device can have a reduced outward form while enabling the driving of the first display element and the second display element which performs display using a method different from that of the first display element. Consequently, a novel display device that is highly convenient or reliable can be provided.

(4) One embodiment of the present invention is the above-described display device further including a plurality of pixels, another plurality of pixels, and a scan line.

The plurality of pixels include the pixel and are provided in a row direction.

The another plurality of pixels include the pixel and are provided in a column direction that intersects the row direction.

The scan line is electrically connected to the plurality of pixels, and the another plurality of pixels are electrically connected to the signal line.

(5) One embodiment of the present invention is the above-described display device further including a driver circuit.

The driver circuit is electrically connected to the scan line, and the driver circuit is configured to supply a selection signal.

(6) One embodiment of the present invention is the above-described display device further including a driver circuit.

The driver circuit is electrically connected to the signal line, and the driver circuit is configured to supply an image signal.

(7) One embodiment of the present invention is the above-described display device, in which the driver circuit includes a transistor and the transistor includes silicon in a semiconductor film.

Thus, the pixel circuit can be driven using the driver circuit including the transistor which is formed in a process different from that of the transistor included in the pixel circuit, for example. Consequently, a novel display device that is highly convenient or reliable can be provided.

(8) One embodiment of the present invention is the above-described display device, in which the second display element is provided so that display using the second display element can be seen from part of a region from which display using the first display element can be seen.

Thus, the display using the second display element can be seen from part of the region from which the display using the first display element can be seen. Alternatively, a user can see the display without changing the attitude or the like of the display device. Thus, a novel display device that is highly convenient or reliable can be provided.

(9) One embodiment of the present invention is the above-described display device, in which the second display element is configured to perform display in a region surrounded by a region where the first display element performs display.

(10) One embodiment of the present invention is the above-described display device, in which the second display element is configured to emit light toward the second insulating film and the first insulating film.

The first display element includes a reflective film and is configured to control the intensity of reflected light.

The reflective film is configured to reflect incident light, and the reflective film has a shape including a region that does not block light emitted from the second display element.

(11) One embodiment of the present invention is an input/output device including the above-described display device and an input portion.

The input portion includes a region overlapping with the display device, and the input portion is configured to sense an object that comes in the vicinity of the region overlapping with the display device.

The input portion includes a control line, a signal line, and a sensing element.

The control line extends in a row direction, and the signal line extends in a column direction that intersects the row direction.

The sensing element has a light-transmitting property. The sensing element includes an electrode electrically connected to the control line and an electrode electrically connected to the signal line.

The electrode electrically connected to the signal line is provided so that an electric field part of which is blocked by the object that comes in the vicinity of the region overlapping with the display device is generated between the electrode electrically connected to the signal line and the electrode electrically connected to the control line.

One embodiment of the present invention includes a sensing element that has a light-transmitting property in a region overlapping with a pixel. Thus, an object that comes in the vicinity of a region overlapping with a display panel can be sensed. As a result, a novel input/output device that is highly convenient or reliable can be provided.

(12) One embodiment of the present invention is the above-described input/output device, in which the electrode electrically connected to the control line includes a light-transmitting conductive film including a region overlapping with the pixel, and the electrode electrically connected to the signal line includes a light-transmitting conductive film including a region overlapping with the pixel.

Since the input/output device of one embodiment of the present invention includes the control line including the light-transmitting conductive film in the region overlapping with the pixel and the signal line including the light-transmitting conductive film in the region overlapping with the pixel, an object that comes in the vicinity of the region overlapping with the display device can be sensed without disturbing display of the display device. As a result, a novel input/output device that is highly convenient or reliable can be provided.

(13) One embodiment of the present invention is the above-described input/output device, in which the electrode electrically connected to the control line includes a conductive film provided with an opening including a region overlapping with the pixel, and the electrode electrically connected to the signal line includes a conductive film provided with an opening including a region overlapping with the pixel.

(14) One embodiment of the present invention is the above-described input/output device, in which the first display element includes a first electrode and a second electrode, the first electrode is electrically connected to the fourth conductive film, and a gap between the electrode electrically connected to the control line and the second electrode or between the electrode electrically connected to the signal line and the second electrode is more than or equal to 0.2 μm and less than or equal to 16 μm.

Since the input/output device of one embodiment of the present invention includes the electrode including the conductive film provided with the opening in the region overlapping with the pixel, an object that comes in the vicinity of the region overlapping with the display device can be sensed without disturbing display of the display device. As a result, a novel input/output device that is highly convenient or reliable can be provided.

(15) One embodiment of the present invention is the above-described input/output device further including a first functional film and a second functional film.

The first functional film includes a region that overlaps with the first display element with the sensing element positioned therebetween. The first functional film includes a circular polarizing film.

The second functional film includes a region positioned between the first functional film and the first display element. The second functional film includes a light diffusion film.

Since the input/output device of one embodiment of the present invention includes the first functional film, which is positioned closer to a user's side than the sensing element, and the second functional film between the first functional film and the first display element, light reflected by the sensing element can be controlled by the first functional film. Alternatively, light reflected by the first display element can be diffused by the second functional film. As a result, a novel input/output device that is highly convenient or reliable can be provided.

(16) One embodiment of the present invention is a data processing device including at least one of a keyboard, a hardware button, a pointing device, a touch sensor, an illuminance sensor, an imaging device, an audio input device, a viewpoint input device, and an attitude determination device; and the above-described input/output device.

Thus, power consumption can be reduced and excellent visibility can be ensured even in a bright place. As a result, a novel data processing device that is highly convenient or reliable can be provided.

Although the block diagram attached to this specification shows components classified by their functions in independent blocks, it is difficult to classify actual components according to their functions completely and it is possible for one component to have a plurality of functions.

In this specification, the terms “source” and “drain” of a transistor interchange with each other depending on the polarity of the transistor or the levels of potentials applied to the terminals. In general, in an n-channel transistor, a terminal to which a lower potential is applied is called a source, and a terminal to which a higher potential is applied is called a drain. In a p-channel transistor, a terminal to which a lower potential is applied is called a drain, and a terminal to which a higher potential is applied is called a source. In this specification, although connection relation of the transistor is described assuming that the source and the drain are fixed for convenience in some cases, actually, the names of the source and the drain interchange with each other depending on the relation of the potentials.

Note that in this specification, a “source” of a transistor means a source region that is part of a semiconductor film functioning as an active layer or a source electrode connected to the semiconductor film. Similarly, a “drain” of a transistor means a drain region that is part of the semiconductor film or a drain electrode connected to the semiconductor film. A “gate” means a gate electrode.

Note that in this specification, a state in which transistors are connected to each other in series means, for example, a state in which only one of a source and a drain of a first transistor is connected to only one of a source and a drain of a second transistor. In addition, a state in which transistors are connected in parallel means a state in which one of a source and a drain of a first transistor is connected to one of a source and a drain of a second transistor and the other of the source and the drain of the first transistor is connected to the other of the source and the drain of the second transistor.

In this specification, the term “connection” means electrical connection and corresponds to a state where a current, a voltage, or a potential can be supplied or transmitted. Accordingly, connection means not only direct connection but also indirect connection through a circuit element such as a wiring, a resistor, a diode, or a transistor so that a current, a potential, or a voltage can be supplied or transmitted.

In this specification, even when different components are connected to each other in a circuit diagram, there is actually a case where one conductive film has functions of a plurality of components such as a case where part of a wiring serves as an electrode. The term “connection” in this specification also means such a case where one conductive film has functions of a plurality of components.

Further, in this specification, one of a first electrode and a second electrode of a transistor refers to a source electrode and the other refers to a drain electrode.

According to one embodiment of the present invention, a novel display device that is highly convenient or reliable can be provided. Furthermore, a novel input/output device that is highly convenient or reliable can be provided. Furthermore, a novel data processing device that is highly convenient or reliable can be provided. Moreover, a novel data processing device or a novel semiconductor device can be provided.

Note that the descriptions of these effects do not disturb the existence of other effects. One embodiment of the present invention does not necessarily have all the effects listed above. Other effects will be apparent from and can be derived from the description of the specification, the drawings, the claims, and the like.

### BRIEF DESCRIPTION OF DRAWINGS

In the accompanying drawings:

FIGS. 1A, 1B1, and 1B2 illustrate a structure of an input/output device of an embodiment;

FIGS. 2A to 2C are cross-sectional views illustrating a cross-sectional structure of an input/output device of an embodiment;

FIGS. 3A and 3B are cross-sectional views illustrating a cross-sectional structure of an input/output device of an embodiment;

FIG. 4 is a circuit diagram illustrating a structure of an input/output device of an embodiment;

FIGS. 5A, 5B1, and 5B2 are a block diagram and schematic diagrams illustrating structures of an input/output device of an embodiment;

FIGS. 6A, 6B1, and 6B2 are a block diagram and schematic diagrams illustrating a structure of a sensor portion of an input/output device of an embodiment;

FIGS. 7A, 7B1, and 7B2 illustrate a structure of an input/output device of an embodiment;

FIGS. 8A to 8C are cross-sectional views illustrating a cross-sectional structure of an input/output device of an embodiment;

FIG. 9 is a cross-sectional view illustrating a cross-sectional structure of an input/output device of an embodiment;

FIGS. 10A to 10D illustrate a structure of a transistor of an embodiment;

FIGS. 11A to 11C illustrate a structure of a transistor of an embodiment;

FIG. 12A is a block diagram and FIGS. 12B and 12C are projection views each illustrating a structure of a data processing device of an embodiment;

FIGS. 13A to 13C are block diagrams and a circuit diagram illustrating structures in a display device of an embodiment;

FIGS. 14A and 14B are flow charts each illustrating a program of an embodiment;

FIGS. 15A to 15C are a cross-sectional view and circuit diagrams each illustrating a structure of a semiconductor device of an embodiment;

FIG. 16 is a block diagram illustrating a structure of a CPU of an embodiment;

FIG. 17 is a circuit diagram illustrating a structure of a memory element of an embodiment; and

FIGS. 18A to 18H each illustrate a structure of an electronic device of an embodiment.

### BEST MODE FOR CARRYING OUT THE INVENTION

An input/output device of one embodiment of the present invention includes a signal line, a pixel electrically connected to the signal line, a first conductive film electrically connected to the pixel, a second conductive film including a region overlapping with the first conductive film, and a first insulating film including a region sandwiched between the first conductive film and the second conductive film and a second opening in the sandwiched region. The pixel includes a pixel circuit electrically connected to the signal line, a third conductive film electrically connected to the pixel circuit, a fourth conductive film including a region overlapping with the third conductive film, a second insulating film including a region sandwiched between the fourth conductive film and the third conductive film and an opening in the sandwiched region, a first display element electrically connected to the fourth conductive film, and a second display element electrically connected to the pixel circuit. Moreover, the second conductive film is electrically connected to the first conductive film through the second opening, and the third conductive film is electrically connected to the fourth conductive film through the opening.

Thus, the first display element and the second display element which performs display using a method different from that of the first display element can be driven using transistors which can be formed in different processes, for example. Consequently, a novel display device that is highly convenient or reliable can be provided.

Embodiments will be described in detail with reference to the drawings. Note that the present invention is not limited to the following description. It will be readily appreciated by those skilled in the art that modes and details of the present invention can be modified in various ways without departing from the spirit and scope of the present invention. Thus, the present invention should not be construed as being limited to the description in the following embodiments. Note that in structures of the invention described below, the same portions or portions having similar functions are denoted by the same reference numerals in different drawings, and a description thereof is not repeated.

### Embodiment 1

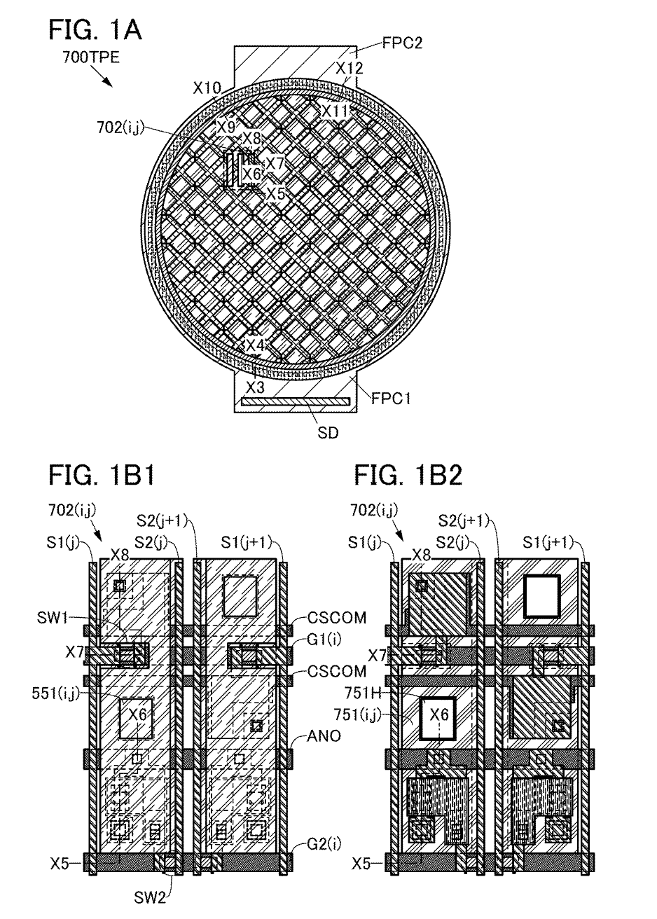

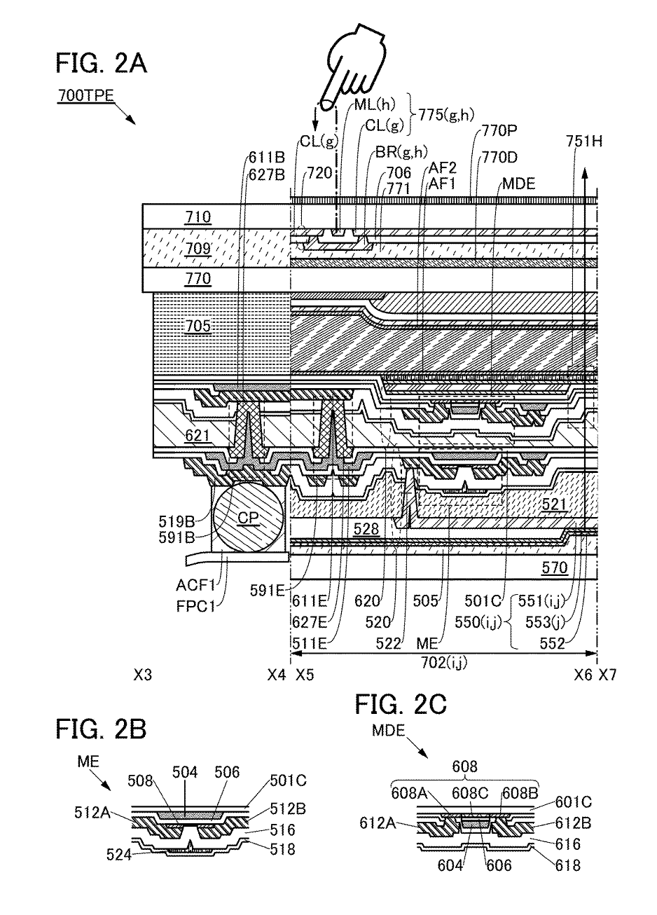

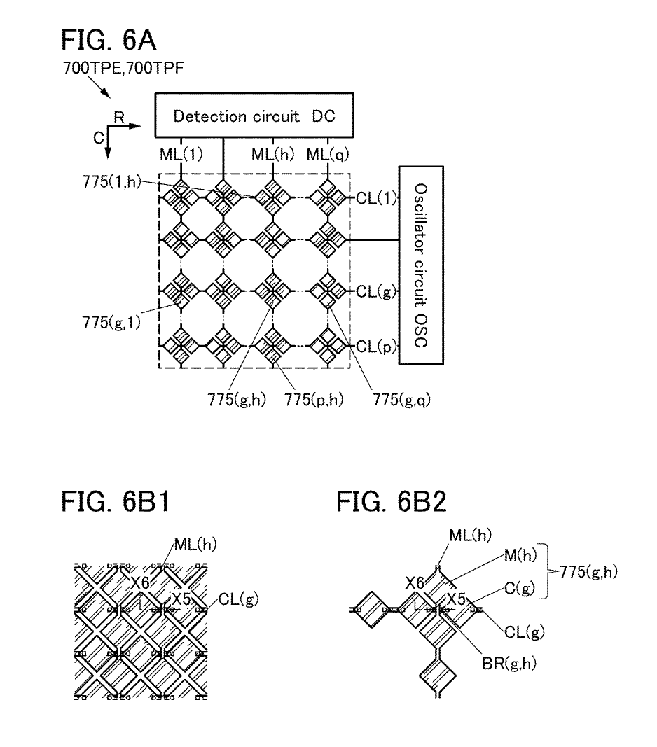

In this embodiment, a structure of an input/output device 700TPE in one embodiment of the present invention will be described with reference to FIGS. 1A, 1B1, and 1B2, FIGS. 2A to 2C, FIGS. 3A and 3B, FIG. 4, FIGS. 5A, 5B1, and 5B2, and FIGS. 6A, 6B1, and 6B2. Note that in this specification, an integral variable of 1 or more may be used for reference numerals. For example, “(p)” where p is an integral variable of 1 or more may be used for part of a reference numeral that specifies any one of components (p components in maximum). For another example, “(m, n)” where m and n are each an integral variable of 1 or more may be used for part of a reference numeral that specifies any one of components (m×n components in maximum).

FIGS. 1A, 1B1, and 1B2 illustrate a structure of an input/output device of one embodiment of the present invention. FIG. 1A is a top view of the input/output device of one embodiment of the present invention. FIG. 1B1 is a bottom view illustrating a structure of part of FIG. 1A. FIG. 1B2 is a bottom view omitting some components illustrated in FIG. 1B1.

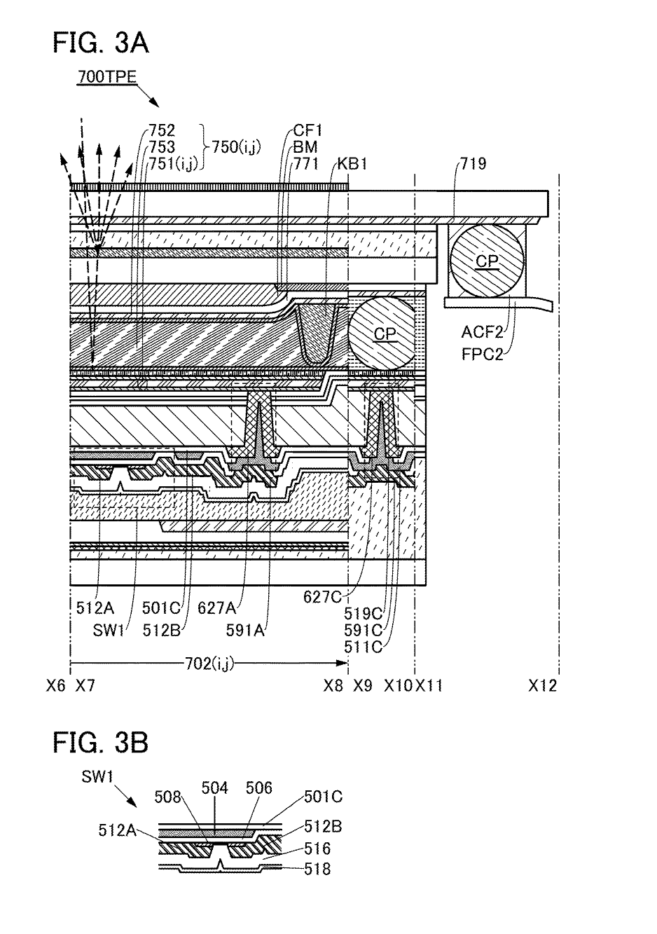

FIGS. 2A to 2C and FIGS. 3A and 3B are cross-sectional views illustrating a structure of the input/output device of one embodiment of the present invention. FIG. 2A is a cross-sectional view taken along cutting plane lines X3-X4 and X5-X6 in FIG. 1A, FIG. 2B illustrates part of FIG. 2A, and FIG. 2C illustrates another part of FIG. 2A.

FIG. 3A is a cross-sectional view taken along cutting plane lines X7-X8, X9-X10, and X11-X12 in FIG. 1A, and FIG. 3B illustrates part of FIG. 3A.

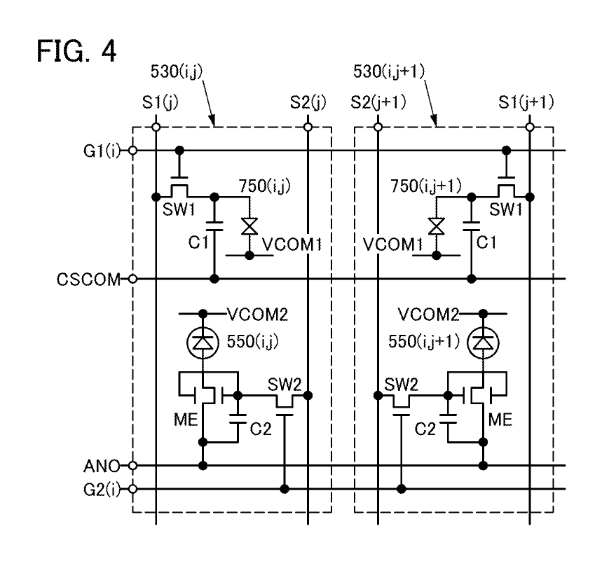

FIG. 4 is a circuit diagram illustrating a structure of a pixel circuit included in an input/output device of one embodiment of the present invention.

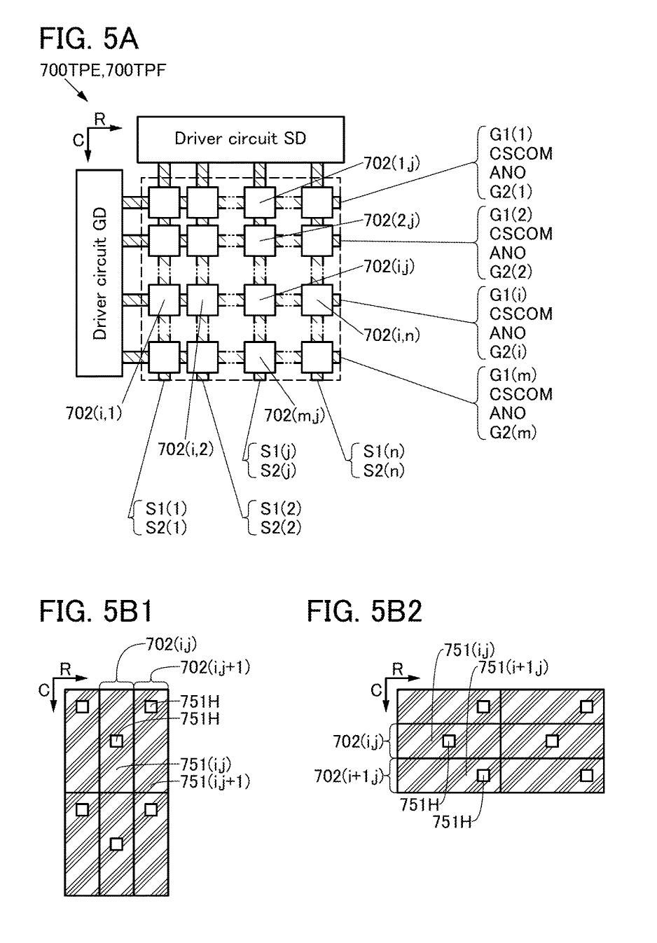

FIGS. 5A, 5B1, and 5B2 are block diagrams illustrating the arrangement of pixels, wirings, and the like in a display device that can be used for the input/output device of one embodiment of the present invention. FIGS. 5B1 and 5B2 are schematic diagrams each illustrating the arrangement of openings that can be used for the input/output device of one embodiment of the present invention.

FIGS. 6A, 6B1, and 6B2 illustrate a structure of an input/output device of one embodiment of the present invention. FIG. 6A is a block diagram of an input portion of the input/output device of one embodiment of the present invention. FIG. 6B1 is a top view illustrating part of FIG. 6A. FIG. 6B2 is a top view omitting some components illustrated in FIG. 6B1.

### Structure Example 1 of Input/Output Device

The input/output device 700TPE described in this embodiment includes a display device and an input portion. For example, the input portion is included on the display side of the display device (see FIG. 2A and FIG. 3A).

<<Display device>>

The display device includes a signal line S1(j), a pixel 702(i, j), a conductive film 511E, a conductive film 611E, and an insulating film 621 (see FIGS. 1A, 1B1, and 1B2 and FIGS. 2A to 2C).

The pixel 702(i, j) is electrically connected to the signal line S1(j).

The conductive film 511E is electrically connected to the pixel 702(i, j).

The conductive film 611E includes a region overlapping with the conductive film 511E.

The insulating film 621 includes a region sandwiched between the conductive film 511E and the conductive film 611E and has a second opening 591E in the region sandwiched between the conductive film 511E and the conductive film 611E.

The conductive film 611E is electrically connected to the conductive film 511E through the second opening 591E. Note that the conductive film 611E can be electrically connected to the conductive film 511E through a conductive film 627E, for example. Incidentally, the conductive film 627E which electrically connects the conductive film 611E to the conductive film 511E through the opening 591E formed in an insulating film 501C can be referred to as a through electrode. Moreover, the conductive film 511E and the conductive film 611E that is provided so that the insulating film 501C is sandwiched between the conductive film 511E and the conductive film 611E can be collectively referred to as a multilayer wiring.

The pixel 702(i, j) includes a pixel circuit 530(i, j), a third conductive film, a fourth conductive film, the insulating film 501C, a first display element 750(i, j), and a second display element 550(i, j) (see FIG. 2A, FIG. 3A, and FIG. 4)

The pixel circuit 530(i, j) is electrically connected to the signal line S1(j) (see FIG. 4). Note that a conductive film 512A is electrically connected to the signal line S1(j) (see FIG. 3A and FIG. 4).

The third conductive film is electrically connected to the pixel circuit 530(i, j). For example, a conductive film 512B serving as a source electrode or a drain electrode of a transistor used as a switch SW1 of the pixel circuit 530(i, j) can be used as the third conductive film (see FIG. 3A and FIG. 4).

The fourth conductive film includes a region overlapping with the third conductive film. For example, the fourth conductive film can be used as a first electrode 751(i, j) of the first display element 750(i, j).

The insulating film 501C includes a region sandwiched between the third conductive film and the fourth conductive film and has an opening 591A in the region sandwiched between the fourth conductive film and the third conductive film (see FIG. 3A).

The third conductive film is electrically connected to the fourth conductive film through the opening 591A. For example, the conductive film 512B is electrically connected to the first electrode 751(i, j). Specifically, for example, the conductive film 512B can be electrically connected to the first electrode 751(i, j) through a conductive film 627A. Incidentally, the fourth conductive film electrically connected to the third conductive film through the opening 591A provided in the insulating film 501C can be referred to as a through electrode.

The first display element 750(i, j) is electrically connected to the fourth conductive film.

The second display element 550(i, j) is electrically connected to the pixel circuit 530(i, j).

The display device that can be used for the input/output device of one embodiment of the present invention includes a first transistor ME and a second transistor MDE (see FIGS. 2A and 2B).

The first transistor ME includes a region overlapping with the insulating film 621, is electrically connected to the conductive film 511E, and includes a first semiconductor film 508.

The second transistor MDE includes a region overlapping with the insulating film 621, is electrically connected to the conductive film 611E, includes a second semiconductor film 608 which is different from the first semiconductor film 508. For example, a film including an oxide semiconductor is used as the first semiconductor film 508, and a film including silicon is used as the second semiconductor film 608. Specifically, an oxide semiconductor including indium, gallium, and zinc can be used for the first semiconductor film 508, and a film including polysilicon can be used as the second semiconductor film 608.

Thus, the first display element and the second display element which performs display using a method different from that of the first display element can be driven using the first transistor and the second transistor which is formed in a process different from that of the first transistor, for example. Consequently, a novel display device that is highly convenient or reliable can be provided.

In the display device that can be used for the input/output device described in this embodiment, the second transistor MDE includes a region overlapping with the first transistor ME.

Accordingly, the outward form of the display device in which the first display element and the second display element which performs display using a method different from that of the first display element can be driven can be reduced. The design flexibility can be increased. Consequently, a novel display device that is highly convenient or reliable can be provided.

Furthermore, the display device that can be used for the input/output device described in this embodiment includes a plurality of pixels 702(i, 1) to 702(i, n), another plurality of pixels 702(1, j) to 702(m, j), and a scan line G1(i) (see FIG. 5A). Note that i is an integer greater than or equal to 1 and less than or equal to m, j is an integer greater than or equal to 1 and less than or equal to n, and each of m and n is an integer greater than or equal to 1.

The plurality of pixels 702(i, 1) to 702(i, n) include the pixel 702(i, j) and are provided in a row direction (a direction indicated by an arrow R in the drawing).

The another plurality of pixels 702(1, j) to 702(m, j) include the pixel 702(i, j) and are provided in a column direction (a direction indicated by an arrow C in the drawing) that intersects the row direction.

The scan line G1(i) is electrically connected to the plurality of pixels 702(i, 1) to 702(i, n).

The another plurality of pixels 702(1, j) to 702(m, j) are electrically connected to the signal line S1(j).

Moreover, the display device that can be used for the input/output device described in this embodiment includes a driver circuit GD.

The driver circuit GD is electrically connected to the scan line G1(i) and is configured to supply a selection signal.

Furthermore, the display device that can be used for the input/output device described in this embodiment includes a driver circuit SD.

The driver circuit SD is electrically connected to the signal line S1(j) and is configured to supply an image signal.

In the display device that can be used for the input/output device described in this embodiment, the driver circuit GD or the driver circuit SD includes a transistor including silicon in its semiconductor film. For example, a semiconductor including an element belonging to Group 14 can be used for the semiconductor film. Specifically, a semiconductor including silicon can be used for the semiconductor film. For example, single crystal silicon, polysilicon, microcrystalline silicon, amorphous silicon, or the like can be used for the semiconductor film.

Thus, the pixel circuit can be driven using the driver circuit including the transistor which is formed in a process different from that of the transistor included in the pixel circuit, for example. Consequently, a novel display device that is highly convenient or reliable can be provided.

The second display element 550(i, j) of the input/output device described in this embodiment is provided so that the display using the second display element 550(i, j) can be seen from part of a region from which the display using the first display element 750(i, j) can be seen. For example, dashed arrows shown in FIG. 3A denote the directions in which external light is incident on and reflected by the first display element 750(i, j) that performs display by controlling the intensity of external light reflection. A solid arrow shown in FIG. 2A denotes the direction in which the second display element 550(i, j) emits light to the part of the region from which the display using the first display element 750(i, j) can be seen.

Thus, the display using the second display element can be seen from part of the region from which the display using the first display element can be seen. Alternatively, a user can see the display without changing the attitude or the like of the display device. Thus, a novel display device that is highly convenient or reliable can be provided.

In addition, the second display element 550(i, j) of the input/output device described in this embodiment is configured to perform display in a region surrounded by a region where the first display element 750(i, j) performs display (see FIG. 5B1 or FIG. 5B2). Note that the first display element 750(i, j) performs display in a region overlapping with the first electrode 751(i, j), and the second display element 550(i, j) performs display in a region overlapping with an opening 751H.

The second display element 550(i, j) in the input/output device described in this embodiment is configured to emit light toward the insulating film 501C (see FIG. 2A).

The first display element 750(i, j) includes a reflective film that reflects incident light and is configured to control the intensity of reflected light. The reflective film is configured to reflect incident light and has a shape including a region that does not block light emitted from the second display element 550(i, j). For example, the reflective film can have a shape including the opening 751H. The second display element 550(i, j) can emit light toward the opening 751H. The fourth conductive film, the first electrode 751(i, j), or the like can be used as the reflective film of the first display element 750(i, j), for example.

### <<Input Portion>>

The input portion of the input/output device described in this embodiment includes a region overlapping with the display device and is configured to sense an object that comes in the vicinity of the region overlapping with the display device (see FIG. 2A and FIG. 6A).

The input portion includes a control line CL(g), a signal line ML(h), and a sensing element 775(g, h). For example, a sensing element 775(g, h) configured to sense an approaching finger or the like can be used.

The control line CL(g) extends in the row direction, and the signal line ML(h) extends in the column direction that intersects the row direction (see FIG. 6A).

The sensing element 775(g, h) has a light-transmitting property. The sensing element 775(g, h) includes an electrode C(g) electrically connected to the control line CL(g) and an electrode M(h) electrically connected to the signal line ML(h) (see FIG. 6B2).

The electrode M(h) electrically connected to the signal line ML(h) is provided so that an electric field part of which is blocked by an object that comes in the vicinity of the region overlapping with the display panel is generated between the electrode M(h) and the electrode C(g) electrically connected to the control line CL(g).

The input portion of the input/output device according to one embodiment of the present invention includes a sensing element that has a light-transmitting property in a region overlapping with a pixel. Thus, an object that comes in the vicinity of a region overlapping with a display panel can be sensed. As a result, a novel input/output device that is highly convenient or reliable can be provided.

In the input/output device described in this embodiment, the electrode C(g) electrically connected to the control line CL(g) includes a light-transmitting conductive film, and the electrode M(h) electrically connected to the signal line ML(h) includes a light-transmitting conductive film. The light-transmitting conductive films include regions overlapping with the pixel 702(i, j). For example, the sensing element 775(g, h) includes a region overlapping with the pixel 702(i, j) (see FIG. 2A).

Since the input/output device of one embodiment of the present invention includes the control line including the light-transmitting conductive film in the region overlapping with the pixel and the signal line including the light-transmitting conductive film in the region overlapping with the pixel, an object that comes in the vicinity of the region overlapping with the display device can be sensed without disturbing display of the display device. As a result, a novel input/output device that is highly convenient or reliable can be provided.

In the input/output device described in this embodiment, the electrode C(g) electrically connected to the control line CL(g) includes a conductive film provided with an opening, and the electrode M(h) electrically connected to the signal line ML(h) includes a conductive film provided with an opening. The openings include regions overlapping with the pixel 702(i, j).

In the input/output device described in this embodiment, the gap between a second electrode 752 and the electrode C(g) electrically connected to the control line CL(g) or between the second electrode 752 and the electrode M(h) electrically connected to the signal line ML(h) is more than or equal to 0.2 μm and less than or equal to 16 μm.

Since the input/output device of one embodiment of the present invention includes the electrode including the conductive film provided with the opening in the region overlapping with the pixel, an object that comes in the vicinity of the region overlapping with the display device can be sensed without disturbing display of the display device. As a result, a novel input/output device that is highly convenient or reliable can be provided.

The input/output device described in this embodiment includes a first functional film 770P and a second functional film 770D (see FIG. 2A).

The first functional film 770P includes a region where the sensing element 775(g, h) is sandwiched between the first functional film 770P and the first display element 750(i, j), and includes a circularly polarizing film.

The second functional film 770D includes a region between the first functional film 770P and the first display element 750(i, j), and includes a light diffusion film.

Since the input/output device of one embodiment of the present invention includes the first functional film, which is positioned closer to a user's side than the sensing element, and the second functional film between the first functional film and the first display element, light reflected by the sensing element can be controlled by the first functional film. Alternatively, light reflected by the first display element can be diffused by the second functional film. As a result, a novel input/output device that is highly convenient or reliable can be provided.

The input/output device described in this embodiment includes the pixel 702(i, j), the plurality of pixels 702(i, 1) to 702(i, n), the another plurality of pixels 702(1, j) to 702(m, j), and the scan line G1(i) (see FIG. 5A). Note that i is an integer greater than or equal to 1 and less than or equal to m, j is an integer greater than or equal to 1 and less than or equal to n, and each of m and n is an integer greater than or equal to 1.

The input/output device described in this embodiment includes a scan line G2(i), a wiring CSCOM, and a wiring ANO.

The plurality of pixels 702(i, 1) to 702(i, n) include the pixel 702(i, j) and are arranged in the row direction (the direction shown by the arrow R in drawings).

The another plurality of pixels 702(1, j) to 702(m, j) include the pixel 702(i, j) and are arranged in the column direction (the direction shown by the arrow C in drawings) that intersects the row direction.

The scan line G1(i) is electrically connected to the plurality of pixels 702(i, 1) to 702(i, n) arranged in the row direction.

The another plurality of pixels 702(1, j) to 702(m, j) arranged in the column direction are electrically connected to the signal line S1(j).

For example, the pixel 702(i, j+1) adjacent to the pixel 702(i, j) in the row direction includes an opening in a position different from that of the opening 751H in the pixel 702(i, j) (see FIG. 5B1).

For example, the pixel 702(i+1, j) adjacent to the pixel 702(i, j) in the column direction includes an opening in a position different from that of the opening 751H in the pixel 702(i, j) (see FIG. 5B2). Note that the first electrode 751(i, j) can be used as the reflective film.

In addition, the first display element 750(i, j) of the input/output device described in this embodiment includes a layer 753 containing a liquid crystal material, the first electrode 751(i, j), and the second electrode 752. Note that the second electrode 752 is provided so that an electric field for controlling the alignment of the liquid crystal material is generated between the second electrode 752 and the first electrode 751(i, j) (see FIG. 3A).

Furthermore, the first electrode 751(i, j) of the input/output device described in this embodiment includes a side end portion embedded in the insulating film 601C (see FIG. 2A and FIG. 3A). Accordingly, a step at the edge of the first electrode 751(i, j) can be minimized to reduce the possibility of alignment defects in the liquid crystal material due to the step.

In addition, the input/output device described in this embodiment includes an alignment film AF1 and an alignment film AF2. The alignment film AF2 is provided so that the layer 753 containing a liquid crystal material lies between the alignment films AF1 and AF2.

In addition, the second display 550(i, j) of the input/output device described in this embodiment includes a third electrode 551(i, j), a fourth electrode 552, and a layer 553(j) containing a light-emitting material.

The fourth electrode 552 includes a region overlapping with the third electrode 551(i, j). The layer 553(j) containing a light-emitting material includes a region between the third electrode 551 and the fourth electrode 552. The third electrode 551(i, j) is electrically connected to the transistor ME included in the pixel circuit 530(i, j) at a contact portion 522.

In addition, the input/output device described in this embodiment includes a coloring film CF1, a light-blocking film BM, an insulating film 771, the functional film 770P, and the functional film 770D.

The coloring film CF1 includes a region overlapping with the first display element 750(i, j). The light blocking film BM has an opening in a region overlapping with the first display element 750(i, j).

The insulating film 771 lies between the coloring film CF1 and the layer 753 containing a liquid crystal material or between the light-blocking film BM and the layer 753 containing a liquid crystal material. Thus, unevenness due to the thickness of the coloring film CF1 can be avoided. Impurities can be prevented from being diffused from the light-blocking film BM, the coloring film CF1, or the like to the layer 753 containing a liquid crystal material.

The functional film 770P includes a region overlapping with the first display element 750(i, j). The functional film 770P is provided so that the sensing element 775(g, h) is sandwiched between the functional film 770P and the first display element 750(i, j). Thus, for example, light reflected by the sensing element 775(g, h) can be reduced.

The functional film 770D includes a region overlapping with the first display element 750(i, j). The functional film 770D is provided so that a substrate 770 lies between the functional film 770D and the first display element 750(i, j). Thus, for example, light reflected by the first display element 750(i, j) can be diffused.

The input/output device described in this embodiment includes a substrate 570, the substrate 770, a substrate 710, a functional layer 520, a functional layer 720, and a functional layer 620.

The substrate 770 includes a region overlapping with the substrate 570.

The substrate 710 includes a region overlapping with the substrate 770.

The functional layer 520 includes a region between the substrate 570 and the substrate 770. The functional layer 520 includes the pixel circuit 530(i, j) having the transistor ME, the second display element 550(i, j), an insulating film 521, and an insulating film 528. Furthermore, the functional layer 520 includes an insulating film 518 and an insulating film 516 (see FIGS. 2A and 2B).

The insulating film 521 lies between the pixel circuit 530(i, j) including the transistor ME and the second display element 550(i, j).

The insulating film 528 lies between the insulating film 521 and the substrate 570 and has an opening in a region overlapping with the second display element 550(i, j). The insulating film 528 along the edge of the third electrode 551 can avoid a short circuit between the third electrode 551 and the fourth electrode 552.

The insulating film 518 includes a region between the insulating film 521 and the transistor ME and the switch SW1 in the pixel circuit 530(i, j). The insulating film 516 includes a region between the insulating film 518 and the transistor ME and the switch SW1 in the pixel circuit 530(i, j).

The functional layer 720 includes a region between the substrate 770 and the substrate 710. The functional layer 720 includes the sensing element 775(g, h) and an insulating film 706.

The functional layer 620 includes a region between the substrate 770 and the functional layer 520. The functional layer 620 includes the conductive film 612B, the conductive film 611E, and the transistor MDE.

The input/output device described in this embodiment includes a bonding layer 505, a bonding layer 709, a sealant 705, and a structure body KB1.

The bonding layer 505 lies between the functional layer 520 and the substrate 570 to bond them together.

The sealant 705 lies between the functional layer 520 and the substrate 770 to bond them together.

The structure body KB1 is provided for making a predetermined gap between the functional layer 520 and the substrate 770.

The bonding layer 709 lies between the functional layer 720 and the substrate 770 to bond them together.

In addition, the input/output device described in this embodiment includes a terminal 519C and a conductive film 511C.

The insulating film 501C includes a region between the terminal 519C and the conductive film 511C. In addition, the insulating film 501C has an opening 591C.

The terminal 519C is electrically connected to the conductive film 511C through the opening 591C. In addition, the conductive film 511C is electrically connected to the pixel circuit 530(i, j). For example, the terminal 519C can be electrically connected to the conductive film 511C through a conductive film 627C.

A conductor CP lies between the terminal 519C and the second electrode 752 for electrically connecting them. For example, a conductive particle can be used as the conductor CP.

In addition, the input/output device described in this embodiment includes a terminal 519B.

The insulating film 501C includes a region sandwiched between the terminal 519B and the conductive film 611B. The insulating film 501C has an opening 591B.

The terminal 519B is electrically connected to the conductive film 611B through the opening 591B. For example, the terminal 519B can be electrically connected to the conductive film 611B through a conductive film 627B. In addition, the conductive film 611B is electrically connected to the driver circuit GD or the driver circuit SD. The terminal 519B can be electrically connected to a flexible printed circuit FPC1 using a conductive material ACF1, for example. Note that a conductive material containing the conductor CP can be used as the conductive material ACF1.

Moreover, the input/output device described in this embodiment includes the conductive film 511E and the conductive film 611E.

The insulating film 501C includes a region sandwiched between the conductive film 511E and the conductive film 611E. Furthermore, the insulating film 501C has the opening 591E.

The conductive film 511E is electrically connected to the conductive film 611E through the opening 591E. For example, the conductive film 511E can be electrically connected to the conductive film 611E through the conductive film 627E. The conductive film 511E is electrically connected to the driver circuit GD or the driver circuit SD. For example, the conductive film 511E can be electrically connected to the pixel circuit 530(i, j).

The input/output device described in this embodiment includes a terminal 719. The terminal 719 is electrically connected to the sensing element 775(g, h).

In addition, the input/output device described in this embodiment includes the driver circuit GD and the driver circuit SD (see FIGS. 1A and 5A).

The driver circuit GD is electrically connected to the scan line G1(i). The driver circuit GD includes a transistor MDE, for example. Specifically, a transistor including a semiconductor film that can be formed in a step different from the step for the semiconductor film in the transistor included in the pixel circuit 530(i, j) can be used as the transistor MDE (see FIGS. 2A and 2B).

The driver circuit SD is electrically connected to the signal line S1(j). The driver circuit SD is electrically connected to a terminal using a conductive material, for example. The terminal can be formed in the same step as the terminal 519B or the terminal 519C.

The input/output device described in this embodiment includes a plurality of sensing elements 775(g, 1) to 775(g, q) and another plurality of sensing elements 775(1, h) to 775(p, h) (see FIG. 6A). Note that g is an integer greater than or equal to 1 and less than or equal to p, h is an integer greater than or equal to 1 and less than or equal to q, and each of p and q is an integer greater than or equal to 1.

The plurality of sensing elements 775(g, 1) to 775(g, q) include the sensing element 775(g, h) and are arranged in the row direction (indicated by the arrow R in the drawing).

The another plurality of the sensing elements 775(1, h) to 775(p, h) include the sensing element 775(g, h) and are arranged in the column direction (indicated by the arrow C in the drawing) that intersects the row direction.

The plurality of sensing elements 775(g, 1) to 775(g, q) arranged in the row direction include the control line CL(g).

The another plurality of sensing elements 775(1, h) to 775(p, h) arranged in the column direction include the signal line ML(h).

The control line CL(g) of the input/output device described in this embodiment includes a conductive film BR(g, h) (see FIG. 2A). The conductive film BR(g, h) includes a region overlapping with the signal line ML(h).

The insulating film 706 lies between the signal line ML(h) and the conductive film BR(g, h). Thus, a short circuit between the signal line ML(h) and the conductive film BR(g, h) can be avoided.

The input/output device described in this embodiment includes an oscillator circuit OSC and a detection circuit DC (see FIG. 6A).

The oscillator circuit OSC is electrically connected to the control line CL(g) and has a function of supplying a search signal. As the search signal, a rectangular wave, a sawtooth wave, a triangular wave, or the like can be used.

The detection circuit DC is electrically connected to the signal line ML(h) and has a function of supplying a sensor signal in accordance with a change in the potential of the signal line ML(h).

Individual components of the input/output device are described below. Note that these components cannot be clearly distinguished and one component may serve as another one or include part of another one.

For example, the fourth conductive film can be used as the first electrode 751(i, j). The fourth conductive film can be used as a reflective film.

In addition, the third conductive film can be used as the conductive film 512B serving as a source electrode or a drain electrode of a transistor.

### Structural Example

The input/output device of one embodiment of the present invention includes the substrate 570, the substrate 770, the substrate 710, the structure body KB1, the sealant 705, the bonding layer 505, or the bonding layer 709.

In addition, the input/output device of one embodiment of the present invention includes the functional layer 520, the functional layer 720, the insulating film 521, and the insulating film 528.

In addition, the input/output device of one embodiment of the present invention includes the signal line S1(j), a signal line S2(j), the scan line G1(i), the scan line G2(i), the wiring CSCOM, and the wiring ANO.

In addition, the input/output device of one embodiment of the present invention includes the fourth conductive film or the third conductive film.

In addition, the input/output device of one embodiment of the present invention includes the terminal 519B, the terminal 519C, the terminal 719, or the conductive film 511C.

In addition, the input/output device of one embodiment of the present invention includes the pixel circuit 530(i, j) or the switch SW1.

In addition, the input/output device of one embodiment of the present invention includes the first display element 750(i, j), the first electrode 751(i, j), the reflective film, the opening 751H, the layer 753 containing a liquid crystal material, or the second electrode 752.

In addition, the input/output device of one embodiment of the present invention includes the alignment film AF1, the alignment film AF2, the coloring film CF1, the light-blocking film BM, the insulating film 771, the functional film 770P, or the functional film 770D.

In addition, the input/output device of one embodiment of the present invention includes the second display element 550(i, j), the third electrode 551(i, j), the fourth electrode 552, or the layer 553(j) containing a light-emitting material.

Furthermore, the input/output device of one embodiment of the present invention includes the insulating film 501C.

In addition, the input/output device of one embodiment of the present invention includes the driver circuit GD or the driver circuit SD.

The input/output device of one embodiment of the present invention includes the sensing element 775(g, h), the control line CL(g), the signal line ML(h), the conductive film BR(g, h), or the insulating film 706.

The input/output device of one embodiment of the present invention includes the oscillator circuit OSC and the detection circuit DC.

### <<Substrate 570>>

The substrate 570 or the like can be formed using a material having heat resistance high enough to withstand heat treatment in the manufacturing process. Specifically, non-alkali glass with a thickness of 0.7 mm can be used. Alternatively, non-alkali glass polished to a thickness of approximately 0.1 mm can be used.

For example, a large-sized glass substrate having any of the following sizes can be used as the substrate 570 or the like: the 6th generation (1500 mm×1850 mm), the 7th generation (1870 mm×2200 mm), the 8th generation (2200 mm×2400 mm), the 9th generation (2400 mm×2800 mm), and the 10th generation (2950 mm×3400 mm). Thus, a large-sized display device can be manufactured.

For the substrate 570 or the like, an organic material, an inorganic material, a composite material of an organic material and an inorganic material, or the like can be used. For example, an inorganic material such as glass, ceramics, or a metal can be used for the substrate 570 or the like.

Specifically, non-alkali glass, soda-lime glass, potash glass, crystal glass, aluminosilicate glass, tempered glass, chemically tempered glass, quartz, sapphire, or the like can be used for the substrate 570 or the like. Specifically, an inorganic oxide film, an inorganic nitride film, an inorganic oxynitride film, or the like can be used for the substrate 570 or the like. For example, silicon oxide, silicon nitride, silicon oxynitride, an alumina film, or the like can be used for the substrate 570 or the like. Stainless steel, aluminum, or the like can be used for the substrate 570 or the like.

For example, a single crystal semiconductor substrate or a polycrystalline semiconductor substrate of silicon or silicon carbide, a compound semiconductor substrate of silicon germanium, an SOI substrate, or the like can be used as the substrate 570 or the like. Thus, a semiconductor element can be formed over the substrate 570 or the like.

For example, an organic material such as a resin, a resin film, or plastic can be used for the substrate 570 or the like. Specifically, a resin film or a resin plate of polyester, polyolefin, polyamide, polyimide, polycarbonate, an acrylic resin, or the like can be used for the substrate 570 or the like.

For example, a composite material, such as a resin film to which a metal plate, a thin glass plate, or an inorganic film is bonded can be used for the substrate 570 or the like. For example, a composite material formed by dispersing a fibrous or particulate metal, glass, an inorganic material, or the like into a resin film can be used for the substrate 570 or the like. For example, a composite material formed by dispersing a fibrous or particulate resin, organic material, or the like into an inorganic material can be used for the substrate 570 or the like.

A single-layer material or a layered material in which a plurality of layers are stacked can be used for the substrate 570 or the like. For example, a layered material in which a substrate, an insulating film that prevents diffusion of impurities contained in the substrate, and the like are stacked can be used for the substrate 570 or the like. Specifically, a layered material in which glass and one or a plurality of films that prevent diffusion of impurities contained in the glass and that are selected from a silicon oxide layer, a silicon nitride layer, a silicon oxynitride layer, and the like are stacked can be used for the substrate 570 or the like. Alternatively, a layered material in which a resin and a film for preventing diffusion of impurities that penetrate the resin, such as a silicon oxide film, a silicon nitride film, or a silicon oxynitride film, are stacked can be used for the substrate 570 or the like.

Specifically, a resin film, a resin plate, or a stack of polyester, polyolefin, polyamide, polyimide, polycarbonate, an acrylic resin, or the like can be used as the substrate 570 or the like.

Specifically, a material including polyester, polyolefin, polyamide (e.g., nylon or aramid), polyimide, polycarbonate, polyurethane, an acrylic resin, an epoxy resin, a resin having a siloxane bond, such as silicone, or the like can be used for the substrate 570 or the like.

Specifically, polyethylene terephthalate (PET), polyethylene naphthalate (PEN), polyethersulfone (PES), an acrylic resin, or the like can be used for the substrate 570 or the like.

Alternatively, paper, wood, or the like can be used for the substrate 570 or the like.

For example, a flexible substrate can be used as the substrate 570 or the like.

Note that a transistor, a capacitor, or the like can be directly formed on the substrate. Alternatively, a transistor, a capacitor, or the like can be formed over a substrate for use in manufacturing processes that can withstand heat applied in the manufacturing process and can be transferred to the substrate 570 or the like. Thus, a transistor, a capacitor, or the like can be formed over a flexible substrate, for example.

### <<Substrate 770, Substrate 710>>

For example, a light-transmitting material can be used for the substrate 770 or the substrate 710. Specifically, any of the materials that can be used for the substrate 570 can be used for the substrate 770 or the substrate 710. For example, non-alkali glass, aluminosilicate glass, tempered glass, chemically tempered glass, sapphire, or the like can be used. Note that aluminosilicate glass, tempered glass, chemically tempered glass, sapphire, or the like can be favorably used for the substrate 770 or the substrate 710 that is arranged on the user side of the input/output device. This can prevent damage or a crack of the input/output device caused by the use thereof.

Moreover, a material polished to a thickness of approximately 0.7 mm or 0.1 mm can be used for the substrate 770 or the substrate 710. Thus, the functional film 770D is provided near the first display element 750(i, j), which makes it possible to reduce an image blur and to display a clear image.

### <<Structure Body KB1>>

For example, an organic material, an inorganic material, or a composite material of an organic material and an inorganic material can be used for the structure body KB1 or the like. Thus, components between which the structure body KB1 or the like is provided can have a predetermined gap.

Specifically, for the structure body KB1 or the like, polyester, polyolefin, polyamide, polyimide, polycarbonate, polysiloxane, an acrylic resin, or the like, or a composite material of a plurality of kinds of resins selected from these can be used. Alternatively, a photosensitive material may be used.

### <<Sealant 705>>

For the sealant 705 or the like, an inorganic material, an organic material, a composite material of an inorganic material and an organic material, or the like can be used.

For example, an organic material such as a thermally fusible resin or a curable resin can be used for the sealant 705 or the like.

For the sealant 705 or the like, an organic material such as a reactive curable adhesive, a photo-curable adhesive, a thermosetting adhesive, and/or an anaerobic adhesive can be used.

Specifically, an adhesive containing an epoxy resin, an acrylic resin, a silicone resin, a phenol resin, a polyimide resin, an imide resin, a polyvinyl chloride (PVC) resin, a polyvinyl butyral (PVB) resin, or an ethylene vinyl acetate (EVA) resin, or the like can be used for the sealant 705 or the like.

### <<Bonding Layer 505>>

For example, a material that can be used for the sealant 705 can be used for the bonding layer 505.

### <<Bonding Layer 709>>

For example, a material that can be used for the sealant 705 can be used for the bonding layer 709.

### <<Insulating Film 521, Insulating Film 621>>

For example, an insulating inorganic material, an insulating organic material, or an insulating composite material containing an inorganic material and an organic material can be used for the insulating film 521, the insulating film 621, or the like.

Specifically, an inorganic oxide film, an inorganic nitride film, an inorganic oxynitride film, or a layered material obtained by stacking any of these films can be used for the insulating film 521, the insulating film 621, or the like. For example, a film including any of a silicon oxide film, a silicon nitride film, a silicon oxynitride film, and an aluminum oxide film, and the like, or a film including a layered material obtained by stacking any of these films can be used for the insulating film 521, the insulating film 621, or the like.

Specifically, polyester, polyolefin, polyamide, polyimide, polycarbonate, polysiloxane, an acrylic resin, or the like, or a layered or composite material including resins selected from these, or the like can be used for the insulating film 521, the insulating film 621, or the like. Alternatively, a photosensitive material may be used.

Thus, steps due to components overlapping with the insulating film 521 or the insulating film 621, for example, can be covered so that a flat surface can be formed.

### <<Insulating Film 528>>

For example, a material that can be used for the insulating film 521 can be used for the insulating film 528 or the like. Specifically, a 1-μm-thick film containing polyimide can be used for the insulating film 528.

### <<Insulating Film 501C>>

For example, the material that can be used for the insulating film 521 can be used for the insulating film 501C. Specifically, a material containing silicon and oxygen can be used for the insulating film 501C. Thus, impurity diffusion into the pixel circuit, the second display element, or the like can be suppressed.

For example, a 200-nm-thick film containing silicon, oxygen, and nitrogen can be used as the insulating film 501C.

Note that the insulating film 501C includes the openings 591A, 591B, and 591C.

### <<Insulating Film 706>>

For example, a material that can be used for the insulating film 521 can be used for the insulating film 528 or the like. Specifically, for example, a film containing silicon and oxygen can be used for the insulating film 706.

### <<Wiring, Terminal, Conductive Film>>

A conductive material can be used for a wiring or the like. Specifically, the conductive material can be used for the signal line S1(j), the signal line S2(j), the scan line G1(i), the scan line G2(i), the wiring CSCOM, the wiring ANO, the terminal 519B, the terminal 519C, the terminal 719, the conductive film 511C, the conductive film 511E, the conductive film 611B, the conductive film 611E, the conductive film 627A, the conductive film 627B, the conductive film 627C, the conductive film 627E, or the like.

For example, an inorganic conductive material, an organic conductive material, a metal material, a conductive ceramic material, or the like can be used for the wiring or the like.

Specifically, a metal element selected from aluminum, gold, platinum, silver, copper, chromium, tantalum, titanium, molybdenum, tungsten, nickel, iron, cobalt, palladium, and manganese, or the like can be used for the wiring or the like. Alternatively, an alloy including any of the above-described metal elements, or the like can be used for the wiring or the like. In particular, an alloy of copper and manganese is suitably used in microfabrication with the use of a wet etching method.

Specifically, a two-layer structure in which a titanium film is stacked over an aluminum film, a two-layer structure in which a titanium film is stacked over a titanium nitride film, a two-layer structure in which a tungsten film is stacked over a titanium nitride film, a two-layer structure in which a tungsten film is stacked over a tantalum nitride film or a tungsten nitride film, a three-layer structure in which a titanium film, an aluminum film, and a titanium film are stacked in this order, or the like can be used for the wiring or the like.

Specifically, a conductive oxide such as indium oxide, indium tin oxide, indium zinc oxide, zinc oxide, or zinc oxide to which gallium is added can be used for the wiring or the like.

Specifically, a film containing graphene or graphite can be used for the wiring or the like.

For example, a film including graphene oxide is formed and is reduced, so that a film including graphene can be formed. As a reducing method, a method using heat, a method using a reducing agent, or the like can be employed.

Specifically, a conductive high molecule can be used for the wiring or the like.

For example, a conductive film formed by a plating method can be used as the conductive film 627A, the conductive film 627B, the conductive film 627C, or the conductive film 627E. Specifically, a conductive film formed by an electroless plating method can be used. Thus, the conductive film can have a shape along the opening having a high aspect ratio.

### <<Third Conductive Film, Fourth Conductive Film>>

For example, the material that can be used for the wiring or the like can be used for the third conductive film or the fourth conductive film.

The third electrode 551(i, j), the wiring, or the like can be used for the fourth conductive film.

The conductive film 512B, the wiring, or the like of the transistor that can be used as the switch SW1 can be used as the third conductive film.

<<Pixel Circuit 530(i, j)>>

The pixel circuit 530(i, j) is electrically connected to the signal line S1(j), the signal line S2(j), the scan line G1(i), the scan line G2(i), the wiring CSCOM, and the wiring ANO (see FIG. 4).

The pixel circuit 530(i, j+1) is electrically connected to a signal line S1(j+1), a signal line S2(j+1), the scan line G1(i), the scan line G2(i), the wiring CSCOM, and the wiring ANO.

In the case where a voltage of a signal supplied to the signal line S2(j) is different from a voltage of a signal supplied to the signal line S1(j+1), the signal line S1(j+1) is positioned apart from the signal line S2(j). Specifically, the signal line S2(j+1) is positioned adjacent to the signal line S2(j).

The pixel circuit 530(i, j) includes the switch SW1, a capacitor C1, a switch SW2, the transistor ME, and a capacitor C2.

For example, a transistor including a gate electrode electrically connected to the scan line G1(i) and a first electrode electrically connected to the signal line S1(j) can be used as the switch SW1.

The capacitor C1 includes a first electrode electrically connected to the second electrode of the transistor used as the switch SW1 and a second electrode electrically connected to the wiring CSCOM.

For example, a transistor including a gate electrode electrically connected to the scan line G2(i) and a first electrode electrically connected to the signal line S2(j) can be used as the switch SW2.

The transistor ME includes a gate electrode electrically connected to a second electrode of the transistor used as the switch SW2 and a first electrode electrically connected to the wiring ANO.

Note that a transistor including a conductive film provided such that a semiconductor film is sandwiched between a gate electrode and the conductive film can be used as the transistor ME. For example, a conductive film electrically connected to a wiring that can supply the same potential as that of the gate electrode of the transistor ME can be used.

The capacitor C2 includes a first electrode electrically connected to the second electrode of the transistor used as the switch SW2 and a second electrode electrically connected to the first electrode of the transistor ME.

Note that the first electrode of the first display element 750 is electrically connected to the second electrode of the transistor used as the switch SW1, and the second electrode of the first display element 750 is electrically connected to the wiring VCOM1, so that the first display element 750 can be driven.

In addition, the first electrode of the second display element 550 is electrically connected to the second electrode of the transistor ME, and the second electrode of the second display element 550 is electrically connected to the wiring VCOM2, so that the second display element 550 can be driven.

### <<Switch SW1, Switch SW2, Transistor ME, Transistor MDE>>

For example, a bottom-gate transistor, a top-gate transistor, or the like can be used as the switch SW1, the switch SW2, the transistor ME, the transistor MDE, or the like.

For example, a transistor whose semiconductor film contains a semiconductor containing an element of Group 14 can be used. Specifically, a semiconductor containing silicon can be used for the semiconductor film. For example, single crystal silicon, polysilicon, microcrystalline silicon, amorphous silicon, or the like can be used for the semiconductor film of the transistor.

For example, a transistor whose semiconductor film contains an oxide semiconductor can be used. Specifically, an oxide semiconductor containing indium or an oxide semiconductor containing indium, gallium, and zinc can be used for a semiconductor film.

For example, a transistor having a lower leakage current in an off state than a transistor that uses amorphous silicon in a semiconductor film can be used as the switch SW1, the switch SW2, the transistor ME, the transistor MDE, or the like. Specifically, a transistor in which an oxide semiconductor is used in the semiconductor film 508 can be used as the switch SW1, the switch SW2, the transistor ME, the transistor MDE, or the like.

Thus, a pixel circuit can hold an image signal for a longer time than a pixel circuit including a transistor that uses amorphous silicon in a semiconductor film. Specifically, the selection signal can be supplied at a frequency of lower than 30 Hz, preferably lower than 1 Hz, further preferably less than once per minute while flickering is suppressed. Consequently, eyestrain on a user of the data processing device can be reduced, and power consumption for driving can be reduced.

For example, a transistor including the semiconductor film 508, a conductive film 504, an insulating film 506, the conductive film 512A, and the conductive film 512B can be used as the switch SW1 (see FIG. 3B).

The conductive film 504 includes a region overlapping with the semiconductor film 508 and has a function of a gate electrode. The insulating film 506 includes a region sandwiched between the semiconductor film 508 and the conductive film 504 and has a function of a gate insulating film. The conductive film 512A is electrically connected to the semiconductor film 508 and has a function of one of a source electrode and a drain electrode. The conductive film 512B is electrically connected to the semiconductor film 508 and has a function of the other of the source electrode and the drain electrode.

For example, a transistor including a conductive film 524 can be used as the transistor ME (see FIG. 2B). The semiconductor film 508 is sandwiched between the conductive film 504 and a region included in the conductive film 524.

Specifically, a conductive film in which a 10-nm-thick film containing tantalum and nitrogen and a 300-nm-thick film containing copper are stacked in this order can be used as the conductive film 504.

A material in which a 400-nm-thick film containing silicon and nitrogen and a 200-nm-thick film containing silicon, oxygen, and nitrogen are stacked in this order can be used for the insulating film 506.

A 25-nm-thick film containing indium, gallium, and zinc can be used as the semiconductor film 508.

A conductive film in which a 50-nm-thick film containing tungsten, a 400-nm-thick film containing aluminum, and a 100-nm-thick film containing titanium are stacked in this order can be used as the conductive film 512A or 512B.

For example, a transistor including the semiconductor film 608, a conductive film 604, an insulating film 606, a conductive film 612A, and a conductive film 612B can be used as the transistor MDE (see FIG. 2C).

The conductive film 604 includes a region overlapping with the semiconductor film 608 and has a function of a gate electrode. The insulating film 606 includes a region sandwiched between the semiconductor film 608 and the conductive film 604 and has a function of a gate insulating film.

The semiconductor film 608 includes a first region 608A, a second region 608B, and a third region 608C. The third region 608C is sandwiched between the first region 608A and the second region 608B and includes a region overlapping with the conductive film 604. The first region 608A includes a region not overlapping with the conductive film 604, and the second region 608B includes a region not overlapping with the conductive film 604. The first region 608A and the second region 608B have a lower resistivity than the third region 608C, and function as a source region and a drain region.

The conductive film 612A is electrically connected to the first region 608A of the semiconductor film 608 and has a function of one of a source electrode and a drain electrode. The conductive film 612B is electrically connected to the second region 608B of the semiconductor film 608 and has a function of the other of the source electrode and the drain electrode.

Specifically, polysilicon or single crystal silicon can be used for the semiconductor film 608. This can increase the current drive capability of the transistor.

<<First Display Element 750(i,j)>>

For example, a display element having a function of controlling transmission or reflection of light can be used as the first display element 750(i, j) or the like. For example, a combined structure of a polarizing plate and a liquid crystal element or a MEMS shutter display element can be used. Specifically, the use of a reflective display element can reduce power consumption of an input/output device or enables image display with favorable contrast in a bright environment. For example, a reflective liquid crystal display element can be used as the first display element 750.

For example, a liquid crystal element driven in any of the following driving modes can be used: an in-plane switching (IPS) mode, a twisted nematic (TN) mode, a fringe field switching (FFS) mode, an axially symmetric aligned micro-cell (ASM) mode, an optically compensated birefringence (OCB) mode, a ferroelectric liquid crystal (FLC) mode, an antiferroelectric liquid crystal (AFLC) mode, and the like.

In addition, a liquid crystal element that can be driven by, for example, a vertical alignment (VA) mode such as a multi-domain vertical alignment (MVA) mode, a patterned vertical alignment (PVA) mode, an electrically controlled birefringence (ECB) mode, a continuous pinwheel alignment (CPA) mode, or an advanced super view (ASV) mode can be used.

For example, thermotropic liquid crystal, low-molecular liquid crystal, high-molecular liquid crystal, polymer dispersed liquid crystal, ferroelectric liquid crystal, or anti-ferroelectric liquid crystal can be used. Alternatively, a liquid crystal material that exhibits a cholesteric phase, a smectic phase, a cubic phase, a chiral nematic phase, an isotropic phase, or the like can be used. Alternatively, a liquid crystal material that exhibits a blue phase can be used.

<<First Electrode 751(i,j)>>

For example, the material of the wiring or the like can be used for the first electrode 751(i, j). Specifically, a reflective film can be used for the first electrode 751(i, j).

### <<Reflective Film>>

For example, a material reflecting visible light can be used as the reflective film. Specifically, a material containing silver can be used for the reflective film. For example, a material containing silver and palladium or a material containing silver and copper can be used for the reflective film.

The reflective film reflects light that passes through the layer 753 containing a liquid crystal material. This allows the first display element 750 to serve as a reflective liquid crystal element. Alternatively, for example, a material with an uneven surface can be used for the reflective film. In that case, incident light can be reflected in various directions so that a white image can be displayed.

Note that other structures may be used as the reflective film without limitation to the first electrode 751(i, j). For example, a structure in which the reflective film lies between the layer 753 containing a liquid crystal material and the first electrode 751(i, j), or a structure in which the first electrode 751(i, j) having light-transmitting properties lies between the reflective film and the layer 753 containing a liquid crystal material can be used.

### <<Opening 751H>>

If the ratio of the total area of the opening 751H to the total area except for the opening is too large, display performed using the first display element 750(i, j) is dark. If the ratio of the total area of the opening 751H to the total area except for the opening is too small, display performed using the second display element 550(i, j) is dark.

If the area of the opening 751H in the reflective film is too small, light emitted from the second display element 550(i, j) is not efficiently extracted.

The opening 751H may have a polygonal shape, a quadrangular shape, an elliptical shape, a circular shape, a cross-like shape, a stripe shape, a slit-like shape, or a checkered pattern, for example. The opening 751H may be positioned close to an adjacent pixel. The opening 751H is preferably provided close to a pixel emitting light of the same color, in which case an undesired phenomenon in which light emitted from the second display element 550(i, j) enters a coloring film of the adjacent pixel, which is called cross talk, can be suppressed.

### <<Second Electrode 752>>

For example, a material having a visible-light transmitting property and conductivity can be used for the second electrode 752.

For example, a conductive oxide, a metal film thin enough to transmit light, or a metal nanowire can be used as the second electrode 752.

Specifically, a conductive oxide containing indium, a metal thin film whose thickness is more than or equal to 1 nm and less than or equal to 10 nm, or a metal nanowire containing silver can be used for the second electrode 752.

Specifically, indium oxide, indium tin oxide, indium zinc oxide, zinc oxide, zinc oxide to which gallium is added, zinc oxide to which aluminum is added, or the like can be used for the second electrode 752.

<<Control Line CL(g), Electrode C(g), Signal Line ML(h), Electrode M(h), Conductive Film BR(g, h)>>

For example, a material having a visible-light-transmitting property and conductivity can be used for the control line CL(g), the electrode C(g), the signal line ML(h), the electrode M(h), or the conductive film BR(g, h).

Specifically, a material used for the second electrode 752 can be used for the control line CL(g), the electrode C(g), the signal line ML(h), the electrode M(h), or the conductive film BR(g, h).

### <<Alignment Film AF1, Alignment Film AF2>>

For example, the alignment films AF1 and AF2 can be formed using a material containing polyimide or the like, such as a material formed to have alignment in a predetermined direction by a rubbing process or an optical alignment process.

For example, a film containing soluble polyimide can be used as the alignment film AF1 or AF2.

### <<Coloring Film CF1>>

The coloring film CF1 can be formed using a material transmitting light of a predetermined color, and can thus be used as a color filter, for example.

For example, the coloring film CF1 can be formed using a material transmitting light of blue, green, red, yellow, or white or the like.

### <<Light-Blocking Film BM>>

The light-blocking film BM can be formed using a material that prevents light transmission and can thus be used as a black matrix, for example.

### <<Insulating Film 771>>

The insulating film 771 can be formed using polyimide, an epoxy resin, an acrylic resin, or the like.

### <<Functional Film 770P, Functional Film 770D>>

For example, an anti-reflection film, a polarizing film, a retardation film, a light diffusion film, a condensing film, or the like can be used as the functional film 770P or the functional film 770D. Alternatively, a film containing a dichromatic pigment can be used as the functional film 770P.

Alternatively, an antistatic film preventing the attachment of a foreign substance, a water repellent film suppressing the attachment of stain, a hard coat film suppressing generation of a scratch in use, or the like can be used as the functional film 770P.

Specifically, a circularly polarizing film can be used as the functional film 770P. Furthermore, a light diffusion film can be used as the functional film 770D.

<<Second Display Element 550(i, j)>>

A light-emitting element, for example, can be used as the second display element 550(i, j). Specifically, an organic electroluminescence element, an inorganic electroluminescence element, a light-emitting diode, or the like can be used as the second display element 550(i, j). Thus, an image can be displayed with favorable color reproducibility.

For example, a light-emitting organic compound can be used for the layer 553(j) containing a light-emitting material. Alternatively, quantum dots can be used for the layer 553(j) containing a light-emitting material. Accordingly, the half width becomes narrow, and light of a bright color can be emitted.

For example, a stacked body for emitting blue light, green light, or red light can be used as the layer 553(j) containing a light-emitting material.

For example, a belt-like stacked body extending in the column direction along the signal line S1(j) can be used for the layer 553(j) containing a light-emitting material. Furthermore, a belt-like stacked body that extends in the column direction along the signal line S1(j+1) and emits light of a color different from that of light emitted from the layer 553(j) containing a light-emitting material can be used for a layer 553(j+1) containing a light-emitting material.

For example, a stacked body for emitting white light can be used as the layer 553(j) containing a light-emitting material and the layer 553(j+1) containing a light-emitting material. Specifically, a stacked body of a layer containing a light-emitting material containing a fluorescent material that emits blue light, a layer containing a material that is other than a fluorescent material and that emits green light and red light, or a layer containing a material that is other than a fluorescent material and that emits yellow light can be used as the layer 553(j) containing a light-emitting material and the layer 553(j+1) containing a light-emitting material.

For example, a material that can be used for the wiring or the like can be used for the third electrode 551(i, j) or the fourth electrode 552.

For example, a material that transmits visible light and can be used for the wiring or the like can be used for the third electrode 551(i, j).

Specifically, conductive oxide, indium-containing conductive oxide, indium oxide, indium tin oxide, indium zinc oxide, zinc oxide, zinc oxide to which gallium is added, or the like can be used for the third electrode 551(i, j). Alternatively, a metal film that is thin enough to transmit light can be used as the third electrode 551(i, j).

For example, a material that reflects visible light and can be used for the wiring or the like can be used for the fourth electrode 552.

<<Sensing Element 775(g, h)>>

For example, an element that senses electrostatic capacitance, illuminance, magnetic force, a radio wave, pressure, or the like and supplies data based on the sensed physical value can be used as the sensing element 775(g, h).

Specifically, a capacitor, a photoelectric conversion element, a magnetic sensing element, a piezoelectric element, a resonator, or the like can be used as the sensing element 775(g, h).

For example, when an object that has a higher dielectric constant than the air, such as a finger, approaches the conductive film in the air, electrostatic capacitance between the finger and the conductive film changes. This electrostatic capacitance change is sensed, and the sensed data can be supplied. Specifically, a self-capacitive sensing element can be used.

For example, the control line CL(g) and the signal line ML(h) can be used for the sensing element 775(g, h). Specifically, the control line CL(g) to which the search signal is supplied and the signal line ML(h) that is provided so that an electric field that is partly blocked by an approaching object is formed between the signal line ML(h) and the control line CL(g) can be used. Thus, the electric field that is blocked by the approaching object and changed can be sensed using the potential of the signal line ML(h), and a sensor signal is supplied. As a result, the approaching object that blocks the electric field can be sensed. Specifically, a mutual capacitive sensing element can be used.

### <<Driver Circuit GD>>

Any of a variety of sequential circuits, such as a shift register, can be used as the driver circuit GD. For example, the transistor MDE, a capacitor, and the like can be used in the driver circuit GD. Specifically, a transistor including a semiconductor film that can be formed in a process different from that of the transistor ME can be used.

A transistor having a different structure from the transistor that can be used as the switch SW1 can be used as the transistor MDE (see FIG. 2C).

### <<Driver Circuit SD>>

For example, an integrated circuit can be used in the driver circuit SD. Specifically, an integrated circuit formed on a silicon substrate can be used as the driver circuit SD.

For example, a chip on glass (COG) method can be used to mount the driver circuit SD on a pad electrically connected to the pixel circuit 530(i, j). Specifically, an anisotropic conductive film can be used to mount the integrated circuit on the pad.

Note that the pad can be formed in the same step as the terminal 519B or 519C.

### <<Oscillator Circuit OSC, Detection Circuit DC>>

For example, an integrated circuit can be used in the oscillator circuit OSC or the detection circuit DC. Specifically, an integrated circuit formed on a silicon substrate can be used as the oscillator circuit OSC or the detection circuit DC.

For example, a chip on glass (COG) method can be used to mount the oscillator circuit OSC or the detection circuit DC on a pad electrically connected to the sensing element 775(g, h). Specifically, an anisotropic conductive film can be used to mount the integrated circuit on the pad.

### Structure Example 2 of Input/Output Device

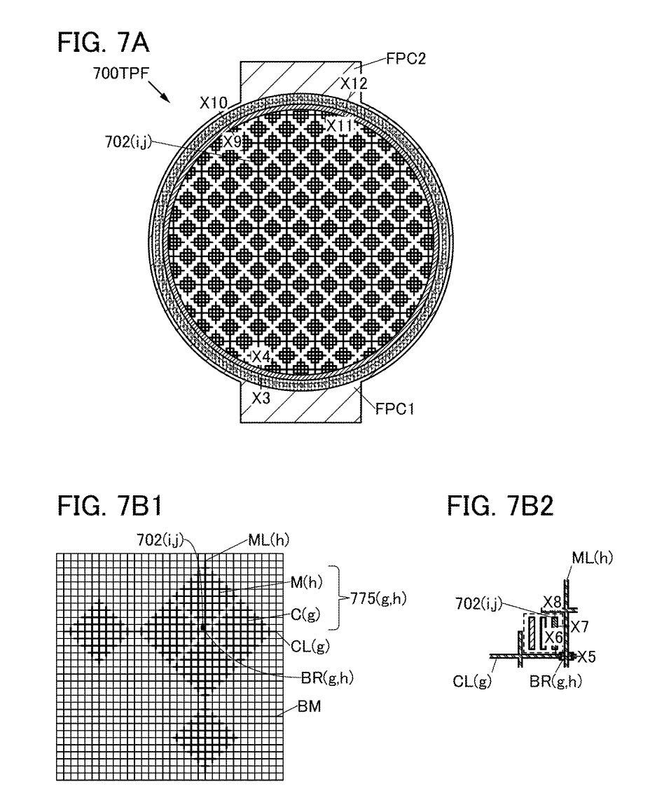

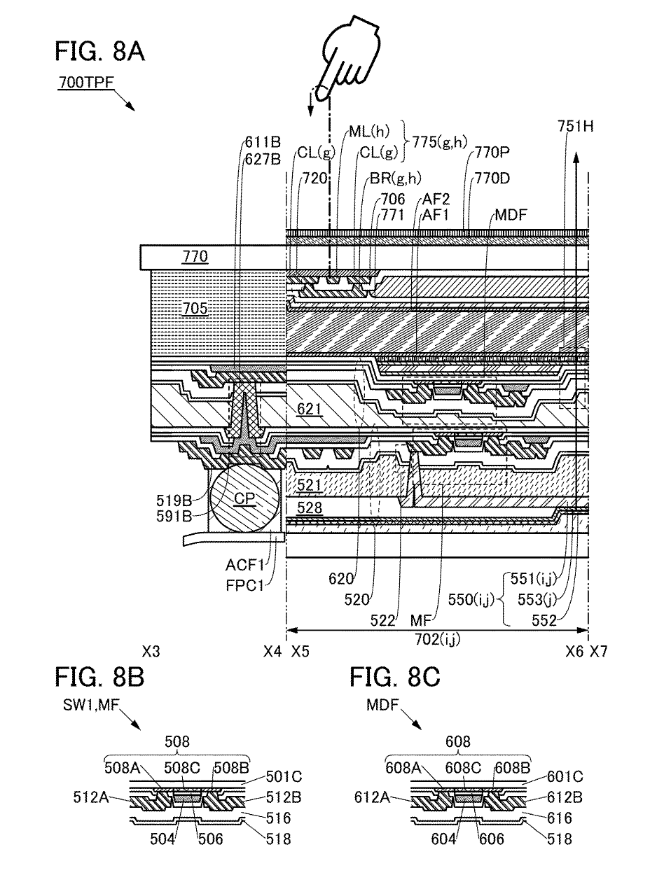

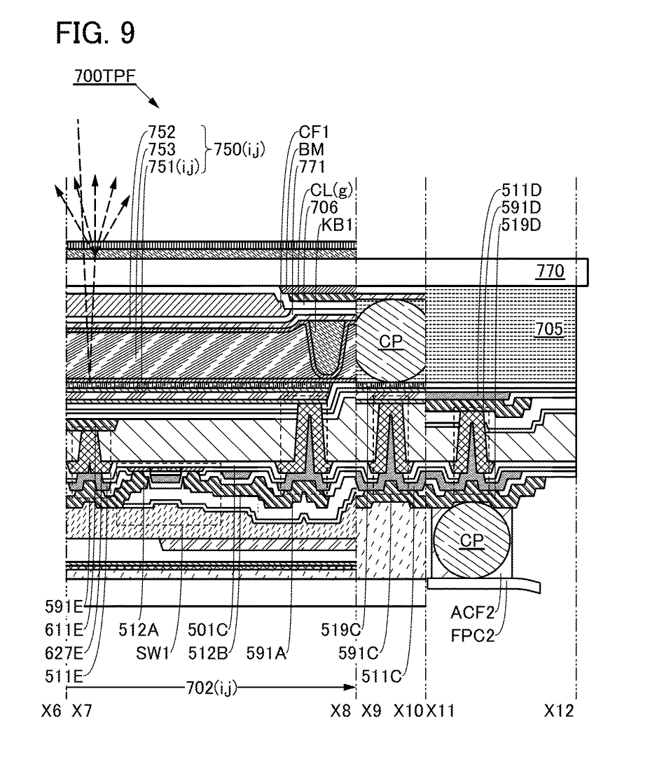

Another structure of the input/output device of one embodiment of the present invention is described with reference to FIGS. 7A, 7B1, and 7B2, FIGS. 8A to 8C, and FIG. 9.

FIGS. 7A, 7B1, and 7B2 illustrate a structure of an input/output device 700TPF of one embodiment of the present invention. FIG. 7A is a top view of the input/output device of one embodiment of the present invention. FIG. 7B1 is a schematic diagram illustrating part of the input portion of the input/output device of one embodiment of the present invention. FIG. 7B2 is a schematic diagram illustrating part of FIG. 7B1.

FIGS. 8A to 8C and FIG. 9 are cross-sectional views illustrating a structure of the input/output device of one embodiment of the present invention. FIG. 8A is a cross-sectional view taken along the cutting plane line X3-X4 in FIG. 7A and the cutting plane line X5-X6 in FIG. 7B2, FIG. 8B illustrates part of FIG. 8A, and FIG. 8C illustrates another part of FIG. 8A.

FIG. 9 is a cross-sectional view taken along the cutting plane line X7-X8 in FIG. 7B2 and cutting plane lines X9-X10 and X11-X12 in FIG. 7A.

Note that the input/output device 700TPF is different from the input/output device 700TPE, which is described with reference to FIGS. 1A, 1B1, and 1B2, FIGS. 2A to 2C, FIGS. 3A and 3B, FIG. 4, and FIGS. 5A, 5B1, and 5B2, in that the functional layer 520 includes a top-gate transistor; the functional layer 720 including an input portion is included in a region surrounded by the substrate 770, the insulating film 501C, and the sealant 705; the electrode C(g) electrically connected to the control line CL(g) is provided with an opening in a region overlapping with a pixel; the electrode M(h) electrically connected to the signal line ML(h) is provided with an opening in a region overlapping with the pixel; a conductive film 511D electrically connected to the control line CL(g) or the signal line ML(h) is included; a terminal 519D electrically connected to the conductive film 511D is included; and the functional layer 620 includes the driver circuit SD. The different portions are described in detail below, and the above description is referred to for the other portions capable of using similar structures.

In the input/output device 700TPF described in this embodiment, the electrode C(g) includes the conductive film provided with the opening, and the electrode M(h) includes the conductive film provided with the opening. The openings include the regions overlapping with the pixel. For example, the opening of the conductive film included in the electrode C(g) includes a region overlapping with the pixel 702(i, j) (see FIG. 7B1, FIG. 7B2, and FIG. 8A). Note that the input/output device 700TPF further includes the light-blocking film BM between the sensing element 775(g, h) and the substrate 770 (see FIG. 8A). The light-blocking film BM has an opening in a region overlapping with the first display element 750(i, j). Moreover, the light-blocking film BM has a region overlapping with the sensing element 775(g, h).

In the input/output device 700TPF described in this embodiment, the gap between the electrode C(g) and the second electrode 752 or the gap between the electrode M(h) and the second electrode 752 is more than or equal to 0.2 μm and less than or equal to 16 μm, preferably more than or equal to 1 μm and less than or equal to 8 μm, further preferably more than or equal to 2.5 μm and less than or equal to 4 μm.

Since the input/output device of one embodiment of the present invention includes the electrode including the conductive film provided with the opening in the region overlapping with the pixel, an object that comes in the vicinity of the region overlapping with the display portion can be sensed without disturbing display of the display portion. Moreover, the thickness of the input/output device can be reduced. As a result, a novel input/output device that is highly convenient or reliable can be provided.

In the input/output device described in this embodiment, the functional layer 720 is included in a region surrounded by the substrate 770, the insulating film 501C, and the sealant 705. Thus, the input/output device can be formed without using the substrate 710 and the bonding layer 709.

Furthermore, the input/output device described in this embodiment includes the conductive film 511D electrically connected to the control line CL(g) or the signal line ML(h).

Moreover, the input/output device described in this embodiment includes the terminal 519D electrically connected to the conductive film 511D. Note that for example, the terminal 519D can be electrically connected to a flexible printed circuit FPC2 using a conductive material ACF2, for example.

### <<Conductive Film 511D>>

For example, a material that can be used for a wiring or the like can be used for the conductive film 511D.

Note that the control line CL(g) and the conductive film 511D can be electrically connected to each other using a conductive material or the like provided between the control line CL(g) and the conductive film 511D. Alternatively, the signal line ML(h) and the conductive film 511D can be electrically connected to each other using a conductive material or the like provided between the signal line ML(h) and the conductive film 511D.

### <<Terminal 519D>>

For example, a material that can be used for a wiring or the like can be used for the terminal 519D. Specifically, the terminal 519D can have the same structure as that of the terminal 519B or the terminal 519C. Note that for example, the terminal 519D can be electrically connected to the flexible printed circuit FPC 2 using the conductive material ACF2.

Note that a search signal can be supplied to the control line CL(g) using the terminal 519D electrically connected to the conductive film 511D. Alternatively, a sensor signal can be supplied from the signal line ML(h).

### <<Switch SW1, Transistor MF>>

A transistor that can be used as the switch SW1 and the transistor MF include the conductive film 504 including a region overlapping with the insulating film 501C and the semiconductor film 508 including a region between the insulating film 501C and the conductive film 504. Note that the conductive film 504 functions as a gate electrode (see FIG. 8B).

The semiconductor film 508 includes a first region 508A, a second region 508B, and a third region 508C. The first region 508A and the second region 508B do not overlap with the conductive film 504. The third region 508C lies between the first region 508A and the second region 508B and overlaps with the conductive film 504.

The transistor MF includes the insulating film 506 between the third region 508C and the conductive film 504. Note that the insulating film 506 functions as a gate insulating film.

The first region 508A and the second region 508B have a lower resistivity than the third region 508C, and function as a source region and a drain region.

Note that, for example, a method for controlling the resistivity of the oxide semiconductor, which is described in the end of this embodiment, can be used as a method for forming the first region 508A and the second region 508B in the semiconductor film 508. Specifically, plasma treatment using a gas containing a rare gas can be employed.

For example, the conductive film 504 can be used as a mask, in which case a part of the third region 508C can be self-aligned to an end portion of the conductive film 504.

The transistor MF includes the conductive films 512A and 512B that are in contact with the first region 508A and the second region 508B, respectively. The conductive film 512A and the conductive film 512B function as a source electrode and a drain electrode.

The transistor that can be formed in the same process as the transistor MF can be used as the switch SW1.

### <<Transistor MDF>>

For example, a transistor including the semiconductor film 608, the conductive film 604, the insulating film 606, the conductive film 612A, and the conductive film 612B can be used as the transistor MDF (see FIG. 8C).

The conductive film 604 includes a region overlapping with the semiconductor film 608 and has a function of a gate electrode. The insulating film 606 includes a region sandwiched between the semiconductor film 608 and the conductive film 604 and has a function of a gate insulating film.

The semiconductor film 608 includes the first region 608A, the second region 608B, and the third region 608C. The third region 608C is sandwiched between the first region 608A and the second region 608B and includes a region overlapping with the conductive film 604. The first region 608A includes a region not overlapping with the conductive film 604, and the second region 608B includes a region not overlapping with the conductive film 604. The first region 608A and the second region 608B have a lower resistivity than the third region 608C, and function as a source region and a drain region.

The conductive film 612A is electrically connected to the first region 608A of the semiconductor film 608 and has a function of one of a source electrode and a drain electrode. The conductive film 612B is electrically connected to the second region 608B of the semiconductor film 608 and has a function of the other of the source electrode and the drain electrode.

Specifically, polysilicon or single crystal silicon can be used for the semiconductor film 608. This can increase the current drive capability of the transistor.

### <Method for Controlling Resistivity of Oxide Semiconductor>

A method for controlling the resistivity of an oxide semiconductor film will be described.

An oxide semiconductor film with a certain resistivity can be used as the semiconductor film 508, the conductive film 524, or the like.

For example, a method for controlling the concentration of impurities such as hydrogen and water contained in the oxide semiconductor film and/or the oxygen vacancies in the film can be used as the method for controlling the resistivity of an oxide semiconductor.

Specifically, plasma treatment can be used as a method for increasing or decreasing the concentration of impurities such as hydrogen and water and/or the oxygen vacancies in the film.

Specifically, plasma treatment using a gas containing one or more kinds selected from a rare gas (He, Ne, Ar, Kr, or Xe), hydrogen, boron, phosphorus, and nitrogen can be employed. For example, plasma treatment in an Ar atmosphere, plasma treatment in a mixed gas atmosphere of Ar and hydrogen, plasma treatment in an ammonia atmosphere, plasma treatment in a mixed gas atmosphere of Ar and ammonia, or plasma treatment in a nitrogen atmosphere can be employed. Thus, the oxide semiconductor film can have a high carrier density and a low resistivity.

Alternatively, hydrogen, boron, phosphorus, or nitrogen is added to the oxide semiconductor film by an ion implantation method, an ion doping method, a plasma immersion ion implantation method, or the like, so that the oxide semiconductor film can have a low resistivity.

Alternatively, an insulating film containing hydrogen is formed in contact with the oxide semiconductor film, and the hydrogen is diffused from the insulating film to the oxide semiconductor film, so that the oxide semiconductor film can have a high carrier density and a low resistivity.

For example, an insulating film with a hydrogen concentration of greater than or equal to 1×10²² atoms/cm³ is formed in contact with the oxide semiconductor film, whereby hydrogen can be effectively supplied to the oxide semiconductor film. Specifically, a silicon nitride film can be used as the insulating film formed in contact with the oxide semiconductor film.

Hydrogen contained in the oxide semiconductor film reacts with oxygen bonded to a metal atom to be water, and an oxygen vacancy is formed in a lattice from which oxygen is released (or a portion from which oxygen is released). Due to entry of hydrogen into the oxygen vacancy, an electron serving as a carrier is generated in some cases. Furthermore, bonding of part of hydrogen to oxygen bonded to a metal atom causes generation of an electron serving as a carrier in some cases. Thus, the oxide semiconductor film can have a high carrier density and a low resistivity.

Specifically, an oxide semiconductor with a hydrogen concentration measured by secondary ion mass spectrometry (SIMS) of greater than or equal to 8×10¹⁹ atoms/cm³, preferably greater than or equal to 1×10²⁰ atoms/cm³, further preferably greater than or equal to 5×10²⁰ atoms/cm³ can be suitably used for the conductive film 524.

Meanwhile, an oxide semiconductor with a high resistivity can be used for a semiconductor film where a channel of a transistor is formed, specifically, the semiconductor film 508.

For example, an insulating film containing oxygen, in other words, an insulating film capable of releasing oxygen, is formed in contact with an oxide semiconductor film, and the oxygen is supplied from the insulating film to the oxide semiconductor film, so that oxygen vacancies in the film or at the interface can be filled. Thus, the oxide semiconductor film can have a high resistivity.

For example, a silicon oxide film or a silicon oxynitride film can be used as the insulating film capable of releasing oxygen.

The oxide semiconductor film in which oxygen vacancies are filled and the hydrogen concentration is reduced can be referred to as a highly purified intrinsic or substantially highly purified intrinsic oxide semiconductor film. The term “substantially intrinsic” refers to the state in which an oxide semiconductor film has a carrier density lower than 8×10¹¹/cm³, preferably lower than 1×10¹¹/cm³, further preferably lower than 1×10¹⁰/cm³. A highly purified intrinsic or substantially highly purified intrinsic oxide semiconductor film has few carrier generation sources and thus can have a low carrier density. The highly purified intrinsic or substantially highly purified intrinsic oxide semiconductor film has a low density of defect states and accordingly can have a low density of trap states.

Furthermore, a transistor including the highly purified intrinsic or substantially highly purified intrinsic oxide semiconductor film has an extremely low off-state current; even when an element has a channel width of 1×10⁶ μm and a channel length L of 10 μm, the off-state current can be lower than or equal to the measurement limit of a semiconductor parameter analyzer, that is, lower than or equal to 1×10⁻¹³ A, at a voltage (drain voltage) between a source electrode and a drain electrode of from 1 V to 10 V.

The transistor in which a channel region is formed in the oxide semiconductor film that is a highly purified intrinsic or substantially highly purified intrinsic oxide semiconductor film can have a small change in electrical characteristics and high reliability.

Specifically, an oxide semiconductor whose hydrogen concentration measured by secondary ion mass spectrometry (SIMS) is lower than or equal to 2×10²⁰ atoms/cm³, preferably lower than or equal to 5×10¹⁹ atoms/cm³, further preferably lower than or equal to 1×10¹⁹ atoms/cm³, further preferably lower than 5×10¹⁸ atoms/cm³, further preferably lower than or equal to 1×10¹⁸ atoms/cm³, further preferably lower than or equal to 5×10¹⁷ atoms/cm³, further preferably lower than or equal to 1×10¹⁶ atoms/cm³ can be favorably used as a semiconductor where a channel of a transistor is formed.

Note that an oxide semiconductor film that has a higher hydrogen concentration and/or a larger number of oxygen vacancies and that has a lower resistivity than the semiconductor film 508 is used as the conductive film 524.

A film whose hydrogen concentration is twice or more, preferably ten times or more that of the semiconductor film 508 can be used as the conductive film 524.

A film whose resistivity is greater than or equal to 1×10⁻⁸ times and less than 1×10⁻¹ times that of the semiconductor film 508 can be used as the conductive film 524.

Specifically, a film whose resistivity is higher than or equal to 1×10⁻³ Ωcm and lower than 1×10⁴ Ωcm, preferably higher than or equal to 1×10⁻³ Ωcm and lower than 1×10⁻¹ Ωcm can be used as the conductive film 524.

Note that this embodiment can be combined with any of the other embodiments in this specification as appropriate.

### Embodiment 2

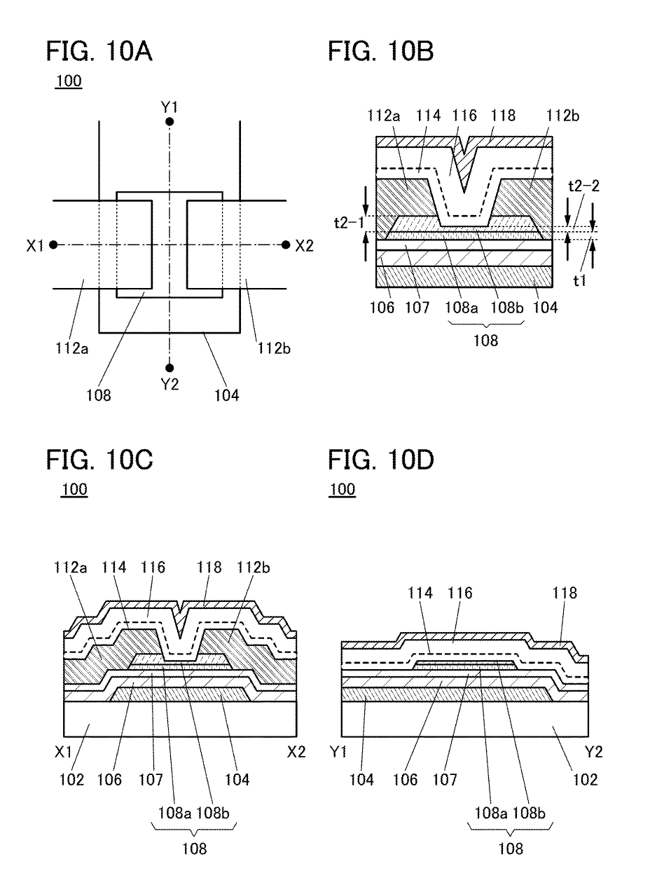

In this embodiment, the structure of a transistor that can be used for the input/output device of one embodiment of the present invention is described with reference to FIGS. 10A to 10D.

### Structural Example of Semiconductor Device

FIG. 10A is a top view of a transistor 100. FIG. 10C is a cross-sectional view taken along the cutting plane line X1-X2 in FIG. 10A. FIG. 10D is a cross-sectional view taken along the cutting plane line Y1-Y2 in FIG. 10A. Note that in FIG. 10A, some components of the transistor 100 (e.g., an insulating film serving as a gate insulating film) are not illustrated to avoid complexity. In some cases, the direction of the cutting plane line X1-X2 is referred to as a channel length direction and the direction of the cutting plane line Y1-Y2 is referred to as a channel width direction. As in FIG. 10A, some components might not be illustrated in some top views of transistors described below.

Note that the transistor 100 can be used in the input/output device or the like described in Embodiment 1.

For example, when the transistor 100 is used as the switch SW1, a substrate 102, a conductive film 104, a stacked film of an insulating film 106 and an insulating film 107, an oxide semiconductor film 108, a conductive film 112a, a conductive film 112b, a stacked film of an insulating film 114 and an insulating film 116, and an insulating film 118 can be referred to as the insulating film 501C, the conductive film 504, the insulating film 506, the semiconductor film 508, the conductive film 512A, the conductive film 512B, the insulating film 516, and the insulating film 518, respectively.

The transistor 100 includes the conductive film 104 functioning as a gate electrode over the substrate 102, the insulating film 106 over the substrate 102 and the conductive film 104, the insulating film 107 over the insulating film 106, the oxide semiconductor film 108 over the insulating film 107, and the conductive films 112a and 112b functioning as source and drain electrodes electrically connected to the oxide semiconductor film 108. Over the transistor 100, specifically, over the conductive films 112a and 112b and the oxide semiconductor film 108, the insulating films 114, 116, and 118 are provided. The insulating films 114, 116, and 118 function as protective insulating films for the transistor 100.

The oxide semiconductor film 108 includes an oxide semiconductor film 108a on the conductive film 104 side and an oxide semiconductor film 108b over the oxide semiconductor film 108a. The conductive film 104 serves as a gate electrode. Furthermore, the insulating films 106 and 107 function as gate insulating films of the transistor 100.

An In-M oxide (M is Ti, Ga, Sn, Y, Zr, La, Ce, Nd, or Hf) or an In-M-Zn oxide can be used for the oxide semiconductor film 108. It is particularly preferable to use an In-M-Zn oxide for the oxide semiconductor film 108.

The oxide semiconductor film 108a includes a first region in which the atomic proportion of In is larger than the atomic proportion of M. The oxide semiconductor film 108b includes a second region in which the atomic proportion of In is smaller than that in the oxide semiconductor film 108a. The second region includes a portion thinner than the first region.

The oxide semiconductor film 108a including the first region in which the atomic proportion of In is larger than that of M can increase the field-effect mobility (also simply referred to as mobility or μFE) of the transistor 100. Specifically, the field-effect mobility of the transistor 100 can exceed 10 cm²/Vs.

For example, the use of the transistor with high field-effect mobility for a gate driver that generates a gate signal (specifically, a demultiplexer connected to an output terminal of a shift register included in a gate driver) allows a semiconductor device or a display device to have a narrow frame.

On the other hand, the oxide semiconductor film 108a including the first region in which the atomic proportion of In is larger than that of M makes it easier to change electrical characteristics of the transistor 100 in light irradiation. However, in the semiconductor device of one embodiment of the present invention, the oxide semiconductor film 108b is formed over the oxide semiconductor film 108a. In addition, the thickness of the channel region in the oxide semiconductor film 108b is smaller than the thickness of the oxide semiconductor film 108a.

Furthermore, the oxide semiconductor film 108b includes the second region in which the atomic proportion of In is smaller than that in the oxide semiconductor film 108a and thus has larger Eg than the oxide semiconductor film 108a. For this reason, the oxide semiconductor film 108 that is a layered structure of the oxide semiconductor film 108a and the oxide semiconductor film 108b has high resistance to a negative bias stress test with light irradiation.

The amount of light absorbed by the oxide semiconductor film 108 can be reduced during light irradiation. As a result, the change in electrical characteristics of the transistor 100 due to light irradiation can be reduced. In the semiconductor device of one embodiment of the present invention, the insulating film 114 or the insulating film 116 includes excess oxygen. This structure can further reduce the change in electrical characteristics of the transistor 100 due to light irradiation.

Here, the oxide semiconductor film 108 is described in detail with reference to FIG. 10B.

FIG. 10B is a cross-sectional enlarged view of the oxide semiconductor film 108 and the vicinity thereof in the transistor 100 illustrated in FIG. 10C.

In FIG. 10B, t1, t2-1, and t2-2 denote a thickness of the oxide semiconductor film 108a, one thickness of the oxide semiconductor film 108b, and the other thickness of the oxide semiconductor film 108b, respectively. The oxide semiconductor film 108b over the oxide semiconductor film 108a prevents the oxide semiconductor film 108a from being exposed to an etching gas, an etchant, or the like when the conductive films 112a and 112b are formed. This is why the oxide semiconductor film 108a is not or is hardly reduced in thickness. In contrast, in the oxide semiconductor film 108b, a portion not overlapping with the conductive films 112a and 112b is etched by formation of the conductive films 112a and 112b, so that a depression is formed in the etched region. In other words, a thickness of the oxide semiconductor film 108b in a region overlapping with the conductive films 112a and 112b is t2-1, and a thickness of the oxide semiconductor film 108b in a region not overlapping with the conductive films 112a and 112b is t2-2.

As for the relationships between the thicknesses of the oxide semiconductor film 108a and the oxide semiconductor film 108b, t2-1>t1>t2-2 is preferable. A transistor with the thickness relationships can have high field-effect mobility and less variation in threshold voltage in light irradiation.

When oxygen vacancies are formed in the oxide semiconductor film 108 included in the transistor 100, electrons serving as carriers are generated; as a result, the transistor 100 tends to be normally-on. Therefore, for stable transistor characteristics, it is important to reduce oxygen vacancies in the oxide semiconductor film 108, particularly oxygen vacancies in the oxide semiconductor film 108a. In the structure of the transistor of one embodiment of the present invention, excess oxygen is introduced into an insulating film over the oxide semiconductor film 108, here, the insulating film 114 and/or the insulating film 116 over the oxide semiconductor film 108, whereby oxygen is moved from the insulating film 114 and/or the insulating film 116 to the oxide semiconductor film 108 to fill oxygen vacancies in the oxide semiconductor film 108, particularly in the oxide semiconductor film 108a.

Note that it is preferable that the insulating films 114 and 116 each include a region (oxygen excess region) including oxygen in excess of that in the stoichiometric composition. In other words, the insulating films 114 and 116 are insulating films capable of releasing oxygen. Note that the oxygen excess region is formed in the insulating films 114 and 116 in such a manner that oxygen is introduced into the insulating films 114 and 116 after the deposition, for example. As a method for introducing oxygen, an ion implantation method, an ion doping method, a plasma immersion ion implantation method, plasma treatment, or the like may be employed.

In order to fill oxygen vacancies in the oxide semiconductor film 108a, the thickness of the portion including the channel region and the vicinity of the channel region in the oxide semiconductor film 108b is preferably small, and t2-2<t1 is preferably satisfied. For example, the thickness of the portion including the channel region and the vicinity of the channel region in the oxide semiconductor film 108b is preferably more than or equal to 1 nm and less than or equal to 20 nm, further preferably more than or equal to 3 nm and less than or equal to 10 nm.

Other constituent elements of the semiconductor device of this embodiment are described below in detail.

### <<Substrate>>

There is no particular limitation on the property of a material and the like of the substrate 102 as long as the material has heat resistance enough to withstand at least heat treatment to be performed later. For example, a glass substrate, a ceramic substrate, a quartz substrate, or a sapphire substrate may be used as the substrate 102.

Alternatively, a single crystal semiconductor substrate or a polycrystalline semiconductor substrate of silicon or silicon carbide, a compound semiconductor substrate of silicon germanium, an SOI substrate, or the like can be used.

Alternatively, any of these substrates provided with a semiconductor element, an insulating film, or the like may be used as the substrate 102.

Note that in the case where a glass substrate is used as the substrate 102, a large substrate having any of the following sizes can be used: the 6th generation (1500 mm×1850 mm), the 7th generation (1870 mm×2200 mm), the 8th generation (2200 mm×2400 mm), the 9th generation (2400 mm×2800 mm), and the 10th generation (2950 mm×3400 mm). Thus, a large display device can be manufactured.

Alternatively, a flexible substrate may be used as the substrate 102, and the transistor 100 may be provided directly on the flexible substrate. Alternatively, a separation layer may be provided between the substrate 102 and the transistor 100. The separation layer can be used when part or the whole of a semiconductor device formed over the separation layer is separated from the substrate 102 and transferred onto another substrate. In such a case, the transistor 100 can be transferred to a substrate having low heat resistance or a flexible substrate as well.

### <<Conductive Film Functioning as Gate Electrode, Source Electrode, and Drain Electrode>>

The conductive film 104 functioning as a gate electrode and the conductive films 112a and 112b functioning as a source electrode and a drain electrode, respectively, can each be formed using a metal element selected from chromium (Cr), copper (Cu), aluminum (Al), gold (Au), silver (Ag), zinc (Zn), molybdenum (Mo), tantalum (Ta), titanium (Ti), tungsten (W), manganese (Mn), nickel (Ni), iron (Fe), and cobalt (Co); an alloy including any of these metal elements as its component; an alloy including a combination of any of these metal elements; or the like.

Furthermore, the conductive films 104, 112a, and 112b may have a single-layer structure or a stacked-layer structure of two or more layers. For example, a single-layer structure of an aluminum film including silicon, a two-layer structure in which a titanium film is stacked over an aluminum film, a two-layer structure in which a titanium film is stacked over a titanium nitride film, a two-layer structure in which a tungsten film is stacked over a titanium nitride film, a two-layer structure in which a tungsten film is stacked over a tantalum nitride film or a tungsten nitride film, and a three-layer structure in which a titanium film, an aluminum film, and a titanium film are stacked in this order can be given. Alternatively, an alloy film or a nitride film in which aluminum and one or more elements selected from titanium, tantalum, tungsten, molybdenum, chromium, neodymium, and scandium are combined may be used.

The conductive films 104, 112a, and 112b can be formed using a light-transmitting conductive material such as indium tin oxide, indium oxide including tungsten oxide, indium zinc oxide including tungsten oxide, indium oxide including titanium oxide, indium tin oxide including titanium oxide, indium zinc oxide, or indium tin oxide to which silicon oxide is added.

A Cu—X alloy film (X is Mn, Ni, Cr, Fe, Co, Mo, Ta, or Ti) may be used for the conductive films 104, 112a, and 112b. Use of a Cu—X alloy film enables the manufacturing cost to be reduced because wet etching process can be used in the processing.

### <<Insulating Film Functioning as Gate Insulating Film>>

As each of the insulating films 106 and 107 functioning as gate insulating films of the transistor 100, an insulating film including at least one of the following films formed by a plasma enhanced chemical vapor deposition (PECVD) method, a sputtering method, or the like can be used: a silicon oxide film, a silicon oxynitride film, a silicon nitride oxide film, a silicon nitride film, an aluminum oxide film, a hafnium oxide film, an yttrium oxide film, a zirconium oxide film, a gallium oxide film, a tantalum oxide film, a magnesium oxide film, a lanthanum oxide film, a cerium oxide film, and a neodymium oxide film. Note that instead of a stacked-layer structure of the insulating films 106 and 107, an insulating film of a single layer formed using a material selected from the above or an insulating film of three or more layers may be used.

The insulating film 106 has a function of a blocking film that inhibits penetration of oxygen. For example, in the case where excess oxygen is supplied to the insulating film 107, the insulating film 114, the insulating film 116, and/or the oxide semiconductor film 108, the insulating film 106 can inhibit penetration of oxygen.

Note that the insulating film 107 that is in contact with the oxide semiconductor film 108 functioning as a channel region of the transistor 100 is preferably an oxide insulating film and preferably includes a region including oxygen in excess of the stoichiometric composition (oxygen-excess region). In other words, the insulating film 107 is an insulating film capable of releasing oxygen. In order to provide the oxygen excess region in the insulating film 107, the insulating film 107 is formed in an oxygen atmosphere, for example. Alternatively, the oxygen excess region may be formed by introduction of oxygen into the insulating film 107 after the deposition. As a method for introducing oxygen, an ion implantation method, an ion doping method, a plasma immersion ion implantation method, plasma treatment, or the like may be employed.

In the case where hafnium oxide is used for the insulating film 107, the following effect is attained. Hafnium oxide has a higher dielectric constant than silicon oxide and silicon oxynitride. Therefore, by using hafnium oxide, the thickness of the insulating film 107 can be made large as compared with the case where silicon oxide is used; thus, leakage current due to tunnel current can be low. That is, it is possible to provide a transistor with a low off-state current. Moreover, hafnium oxide with a crystalline structure has higher dielectric constant than hafnium oxide with an amorphous structure. Therefore, it is preferable to use hafnium oxide with a crystalline structure in order to provide a transistor with a low off-state current. Examples of the crystalline structure include a monoclinic crystal structure and a cubic crystal structure. Note that one embodiment of the present invention is not limited thereto.

In this embodiment, a silicon nitride film is formed as the insulating film 106, and a silicon oxide film is formed as the insulating film 107. The silicon nitride film has a higher dielectric constant than a silicon oxide film and needs a larger thickness for electrostatic capacitance equivalent to that of the silicon oxide film. Thus, when the silicon nitride film is included in the gate insulating film of the transistor 100, the physical thickness of the insulating film can be increased. This makes it possible to reduce a decrease in withstand voltage of the transistor 100 and furthermore to increase the withstand voltage, thereby reducing electrostatic discharge damage to the transistor 100.

### <<Oxide Semiconductor Film>>

The oxide semiconductor film 108 can be formed using the materials described above.

In the case where the oxide semiconductor film 108 includes In-M-Zn oxide, it is preferable that the atomic ratio of metal elements of a sputtering target used for forming the In-M-Zn oxide satisfy In≧M and Zn≧M. As the atomic ratio of metal elements of such a sputtering target, In:M:Zn=1:1:1, In:M:Zn=1:1:1.2, In:M:Zn=2:1:3, In:M:Zn=3:1:2, and In:M:Zn=4:2:4.1 are preferable.

In the case where the oxide semiconductor film 108 includes In-M-Zn oxide, it is preferable to use a target including polycrystalline In-M-Zn oxide as the sputtering target. The use of the target including polycrystalline In-M-Zn oxide facilitates formation of the oxide semiconductor film 108 having crystallinity. Note that the atomic ratios of metal elements in the formed oxide semiconductor film 108 vary from the above atomic ratio of metal elements of the sputtering target within a range of ±40% as an error. For example, when a sputtering target with an atomic ratio of In to Ga and Zn of 4:2:4.1 is used, the atomic ratio of In to Ga and Zn in the formed oxide semiconductor film 108 may be 4:2:3 or in the vicinity of 4:2:3.

The oxide semiconductor film 108a can be formed using the sputtering target having an atomic ratio of In:M:Zn=2:1:3, In:M:Zn=3:1:2, or In:M:Zn=4:2:4.1. The oxide semiconductor film 108b can be formed using the sputtering target having an atomic ratio of In:M:Zn=1:1:1 or In:M:Zn=1:1:1.2. Note that the atomic ratio of metal elements in a sputtering target used for forming the oxide semiconductor film 108b does not necessarily satisfy In≧M and Zn≧M, and may satisfy In≧M and Zn<M, such as In:M:Zn=1:3:2.

The energy gap of the oxide semiconductor film 108 is 2 eV or more, preferably 2.5 eV or more, further preferably 3 eV or more. The use of an oxide semiconductor having a wide energy gap can reduce off-state current of the transistor 100. In particular, an oxide semiconductor film having an energy gap more than or equal to 2 eV, preferably more than or equal to 2 eV and less than or equal to 3.0 eV is preferably used as the oxide semiconductor film 108a, and an oxide semiconductor film having an energy gap more than or equal to 2.5 eV and less than or equal to 3.5 eV is preferably used as the oxide semiconductor film 108b. Furthermore, the oxide semiconductor film 108b preferably has a higher energy gap than that of the oxide semiconductor film 108a.

Each thickness of the oxide semiconductor film 108a and the oxide semiconductor film 108b is more than or equal to 3 nm and less than or equal to 200 nm, preferably more than or equal to 3 nm and less than or equal to 100 nm, further preferably more than or equal to 3 nm and less than or equal to 50 nm. Note that the above-described thickness relationships between them are preferably satisfied.

An oxide semiconductor film with low carrier density is used as the oxide semiconductor film 108b. For example, the carrier density of the oxide semiconductor film 108b is lower than or equal to 1×10¹⁷/cm³, preferably lower than or equal to 1×10¹⁵/cm³, further preferably lower than or equal to 1×10¹³/cm³, still further preferably lower than or equal to 1×10¹¹/cm³.

Note that, without limitation to the compositions and materials described above, a material with an appropriate composition may be used depending on required semiconductor characteristics and electrical characteristics (e.g., field-effect mobility and threshold voltage) of a transistor. Furthermore, in order to obtain required semiconductor characteristics of a transistor, it is preferable that the carrier density, the impurity concentration, the defect density, the atomic ratio of a metal element to oxygen, the interatomic distance, the density, and the like of the oxide semiconductor film 108a and the oxide semiconductor film 108b be set to be appropriate.

Note that it is preferable to use, as the oxide semiconductor film 108a and the oxide semiconductor film 108b, an oxide semiconductor film in which the impurity concentration is low and the density of defect states is low, in which case the transistor can have more excellent electrical characteristics. Here, the state in which the impurity concentration is low and the density of defect states is low (the number of oxygen vacancies is small) is referred to as “highly purified intrinsic” or “substantially highly purified intrinsic”. A highly purified intrinsic or substantially highly purified intrinsic oxide semiconductor film has few carrier generation sources, and thus can have a low carrier density. Thus, a transistor in which a channel region is formed in the oxide semiconductor film rarely has a negative threshold voltage (is rarely normally on). A highly purified intrinsic or substantially highly purified intrinsic oxide semiconductor film has a low density of defect states and accordingly has a low density of trap states in some cases. Furthermore, the highly purified intrinsic or substantially highly purified intrinsic oxide semiconductor film has an extremely low off-state current; even when an element has a channel width of 1×10⁶ μm and a channel length L of 10 μm, the off-state current can be less than or equal to the measurement limit of a semiconductor parameter analyzer, that is, less than or equal to 1×10⁻¹³ A, at a voltage (drain voltage) between a source electrode and a drain electrode of from 1 V to 10 V.

Accordingly, the transistor in which the channel region is formed in the highly purified intrinsic or substantially highly purified intrinsic oxide semiconductor film can have a small change in electrical characteristics and high reliability. Charges trapped by the trap states in the oxide semiconductor film take a long time to be released and may behave like fixed charges. Thus, the transistor whose channel region is formed in the oxide semiconductor film having a high density of trap states has unstable electrical characteristics in some cases. As examples of the impurities, hydrogen, nitrogen, alkali metal, alkaline earth metal, and the like are given.

Hydrogen included in the oxide semiconductor film reacts with oxygen bonded to a metal atom to be water, and also causes oxygen vacancies in a lattice from which oxygen is released (or a portion from which oxygen is released). Due to entry of hydrogen into the oxygen vacancies, electrons serving as carriers are generated in some cases. Furthermore, in some cases, bonding of part of hydrogen to oxygen bonded to a metal atom causes generation of electrons serving as carriers. Thus, a transistor including an oxide semiconductor film that contains hydrogen is likely to be normally on. Accordingly, it is preferable that hydrogen be reduced as much as possible in the oxide semiconductor film 108. Specifically, in the oxide semiconductor film 108, the concentration of hydrogen that is measured by SIMS is lower than or equal to 2×10²⁰ atoms/cm³, preferably lower than or equal to 5×10¹⁹ atoms/cm³, further preferably lower than or equal to 1×10¹⁹ atoms/cm³, further preferably lower than or equal to 5×10¹⁸ atoms/cm³, further preferably lower than or equal to 1×10¹⁸ atoms/cm³, further preferably lower than or equal to 5×10¹⁷ atoms/cm³, and further preferably lower than or equal to 1×10¹⁶ atoms/cm³.

When silicon or carbon that is one of elements belonging to Group 14 is included in the oxide semiconductor film 108a, oxygen vacancies are increased in the oxide semiconductor film 108a, and the oxide semiconductor film 108a becomes an n-type film. Thus, the concentration of silicon or carbon (the concentration is measured by SIMS) in the oxide semiconductor film 108a or the concentration of silicon or carbon (the concentration is measured by SIMS) in the vicinity of an interface with the oxide semiconductor film 108a is set to be lower than or equal to 2×10¹⁸ atoms/cm³, preferably lower than or equal to 2×10¹⁷ atoms/cm³.

In addition, the concentration of alkali metal or alkaline earth metal of the oxide semiconductor film 108a, which is measured by SIMS, is lower than or equal to 1×10¹⁸ atoms/cm³, preferably lower than or equal to 2×10¹⁶ atoms/cm³. Alkali metal and alkaline earth metal might generate carriers when bonded to an oxide semiconductor, in which case the off-state current of the transistor might be increased. Therefore, it is preferable to reduce the concentration of alkali metal or alkaline earth metal of the oxide semiconductor film 108a.

Furthermore, when including nitrogen, the oxide semiconductor film 108a easily becomes n-type by generation of electrons serving as carriers and an increase of carrier density. Thus, a transistor including an oxide semiconductor film that contains nitrogen is likely to have normally-on characteristics. For this reason, nitrogen in the oxide semiconductor film is preferably reduced as much as possible; the concentration of nitrogen that is measured by SIMS is preferably set to be, for example, lower than or equal to 5×10¹⁸ atoms/cm³.

Each of the oxide semiconductor films 108a and 108b may have a non-single-crystal structure. The non-single crystal structure includes a c-axis aligned crystalline oxide semiconductor (CAAC-OS), a polycrystalline structure, a microcrystalline structure, or an amorphous structure, for example. Among the non-single crystal structure, the amorphous structure has the highest density of defect states, whereas CAAC-OS has the lowest density of defect states.

### <<Insulating Film Functioning as Protective Insulating Film of Transistor>>

The insulating films 114 and 116 each have a function of supplying oxygen to the oxide semiconductor film 108. The insulating film 118 has a function as a protective insulating film of the transistor 100. The insulating films 114 and 116 include oxygen. Furthermore, the insulating film 114 is an insulating film that can transmit oxygen. The insulating film 114 also functions as a film that relieves damage to the oxide semiconductor film 108 at the time of forming the insulating film 116 in a later step.

A silicon oxide film, a silicon oxynitride film, or the like with a thickness greater than or equal to 5 nm and less than or equal to 150 nm, preferably greater than or equal to 5 nm and less than or equal to 50 nm can be used as the insulating film 114.

In addition, it is preferable that the number of defects in the insulating film 114 be small and typically, the spin density corresponding to a signal that appears at g=2.001 due to a dangling bond of silicon be lower than or equal to 3×10¹⁷ spins/cm³ by electron spin resonance (ESR) measurement. This is because if the density of defects in the insulating film 114 is high, oxygen is bonded to the defects and the amount of oxygen that transmits the insulating film 114 is decreased.

Note that all oxygen entering the insulating film 114 from the outside does not move to the outside of the insulating film 114 and some oxygen remains in the insulating film 114. Furthermore, movement of oxygen occurs in the insulating film 114 in some cases in such a manner that oxygen enters the insulating film 114 and oxygen included in the insulating film 114 moves to the outside of the insulating film 114. When an oxide insulating film that can transmit oxygen is formed as the insulating film 114, oxygen released from the insulating film 116 provided over the insulating film 114 can be moved to the oxide semiconductor film 108 through the insulating film 114.

Note that the insulating film 114 can be formed using an oxide insulating film having a low density of states due to nitrogen oxide. Note that the density of states due to nitrogen oxide can be formed between the energy of the valence band maximum (Eᵥ_{_}ₒₛ) and the energy of the conduction band minimum (E_{c}_{_}ₒₛ) of the oxide semiconductor film. A silicon oxynitride film that releases less nitrogen oxide, an aluminum oxynitride film that releases less nitrogen oxide, and the like can be used as the above oxide insulating film.

Note that a silicon oxynitride film that releases less nitrogen oxide is a film of which the amount of released ammonia is larger than the amount of released nitrogen oxide in thermal desorption spectroscopy (TDS) analysis; the amount of released ammonia is typically greater than or equal to 1×10¹⁸/cm³ and less than or equal to 5×10¹⁹/cm³. Note that the amount of released ammonia is the amount of ammonia released by heat treatment with which the surface temperature of a film becomes higher than or equal to 50° C. and lower than or equal to 650° C., preferably higher than or equal to 50° C. and lower than or equal to 550° C.

Nitrogen oxide (NOₓ; x is greater than 0 and less than or equal to 2, preferably greater than or equal to 1 and less than or equal to 2), typically NO₂ or NO, forms levels in the insulating film 114, for example. The level is positioned in the energy gap of the oxide semiconductor film 108. Therefore, when nitrogen oxide is diffused to the interface between the insulating film 114 and the oxide semiconductor film 108, an electron is in some cases trapped by the level on the insulating film 114 side. As a result, the trapped electron remains in the vicinity of the interface between the insulating film 114 and the oxide semiconductor film 108; thus, the threshold voltage of the transistor is shifted in the positive direction.

Nitrogen oxide reacts with ammonia and oxygen in heat treatment. Since nitrogen oxide included in the insulating film 114 reacts with ammonia included in the insulating film 116 in heat treatment, nitrogen oxide included in the insulating film 114 is reduced. Therefore, an electron is hardly trapped at the vicinity of the interface between the insulating film 114 and the oxide semiconductor film 108.

By using such an oxide insulating film, the insulating film 114 can reduce the shift in the threshold voltage of the transistor, which leads to a smaller change in the electrical characteristics of the transistor.

Note that in an ESR spectrum at 100 K or lower of the insulating film 114, by heat treatment of a manufacturing process of the transistor, typically heat treatment at a temperature higher than or equal to 300° C. and lower than 350° C., a first signal that appears at a g-factor of greater than or equal to 2.037 and less than or equal to 2.039, a second signal that appears at a g-factor of greater than or equal to 2.001 and less than or equal to 2.003, and a third signal that appears at a g-factor of greater than or equal to 1.964 and less than or equal to 1.966 are observed. The split width of the first and second signals and the split width of the second and third signals that are obtained by ESR measurement using an X-band are each approximately 5 mT. The sum of the spin densities of the first signal that appears at a g-factor of greater than or equal to 2.037 and less than or equal to 2.039, the second signal that appears at a g-factor of greater than or equal to 2.001 and less than or equal to 2.003, and the third signal that appears at a g-factor of greater than or equal to 1.964 and less than or equal to 1.966 is lower than 1×10¹⁸ spins/cm³, typically higher than or equal to 1×10¹⁷ spins/cm³ and lower than 1×10¹⁸ spins/cm³.

In the ESR spectrum at 100 K or lower, the first signal that appears at a g-factor of greater than or equal to 2.037 and less than or equal to 2.039, the second signal that appears at a g-factor of greater than or equal to 2.001 and less than or equal to 2.003, and the third signal that appears at a g-factor of greater than or equal to 1.964 and less than or equal to 1.966 correspond to signals attributed to nitrogen oxide (NOₓ; x is greater than 0 and less than or equal to 2, preferably greater than or equal to 1 and less than or equal to 2). Typical examples of nitrogen oxide include nitrogen monoxide and nitrogen dioxide. In other words, the lower the total spin density of the first signal that appears at a g-factor of greater than or equal to 2.037 and less than or equal to 2.039, the second signal that appears at a g-factor of greater than or equal to 2.001 and less than or equal to 2.003, and the third signal that appears at a g-factor of greater than or equal to 1.964 and less than or equal to 1.966 is, the lower the content of nitrogen oxide in the oxide insulating film is.

The concentration of nitrogen of the above oxide insulating film measured by SIMS is lower than or equal to 6×10²⁰ atoms/cm³.

The above oxide insulating film is formed by a PECVD method at a film surface temperature higher than or equal to 220° C. and lower than or equal to 350° C. using silane and dinitrogen monoxide, whereby a dense and hard film can be formed.

The insulating film 116 is formed using an oxide insulating film that contains oxygen in excess of that in the stoichiometric composition. Part of oxygen is released by heating from the oxide insulating film including oxygen in excess of that in the stoichiometric composition. The oxide insulating film including oxygen in excess of that in the stoichiometric composition is an oxide insulating film of which the amount of released oxygen converted into oxygen atoms is greater than or equal to 1.0×10¹⁹ atoms/cm³, preferably greater than or equal to 3.0×10²⁰ atoms/cm³ in TDS analysis. Note that the temperature of the film surface in the TDS analysis is preferably higher than or equal to 100° C. and lower than or equal to 700° C., or higher than or equal to 100° C. and lower than or equal to 500° C.

A silicon oxide film, a silicon oxynitride film, or the like with a thickness greater than or equal to 30 nm and less than or equal to 500 nm, preferably greater than or equal to 50 nm and less than or equal to 400 nm can be used as the insulating film 116.

It is preferable that the number of defects in the insulating film 116 be small, and typically the spin density corresponding to a signal that appears at g=2.001 due to a dangling bond of silicon be lower than 1.5×10¹⁸ spins/cm³, preferably lower than or equal to 1×10¹⁸ spins/cm³ by ESR measurement. Note that the insulating film 116 is provided more apart from the oxide semiconductor film 108 than the insulating film 114 is; thus, the insulating film 116 may have higher density of defects than the insulating film 114.

Furthermore, the insulating films 114 and 116 can be formed using insulating films formed of the same kinds of materials; thus, a boundary between the insulating films 114 and 116 cannot be clearly observed in some cases. Thus, in this embodiment, the boundary between the insulating films 114 and 116 is shown by a dashed line. Although a two-layer structure of the insulating films 114 and 116 is described in this embodiment, the present invention is not limited to this. For example, a single-layer structure of the insulating film 114 may be employed.

The insulating film 118 includes nitrogen. Alternatively, the insulating film 118 includes nitrogen and silicon. The insulating film 118 has a function of blocking oxygen, hydrogen, water, alkali metal, alkaline earth metal, or the like. It is possible to prevent outward diffusion of oxygen from the oxide semiconductor film 108, outward diffusion of oxygen included in the insulating films 114 and 116, and entry of hydrogen, water, or the like into the oxide semiconductor film 108 from the outside by providing the insulating film 118. A nitride insulating film, for example, can be used as the insulating film 118. The nitride insulating film is formed using silicon nitride, silicon nitride oxide, aluminum nitride, aluminum nitride oxide, or the like. Note that instead of the nitride insulating film having a blocking effect against oxygen, hydrogen, water, alkali metal, alkaline earth metal, and the like, an oxide insulating film having a blocking effect against oxygen, hydrogen, water, and the like may be provided. As the oxide insulating film having a blocking effect against oxygen, hydrogen, water, and the like, an aluminum oxide film, an aluminum oxynitride film, a gallium oxide film, a gallium oxynitride film, an yttrium oxide film, an yttrium oxynitride film, a hafnium oxide film, a hafnium oxynitride film, and the like can be given.

Although the variety of films such as the conductive films, the insulating films, and the oxide semiconductor films that are described above can be formed by a sputtering method or a PECVD method, such films may be formed by another method, e.g., a thermal chemical vapor deposition (CVD) method. Examples of the thermal CVD method include a metal organic chemical vapor deposition (MOCVD) method and an atomic layer deposition (ALD) method.

A thermal CVD method has an advantage that no defect due to plasma damage is generated since it does not utilize plasma for forming a film.

Deposition by a thermal CVD method may be performed in such a manner that a source gas and an oxidizer are supplied to the chamber at a time so that the pressure in a chamber is set to an atmospheric pressure or a reduced pressure, and react with each other in the vicinity of the substrate or over the substrate.

Deposition by an ALD method may be performed in such a manner that the pressure in a chamber is set to an atmospheric pressure or a reduced pressure, source gases for reaction are sequentially introduced into the chamber, and then the sequence of the gas introduction is repeated. For example, two or more kinds of source gases are sequentially supplied to the chamber by switching respective switching valves (also referred to as high-speed valves). For example, a first source gas is introduced, an inert gas (e.g., argon or nitrogen) or the like is introduced at the same time as or after the introduction of the first gas so that the source gases are not mixed, and then a second source gas is introduced. Note that in the case where the first source gas and the inert gas are introduced at a time, the inert gas serves as a carrier gas, and the inert gas may also be introduced at the same time as the introduction of the second source gas. Alternatively, the first source gas may be exhausted by vacuum evacuation instead of the introduction of the inert gas, and then the second source gas may be introduced. The first source gas is adsorbed on the surface of the substrate to form a first layer; then the second source gas is introduced to react with the first layer; as a result, a second layer is stacked over the first layer, so that a thin film is formed. The sequence of the gas introduction is repeated a plurality of times until a desired thickness is obtained, whereby a thin film with excellent step coverage can be formed. The thickness of the thin film can be adjusted by the number of repetition times of the sequence of the gas introduction; therefore, an ALD method makes it possible to accurately adjust a thickness and thus is suitable for manufacturing a minute FET.

The variety of films such as the conductive films, the insulating films, the oxide semiconductor films, and the metal oxide films in this embodiment can be formed by a thermal CVD method such as an MOCVD method or an ALD method. For example, in the case where an In—Ga—Zn—O film is formed, trimethylindium, trimethylgallium, and dimethylzinc are used. Note that the chemical formula of trimethylindium is In(CH₃)₃. The chemical formula of trimethylgallium is Ga(CH₃)₃. The chemical formula of dimethylzinc is Zn(CH₃)₂. Without limitation to the above combination, triethylgallium (chemical formula: Ga(C₂H₅)₃) can be used instead of trimethylgallium and diethylzinc (chemical formula: Zn(C₂H₅)₂) can be used instead of dimethylzinc.

For example, in the case where a hafnium oxide film is formed by a deposition apparatus using an ALD method, two kinds of gases, that is, ozone (O₃) as an oxidizer and a source gas that is obtained by vaporizing liquid containing a solvent and a hafnium precursor compound (e.g., a hafnium alkoxide or a hafnium amide such as tetrakis(dimethylamide)hafnium (TDMAH)) are used. Note that the chemical formula of tetrakis(dimethylamide)hafnium is Hf[N(CH₃)₂]₄. Examples of another material liquid include tetrakis(ethylmethylamide)hafnium.

For example, in the case where an aluminum oxide film is formed by a deposition apparatus using an ALD method, two kinds of gases, e.g., H₂O as an oxidizer and a source gas that is obtained by vaporizing liquid containing a solvent and an aluminum precursor compound (e.g., trimethylaluminum (TMA)) are used. Note that the chemical formula of trimethylaluminum is Al(CH₃)₃. Examples of another material liquid include tris(dimethylamide)aluminum, triisobutylaluminum, and aluminum tris(2,2,6,6-tetramethyl-3,5-heptanedionate).

For example, in the case where a silicon oxide film is formed by a deposition apparatus using an ALD method, hexachlorodisilane is adsorbed on a surface where a film is to be formed, chlorine included in the adsorbate is removed, and radicals of an oxidizing gas (e.g., 02 or dinitrogen monoxide) are supplied to react with the adsorbate.

For example, in the case where a tungsten film is formed using a deposition apparatus using an ALD method, a WF₆ gas and a B₂H₆ gas are sequentially introduced a plurality of times to form an initial tungsten film, and then a WF₆ gas and an H₂ gas are used, so that a tungsten film is formed. Note that a SiH₄ gas may be used instead of a B₂H₆ gas.

For example, in the case where an oxide semiconductor film, e.g., an In—Ga—Zn—O film is formed using a deposition apparatus using an ALD method, an In(CH₃)₃ gas and an O₃ gas are sequentially introduced a plurality of times to form an InO layer, a GaO layer is formed using a Ga(CH₃)₃ gas and an O₃ gas, and then a ZnO layer is formed using a Zn(CH₃)₂ gas and an O₃ gas. Note that the order of these layers is not limited to this example. A mixed compound layer such as an In—Ga—O layer, an In—Zn—O layer, or a Ga—Zn—O layer may be formed by mixing these gases. Note that although an H₂O gas that is obtained by bubbling water with an inert gas such as Ar may be used instead of an O₃ gas, it is preferable to use an O₃ gas, which does not contain H. Furthermore, instead of an In(CH₃)₃ gas, an In(C₂H₅)₃ gas may be used. Instead of a Ga(CH₃)₃ gas, a Ga(C₂H₅)₃ gas may be used. Furthermore, a Zn(CH₃)₂ gas may be used.

Note that this embodiment can be combined with any of the other embodiments in this specification as appropriate.

### Embodiment 3

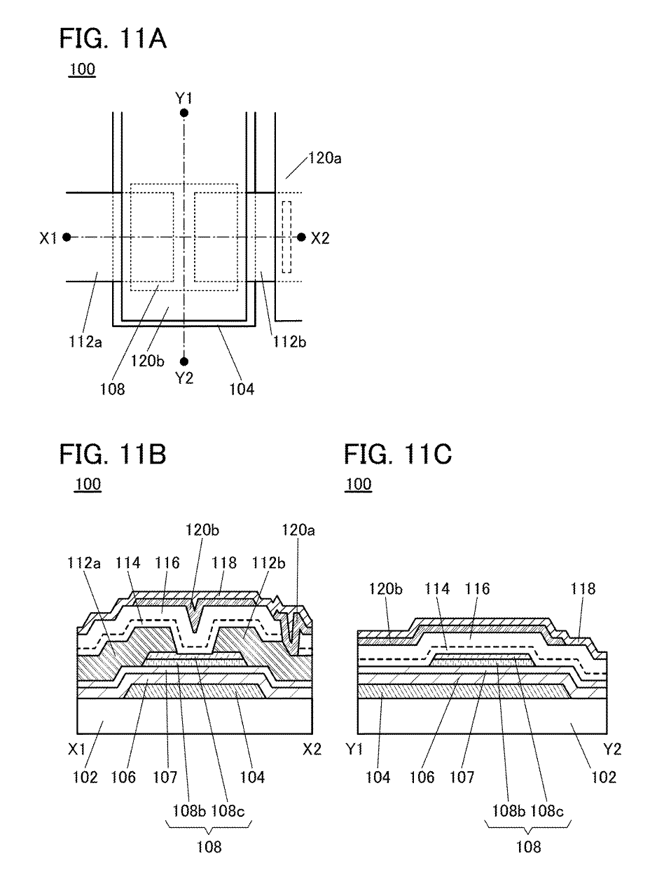

In this embodiment, the structure of a transistor that can be used in the input/output device of one embodiment of the present invention is described with reference to FIGS. 11A to 11C.

### Structural Example of Semiconductor Device

FIG. 11A is a top view of the transistor 100. FIG. 11B is a cross-sectional view taken along the cutting plane line X1-X2 in FIG. 11A. FIG. 11C is a cross-sectional view taken along the cutting plane line Y1-Y2 in FIG. 11A. Note that in FIG. 11A, some components of the transistor 100 (e.g., an insulating film serving as a gate insulating film) are not illustrated to avoid complexity. Furthermore, the direction of the cutting plane line X1-X2 may be called a channel length direction, and the direction of the cutting plane line Y1-Y2 may be called a channel width direction. As in FIG. 11A, some components are not illustrated in some cases in top views of transistors described below.

The transistor 100 can be used for the input/output device or the like described in Embodiment 1.

For example, when the transistor 100 is used as the transistor ME or the transistor MDE, the substrate 102, the conductive film 104, a stacked film of the insulating film 106 and the insulating film 107, the oxide semiconductor film 108, the conductive film 112a, the conductive film 112b, a stacked film of the insulating film 114 and the insulating film 116, the insulating film 118, and a conductive film 120b can be referred to as the insulating film 501C, the conductive film 504, the insulating film 506, the semiconductor film 508, the conductive film 512A, the conductive film 512B, the insulating film 516, the insulating film 518, and the conductive film 524, respectively.

The transistor 100 includes the conductive film 104 functioning as a first gate electrode over the substrate 102, the insulating film 106 over the substrate 102 and the conductive film 104, the insulating film 107 over the insulating film 106, the oxide semiconductor film 108 over the insulating film 107, and the conductive films 112a and 112b functioning as source and drain electrodes electrically connected to the oxide semiconductor film 108, the insulating films 114 and 116 over the oxide semiconductor film 108 and the conductive films 112a and 112b, a conductive film 120a that is over the insulating film 116 and electrically connected to the conductive film 112b, the conductive film 120b over the insulating film 116, and the insulating film 118 over the insulating film 116 and the conductive films 120a and 120b.

The insulating films 106 and 107 function as a first gate insulating film of the transistor 100. The insulating films 114 and 116 function as a second gate insulating film of the transistor 100. The insulating film 118 functions as a protective insulating film of the transistor 100.

The conductive film 120b can be used as a second gate electrode of the transistor 100.

In the case where the transistor 100 is used in the display portion of the input/output device, the conductive film 120a can be used as an electrode of a display element, or the like.

The oxide semiconductor film 108 includes the oxide semiconductor film 108b (on the conductive film 104 side) that functions as a first gate electrode, and an oxide semiconductor film 108c over the oxide semiconductor film 108b. The oxide semiconductor films 108b and 108c contain In, M (M is Al, Ga, Y, or Sn), and Zn.

The oxide semiconductor film 108b preferably includes a region in which the atomic proportion of In is larger than the atomic proportion of M, for example. The oxide semiconductor film 108c preferably includes a region in which the atomic proportion of In is smaller than that in the oxide semiconductor film 108b.

The oxide semiconductor film 108b including the region in which the atomic proportion of In is larger than that of M can increase the field-effect mobility (also simply referred to as mobility or μFE) of the transistor 100. Specifically, the field-effect mobility of the transistor 100 can exceed 10 cm²/Vs, preferably exceed 30 cm²/Vs.

For example, the use of the transistor with high field-effect mobility for a gate driver that generates a gate signal (specifically, a demultiplexer connected to an output terminal of a shift register included in a gate driver) allows a semiconductor device or a display device to have a narrow frame.

On the other hand, the oxide semiconductor film 108b including the region in which the atomic proportion of In is larger than that of M makes it easier to change electrical characteristics of the transistor 100 in light irradiation. However, in the semiconductor device of one embodiment of the present invention, the oxide semiconductor film 108c is formed over the oxide semiconductor film 108b. Furthermore, the oxide semiconductor film 108c including the region in which the atomic proportion of In is smaller than that in the oxide semiconductor film 108b has larger Eg than the oxide semiconductor film 108b. For this reason, the oxide semiconductor film 108 that is a layered structure of the oxide semiconductor film 108b and the oxide semiconductor film 108c has high resistance to a negative bias stress test with light irradiation.

Impurities such as hydrogen or moisture entering the channel region of the oxide semiconductor film 108, particularly the oxide semiconductor film 108b adversely affect the transistor characteristics and therefore cause a problem. Moreover, it is preferable that the amount of impurities such as hydrogen or moisture in the channel region of the oxide semiconductor film 108b be as small as possible. Furthermore, oxygen vacancies formed in the channel region in the oxide semiconductor film 108b adversely affect the transistor characteristics and therefore cause a problem. For example, oxygen vacancies formed in the channel region in the oxide semiconductor film 108b are bonded to hydrogen to serve as a carrier supply source. The carrier supply source generated in the channel region in the oxide semiconductor film 108b causes a change in the electrical characteristics, typically, shift in the threshold voltage, of the transistor 100 including the oxide semiconductor film 108b. Therefore, it is preferable that the amount of oxygen vacancies in the channel region of the oxide semiconductor film 108b be as small as possible.

In view of this, one embodiment of the present invention is a structure in which insulating films in contact with the oxide semiconductor film 108, specifically the insulating film 107 formed under the oxide semiconductor film 108 and the insulating films 114 and 116 formed over the oxide semiconductor film 108 include excess oxygen. Oxygen or excess oxygen is transferred from the insulating film 107 and the insulating films 114 and 116 to the oxide semiconductor film 108, whereby the oxygen vacancies in the oxide semiconductor film can be reduced. As a result, a change in electrical characteristics of the transistor 100, particularly a change in the transistor 100 due to light irradiation, can be reduced.

In one embodiment of the present invention, a manufacturing method is used in which the number of manufacturing steps is not increased or an increase in the number of manufacturing steps is extremely small, because the insulating film 107 and the insulating films 114 and 116 are made to contain excess oxygen. Thus, the transistors 100 can be manufactured with high yield.

Specifically, in a step of forming the oxide semiconductor film 108b, the oxide semiconductor film 108b is formed by a sputtering method in an atmosphere containing an oxygen gas, whereby oxygen or excess oxygen is added to the insulating film 107 over which the oxide semiconductor film 108b is formed.

Furthermore, in a step of forming the conductive films 120a and 120b, the conductive films 120a and 120b are formed by a sputtering method in an atmosphere containing an oxygen gas, whereby oxygen or excess oxygen is added to the insulating film 116 over which the conductive films 120a and 120b are formed. Note that in some cases, oxygen or excess oxygen is added also to the insulating film 114 and the oxide semiconductor film 108 under the insulating film 116 when oxygen or excess oxygen is added to the insulating film 116.

### <Oxide Conductor>

Next, an oxide conductor is described. In a step of forming the conductive films 120a and 120b, the conductive films 120a and 120b serve as a protective film for suppressing release of oxygen from the insulating films 114 and 116. The conductive films 120a and 120b serve as semiconductors before a step of forming the insulating film 118 and serve as conductors after the step of forming the insulating film 118.

To allow the conductive films 120a and 120b to serve as conductors, an oxygen vacancy is formed in the conductive films 120a and 120b and hydrogen is added from the insulating film 118 to the oxygen vacancy, whereby a donor level is formed in the vicinity of the conduction band. As a result, the conductivity of each of the conductive films 120a and 120b is increased, so that the conductive films 120a and 120b become conductors. The conductive films 120a and 120b having become conductors can each be referred to as an oxide conductor. Oxide semiconductors generally have a visible light transmitting property because of their large energy gap. An oxide conductor is an oxide semiconductor having a donor level in the vicinity of the conduction band. Therefore, the influence of absorption due to the donor level is small in an oxide conductor, and an oxide conductor has a visible light transmitting property comparable to that of an oxide semiconductor.

### <Components of Semiconductor Device>

Components of the semiconductor device of this embodiment are described below in detail.

As materials described below, materials described in Embodiment 2 can be used.

The material that can be used for the substrate 102 described in Embodiment 2 can be used for the substrate 102 in this embodiment. Furthermore, the materials that can be used for the insulating films 106 and 107 described in Embodiment 2 can be used for the insulating films 106 and 107 in this embodiment.

In addition, the materials that can be used for the conductive films functioning as the gate electrode, the source electrode, and the drain electrode described in Embodiment 2 can be used for the conductive films functioning as the first gate electrode, the source electrode, and the drain electrode in this embodiment.

### <<Oxide Semiconductor Film>>

The oxide semiconductor film 108 can be formed using the materials described above.

In the case where the oxide semiconductor film 108b includes In-M-Zn oxide, it is preferable that the atomic ratio of metal elements of a sputtering target used for forming the In-M-Zn oxide satisfy In >M. The atomic ratio between metal elements in such a sputtering target is, for example, In:M:Zn=2:1:3, In:M:Zn=3:1:2, or In:M:Zn=4:2:4.1.

In the case where the oxide semiconductor film 108c includes In-M-Zn oxide, it is preferable that the atomic ratio of metal elements of a sputtering target used for forming a film of the In-M-Zn oxide satisfy In≦M. The atomic ratio of metal elements in such a sputtering target is, for example, In:M:Zn=1:1:1, In:M:Zn=1:1:1.2, In:M:Zn=1:3:2, In:M:Zn=1:3:4, In:M:Zn=1:3:6, or In:M:Zn=1:4:5.

In the case where the oxide semiconductor films 108b and 108c include In-M-Zn oxide, it is preferable to use a target including polycrystalline In-M-Zn oxide as the sputtering target. The use of the target including polycrystalline In-M-Zn oxide facilitates formation of the oxide semiconductor films 108b and 108c having crystallinity. Note that the atomic ratios of metal elements in each of the formed oxide semiconductor films 108b and 108c vary from the above atomic ratio of metal elements of the sputtering target within a range of ±40% as an error. For example, when a sputtering target of the oxide semiconductor film 108b with an atomic ratio of In to Ga and Zn of 4:2:4.1 is used, the atomic ratio of In to Ga and Zn in the formed oxide semiconductor film 108b may be 4:2:3 or in the vicinity of 4:2:3.

The energy gap of the oxide semiconductor film 108 is 2 eV or more, preferably 2.5 eV or more, further preferably 3 eV or more. The use of an oxide semiconductor having a wide energy gap can reduce off-state current of the transistor 100. In particular, an oxide semiconductor film having an energy gap more than or equal to 2 eV, preferably more than or equal to 2 eV and less than or equal to 3.0 eV is preferably used as the oxide semiconductor film 108b, and an oxide semiconductor film having an energy gap more than or equal to 2.5 eV and less than or equal to 3.5 eV is preferably used as the oxide semiconductor film 108c. Furthermore, the oxide semiconductor film 108c preferably has a higher energy gap than the oxide semiconductor film 108b.

Each thickness of the oxide semiconductor film 108b and the oxide semiconductor film 108c is more than or equal to 3 nm and less than or equal to 200 nm, preferably more than or equal to 3 nm and less than or equal to 100 nm, further preferably more than or equal to 3 nm and less than or equal to 50 nm.

An oxide semiconductor film with low carrier density is used as the oxide semiconductor film 108c. For example, the carrier density of the oxide semiconductor film 108c is lower than or equal to 1×10¹⁷/cm³, preferably lower than or equal to 1×10¹⁵/cm³, further preferably lower than or equal to 1×10¹³/cm³, still further preferably lower than or equal to 1×10¹¹/cm³.

Note that, without limitation to the compositions and materials described above, a material with an appropriate composition may be used depending on required semiconductor characteristics and electrical characteristics (e.g., field-effect mobility and threshold voltage) of a transistor. Furthermore, in order to obtain required semiconductor characteristics of a transistor, it is preferable that the carrier density, the impurity concentration, the defect density, the atomic ratio of a metal element to oxygen, the interatomic distance, the density, and the like of the oxide semiconductor film 108b and the oxide semiconductor film 108c be set to be appropriate.

Note that it is preferable to use, as the oxide semiconductor film 108b and the oxide semiconductor film 108c, an oxide semiconductor film in which the impurity concentration is low and the density of defect states is low, in which case the transistor can have more excellent electrical characteristics. Here, the state in which the impurity concentration is low and the density of defect states is low (the amount of oxygen vacancy is small) is referred to as “highly purified intrinsic” or “substantially highly purified intrinsic”. A highly purified intrinsic or substantially highly purified intrinsic oxide semiconductor film has few carrier generation sources, and thus can have a low carrier density. Thus, a transistor in which a channel region is formed in the oxide semiconductor film rarely has a negative threshold voltage (is rarely normally on). A highly purified intrinsic or substantially highly purified intrinsic oxide semiconductor film has a low density of defect states and accordingly has a low density of trap states in some cases. Furthermore, the highly purified intrinsic or substantially highly purified intrinsic oxide semiconductor film has an extremely low off-state current; even when an element has a channel width of 1×10⁶ μm and a channel length L of 10 μm, the off-state current can be less than or equal to the measurement limit of a semiconductor parameter analyzer, that is, less than or equal to 1×10⁻¹³ A, at a voltage (drain voltage) between a source electrode and a drain electrode of from 1 V to 10 V.

Accordingly, the transistor in which the channel region is formed in the highly purified intrinsic or substantially highly purified intrinsic oxide semiconductor film can have a small change in electrical characteristics and high reliability. Charges trapped by the trap states in the oxide semiconductor film take a long time to be released and may behave like fixed charges. Thus, the transistor whose channel region is formed in the oxide semiconductor film having a high density of trap states has unstable electrical characteristics in some cases. As examples of the impurities, hydrogen, nitrogen, alkali metal, and alkaline earth metal are given.

Hydrogen included in the oxide semiconductor film reacts with oxygen bonded to a metal atom to be water, and also causes oxygen vacancy in a lattice from which oxygen is released (or a portion from which oxygen is released). Due to entry of hydrogen into the oxygen vacancy, an electron serving as a carrier is generated in some cases. Furthermore, in some cases, bonding of part of hydrogen to oxygen bonded to a metal atom causes generation of an electron serving as a carrier. Thus, a transistor including an oxide semiconductor film that contains hydrogen is likely to be normally on. Accordingly, it is preferable that hydrogen be reduced as much as possible in the oxide semiconductor film 108. Specifically, in the oxide semiconductor film 108, the concentration of hydrogen that is measured by SIMS is lower than or equal to 2×10²⁰ atoms/cm³, preferably lower than or equal to 5×10¹⁹ atoms/cm³, further preferably lower than or equal to 1×10¹⁹ atoms/cm³, further preferably lower than or equal to 5×10¹⁸ atoms/cm³, further preferably lower than or equal to 1×10¹⁸ atoms/cm³, further preferably lower than or equal to 5×10¹⁷ atoms/cm³, and further preferably lower than or equal to 1×10¹⁶ atoms/cm³.

The oxide semiconductor film 108b preferably includes a region in which hydrogen concentration is smaller than that in the oxide semiconductor film 108c. A semiconductor device including the oxide semiconductor film 108b having the region in which hydrogen concentration is smaller than that in the oxide semiconductor film 108c can be increased in reliability.

When silicon or carbon that is one of elements belonging to Group 14 is included in the oxide semiconductor film 108b, oxygen vacancies are increased in the oxide semiconductor film 108b, and the oxide semiconductor film 108b becomes an n-type film. Thus, the concentration of silicon or carbon (the concentration is measured by SIMS) in the oxide semiconductor film 108b or the concentration of silicon or carbon (the concentration is measured by SIMS) in the vicinity of an interface with the oxide semiconductor film 108b is set to be lower than or equal to 2×10¹⁸ atoms/cm³, preferably lower than or equal to 2×10¹⁷ atoms/cm³.

In addition, the concentration of alkali metal or alkaline earth metal of the oxide semiconductor film 108b, which is measured by SIMS, is lower than or equal to 1×10¹⁸ atoms/cm³, preferably lower than or equal to 2×10¹⁶ atoms/cm³. Alkali metal and alkaline earth metal might generate carriers when bonded to an oxide semiconductor, in which case the off-state current of the transistor might be increased. Therefore, it is preferable to reduce the concentration of alkali metal or alkaline earth metal of the oxide semiconductor film 108b.

Furthermore, when including nitrogen, the oxide semiconductor film 108b easily becomes n-type by generation of electrons serving as carriers and an increase of carrier density. Thus, a transistor including an oxide semiconductor film that contains nitrogen is likely to have normally-on characteristics. For this reason, nitrogen in the oxide semiconductor film is preferably reduced as much as possible; the concentration of nitrogen that is measured by SIMS is preferably set to be, for example, lower than or equal to 5×10¹⁸ atoms/cm³.

The oxide semiconductor film 108b and the oxide semiconductor film 108c may have a non-single-crystal structure. The non-single crystal structure includes CAAC-OS, a polycrystalline structure, a microcrystalline structure, or an amorphous structure, for example. Among the non-single crystal structure, the amorphous structure has the highest density of defect states, whereas CAAC-OS has the lowest density of defect states.

### <<Insulating Films Functioning as Second Gate Insulating Film>>

The insulating films 114 and 116 function as a second gate insulating film of the transistor 100. In addition, the insulating films 114 and 116 each have a function of supplying oxygen to the oxide semiconductor film 108. That is, the insulating films 114 and 116 contain oxygen. Furthermore, the insulating film 114 is an insulating film that can transmit oxygen. Note that the insulating film 114 also functions as a film that relieves damage to the oxide semiconductor film 108 at the time of forming the insulating film 116 in a later step.

For example, the insulating films 114 and 116 described in Embodiment 2 can be used as the insulating films 114 and 116 in this embodiment.

### <<Oxide Semiconductor Film Functioning as Conductive Film and Oxide Semiconductor Film Functioning as Second Gate Electrode>>

The material of the oxide semiconductor film 108 described above can be used for the conductive film 120a functioning as a conductive film and the conductive film 120b functioning as the second gate electrode.

That is, the conductive film 120a functioning as a conductive film and the conductive film 120b functioning as a second gate electrode contain a metal element that is the same as that contained in the oxide semiconductor film 108 (the oxide semiconductor film 108b and the oxide semiconductor film 108c). For example, the conductive film 120b functioning as a second gate electrode and the oxide semiconductor film 108 (the oxide semiconductor film 108b and the oxide semiconductor film 108c) contain the same metal element; thus, the manufacturing cost can be reduced.

For example, in the case where the conductive film 120a functioning as a conductive film and the conductive film 120b functioning as a second gate electrode each include In-M-Zn oxide, the atomic ratio of metal elements in a sputtering target used for forming the In-M-Zn oxide preferably satisfies In ≧M. The atomic ratio of metal elements in such a sputtering target is In:M:Zn=2:1:3, InM:Zn=3:1:2, In:M:Zn=4:2:4.1, or the like.

The conductive film 120a functioning as a conductive film and the conductive film 120b functioning as a second gate electrode can each have a single-layer structure or a stacked-layer structure of two or more layers. Note that in the case where the conductive film 120a and the conductive film 120b each have a stacked-layer structure, the composition of the sputtering target is not limited to that described above.

### <<Insulating Film Functioning as Protective Insulating Film of Transistor>>

The insulating film 118 serves as a protective insulating film of the transistor 100.

The insulating film 118 includes one or both of hydrogen and nitrogen. Alternatively, the insulating film 118 includes nitrogen and silicon. The insulating film 118 has a function of blocking oxygen, hydrogen, water, alkali metal, alkaline earth metal, or the like. It is possible to prevent outward diffusion of oxygen from the oxide semiconductor film 108, outward diffusion of oxygen included in the insulating films 114 and 116, and entry of hydrogen, water, or the like into the oxide semiconductor film 108 from the outside by providing the insulating film 118.

The insulating film 118 has a function of supplying one or both of hydrogen and nitrogen to the conductive film 120a functioning as a conductive film and the conductive film 120b functioning as a second gate electrode. The insulating film 118 preferably includes hydrogen and has a function of supplying the hydrogen to the conductive films 120a and 120b. The conductive films 120a and 120b supplied with hydrogen from the insulating film 118 function as conductors.

A nitride insulating film, for example, can be used as the insulating film 118. The nitride insulating film is formed using silicon nitride, silicon nitride oxide, aluminum nitride, aluminum nitride oxide, or the like.

Although the variety of films such as the conductive films, the insulating films, and the oxide semiconductor films that are described above can be formed by a sputtering method or a PECVD method, such films may be formed by another method, e.g., a thermal CVD method. Examples of the thermal CVD method include an MOCVD method and an ALD method.

A thermal CVD method has an advantage that no defect due to plasma damage is generated since it does not utilize plasma for forming a film.

Deposition by a thermal CVD method may be performed in such a manner that a source gas and an oxidizer are supplied to a chamber at a time, the pressure in the chamber is set to an atmospheric pressure or a reduced pressure, and they are reacted with each other in the vicinity of the substrate or over the substrate.

Deposition by an ALD method may be performed in such a manner that the pressure in a chamber is set to an atmospheric pressure or a reduced pressure, source gases for reaction are sequentially introduced into the chamber, and then the sequence of the gas introduction is repeated. For example, two or more kinds of source gases are sequentially supplied to the chamber by switching respective switching valves (also referred to as high-speed valves). For example, a first source gas is introduced, an inert gas (e.g., argon or nitrogen) or the like is introduced at the same time as or after the introduction of the first gas so that the source gases are not mixed, and then a second source gas is introduced. Note that in the case where the first source gas and the inert gas are introduced at a time, the inert gas serves as a carrier gas, and the inert gas may also be introduced at the same time as the introduction of the second source gas. Alternatively, the first source gas may be exhausted by vacuum evacuation instead of the introduction of the inert gas, and then the second source gas may be introduced. The first source gas is adsorbed on the surface of the substrate to form a first layer; then the second source gas is introduced to react with the first layer; as a result, a second layer is stacked over the first layer, so that a thin film is formed. The sequence of the gas introduction is repeated a plurality of times until a desired thickness is obtained, whereby a thin film with excellent step coverage can be formed. The thickness of the thin film can be adjusted by the number of repetition times of the sequence of the gas introduction; therefore, an ALD method makes it possible to accurately adjust a thickness and thus is suitable for manufacturing a minute FET.

The variety of films such as the conductive films, the insulating films, the oxide semiconductor films, and the metal oxide films in this embodiment can be formed by a thermal CVD method such as an MOCVD method or an ALD method. For example, in the case where an In—Ga—Zn—O film is formed, trimethylindium, trimethylgallium, and dimethylzinc are used. Note that the chemical formula of trimethylindium is In(CH₃)₃. The chemical formula of trimethylgallium is Ga(CH₃)₃. The chemical formula of dimethylzinc is Zn(CH₃)₂. Without limitation to the above combination, triethylgallium (chemical formula: Ga(C₂H₅)₃) can be used instead of trimethylgallium and diethylzinc (chemical formula: Zn(C₂H₅)₂) can be used instead of dimethylzinc.

For example, in the case where a hafnium oxide film is formed by a deposition apparatus using an ALD method, two kinds of gases, that is, ozone (O₃) as an oxidizer and a source gas that is obtained by vaporizing liquid containing a solvent and a hafnium precursor compound (e.g., a hafnium alkoxide or a hafnium amide such as tetrakis(dimethylamide)hafnium (TDMAH)) are used. Note that the chemical formula of tetrakis(dimethylamide)hafnium is Hf[N(CH₃)₂]₄. Examples of another material liquid include tetrakis(ethylmethylamide)hafnium.

For example, in the case where an aluminum oxide film is formed by a deposition apparatus using an ALD method, two kinds of gases, e.g., H₂O as an oxidizer and a source gas that is obtained by vaporizing liquid containing a solvent and an aluminum precursor compound (e.g., trimethylaluminum (TMA)) are used. Note that the chemical formula of trimethylaluminum is Al(CH₃)₃. Examples of another material liquid include tris(dimethylamide)aluminum, triisobutylaluminum, and aluminum tris(2,2,6,6-tetramethyl-3,5-heptanedionate).

For example, in the case where a silicon oxide film is formed by a deposition apparatus using an ALD method, hexachlorodisilane is adsorbed on a surface where a film is to be formed, chlorine included in the adsorbate is removed, and radicals of an oxidizing gas (e.g., O₂ or dinitrogen monoxide) are supplied to react with the adsorbate.

For example, in the case where a tungsten film is formed using a deposition apparatus using an ALD method, a WF₆ gas and a B₂H₆ gas are sequentially introduced a plurality of times to form an initial tungsten film, and then a WF₆ gas and an H₂ gas are used, so that a tungsten film is formed. Note that a SiH₄ gas may be used instead of a B₂H₆ gas.

For example, in the case where an oxide semiconductor film, e.g., an In—Ga—Zn—O film is formed using a deposition apparatus using an ALD method, an In(CH₃)₃ gas and an O₃ gas are sequentially introduced a plurality of times to form an InO layer, a GaO layer is formed using a Ga(CH₃)₃ gas and an O₃ gas, and then a ZnO layer is formed using a Zn(CH₃)₂ gas and an O₃ gas. Note that the order of these layers is not limited to this example. A mixed compound layer such as an In—Ga—O layer, an In—Zn—O layer, or a Ga—Zn—O layer may be formed by mixing these gases. Note that although an H₂O gas that is obtained by bubbling water with an inert gas such as Ar may be used instead of an O₃ gas, it is preferable to use an O₃ gas, which does not contain H. Furthermore, instead of an In(CH₃)₃ gas, an In(C₂H₅)₃ gas may be used. Instead of a Ga(CH₃)₃ gas, a Ga(C₂H₅)₃ gas may be used. Furthermore, a Zn(CH₃)₂ gas may be used.

Note that this embodiment can be combined with any of the other embodiments in this specification as appropriate.

### Embodiment 4

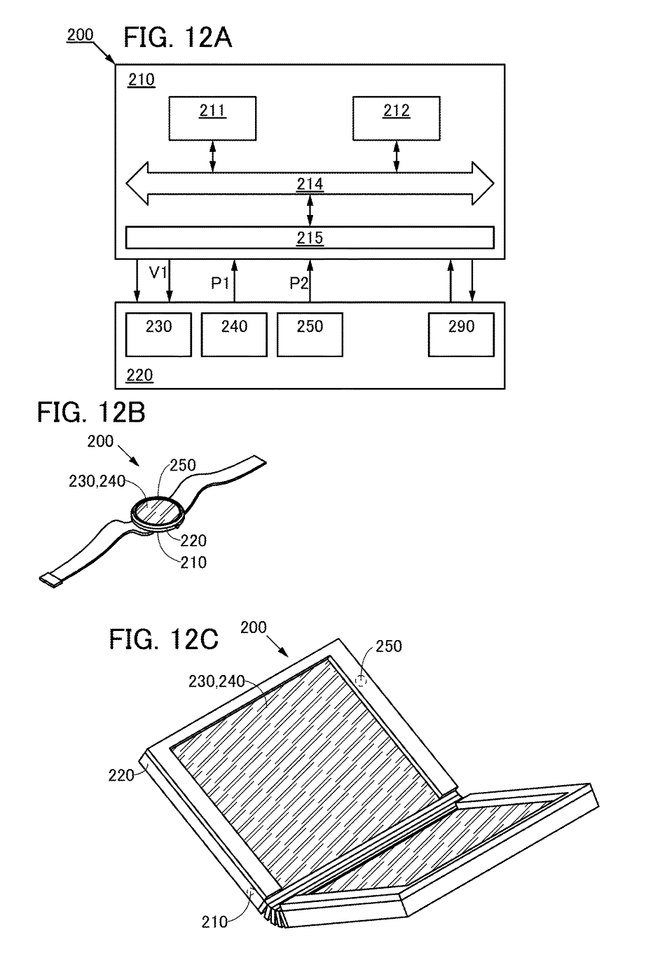

In this embodiment, a structure of a data processing device of one embodiment of the present invention is described with reference to FIGS. 12A to 12C, FIGS. 13A to 13C, and FIGS. 14A and 14B.

FIG. 12A is a block diagram illustrating a structure of a data processing device 200. FIGS. 12B and 12C are projection views illustrating examples of external views of the data processing device 200.

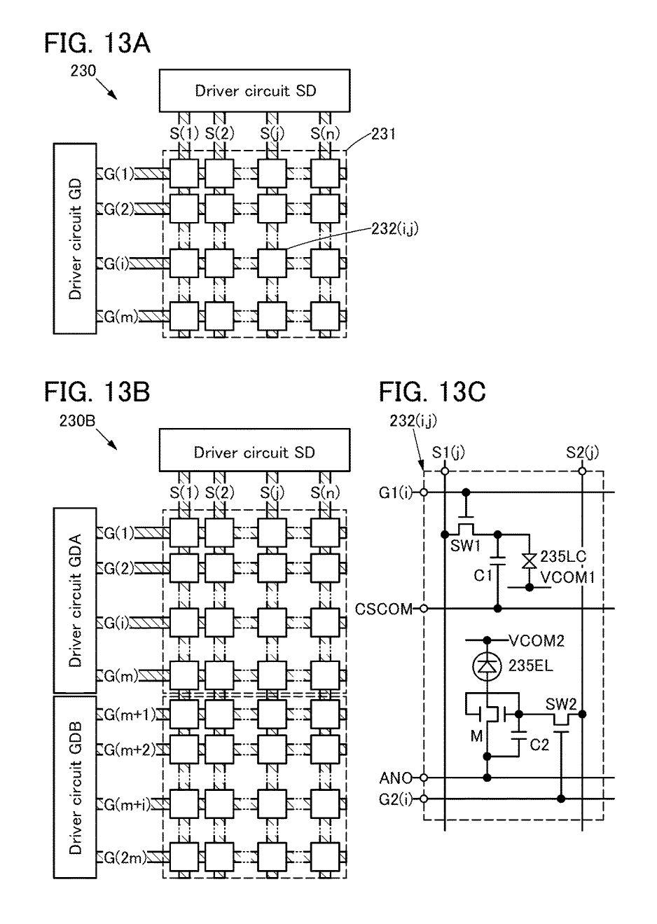

FIG. 13A is a block diagram illustrating a structure of a display portion 230. FIG. 13B is a block diagram illustrating a structure of a display portion 230B. FIG. 13C is a block diagram illustrating a structure of a pixel 232(i, j).

### Structural Example of Data Processing Device

The data processing device 200 described in this embodiment includes an input/output device 220 and an arithmetic device 210 (see FIG. 12A).

The input/output device 220 is configured to supply positional data P1 and pressure data and to receive image data V1 and control data. For example, a crown that can be pushed in a housing, a pressure sensor in contact with the crown or the like, or the like can be used.

The arithmetic device 210 is configured to receive the positional data P1 and the pressure data and to supply the image data V1 and the control data.

The arithmetic device 210 is configured to generate the image data V1 and the control data in accordance with the pressure data.

The input/output device 220 includes the display portion 230 that displays the image data V1, an input portion 240 that supplies the positional data P1, and a sensor portion 250 that supplies the pressure data.

The display portion 230 has a display panel. The sensor portion 250 includes a pressure sensor and is configured to generate the pressure data in accordance with a signal from the pressure sensor.

The arithmetic device 210 includes an arithmetic portion 211 and a memory portion 212.

The memory portion 212 stores a program executed by the arithmetic portion 211.

The program includes the step of selecting a first mode when pressure data exceeding a predetermined threshold is supplied and the step of selecting a second mode when pressure data exceeding a predetermined threshold is not supplied for more than a predetermined period.

The arithmetic portion 211 is configured to supply a control signal in the first mode that is different from a control signal supplied in the second mode.

The control signal includes a signal for refreshing display of the display panel.

The arithmetic device 210 is configured to supply the control signal in the second mode so that the frequency of refreshing the display of the display panel is lower than that in the first mode.

The above-described data processing device of one embodiment of the present invention includes the input/output device that supplies pressure data and the arithmetic device that supplies control data that varies in accordance with the pressure data.

With such a structure, the mode of the data processing device can be switched with the push, for example. Thus, a novel data processing device that is highly convenient or reliable can be provided.

### <Structure>

The data processing device of one embodiment of the present invention includes the arithmetic device 210 or the input/output device 220.

### <<Arithmetic Device 210>>

The arithmetic device 210 includes the arithmetic portion 211, the memory portion 212, a transmission path 214, and an input/output interface 215 (see FIG. 12A).

### <<Arithmetic Portion 211>>

The arithmetic portion 211 is configured to, for example, execute a program. For example, a CPU described in Embodiment 5 can be used. In that case, power consumption can be sufficiently reduced.

### <<Memory Portion 212>>

The memory portion 212 is configured to, for example, store the program executed by the arithmetic portion 211, initial data, setting data, an image, or the like.

Specifically, a hard disk, a flash memory, a memory including a transistor including an oxide semiconductor, or the like can be used.

### <<Input/Output Interface 215, Transmission Path 214>>

The input/output interface 215 includes a terminal or a wiring and is configured to supply and receive data. For example, the input/output interface 215 can be electrically connected to the transmission path 214 and the input/output device 220.

The transmission path 214 includes a wiring and is configured to supply and receive data. For example, the transmission path 214 can be electrically connected to the input/output interface 215. In addition, the transmission path 214 can be electrically connected to the arithmetic portion 211, the memory portion 212, or the input/output interface 215.

### <<Input/Output Device 220>>

The input/output device 220 includes the display portion 230, the input portion 240, the sensor portion 250, or a communication portion 290. For example, the input/output device described in Embodiment 1 can be used. Accordingly, power consumption can be reduced.

### <<Display Portion 230>>

The display portion 230 includes a display region 231, a driver circuit GD, and a driver circuit SD (see FIG. 13A).

The display region 231 includes a plurality of pixels 232(i, 1) to 232 (i, n) arranged in the row direction, a plurality of pixels 232(1, j) to 232 (m, j) arranged in the column direction, scan lines G1(i) and G2(i) electrically connected to the pixels 232(i, 1) to 232 (i, n), and signal lines S1(j) and S2(j) electrically connected to the pixels 232(1, j) to 232 (m, j). Note that i is an integer greater than or equal to 1 and less than or equal to m, j is an integer greater than or equal to 1 and less than or equal to n, and each of m and n is an integer greater than or equal to 1.

Note that the pixel 232(i, j) is electrically connected to the scan line G1(i), the scan line G2(i), the signal lines S1(j) and S2(j), the wiring ANO, the wiring CSCOM, the wiring VCOM1, and the wiring VCOM2 (see FIG. 13C).

The display portion can include a plurality of driver circuits. For example, the display portion 230B can include a driver circuit GDA and a driver circuit GDB (see FIG. 13B).

### <<Driver Circuit GD>>

The driver circuit GD is configured to supply a selection signal in accordance with the control data.

For example, the driver circuit GD is configured to supply a selection signal to one scan line at a frequency of 30 Hz or higher, preferably 60 Hz or higher, in accordance with the control data. Accordingly, moving images can be smoothly displayed.

For example, the driver circuit GD is configured to supply a selection signal to one scan line at a frequency of lower than 30 Hz, preferably lower than 1 Hz, further preferably less than once per minute, in accordance with the control data. Accordingly, a still image can be displayed while flickering is suppressed.

For example, in the case where a plurality of driver circuits is provided, the driver circuits GDA and GDB may supply the selection signals at different frequencies. Specifically, the selection signal can be supplied at a higher frequency to a region on which moving images are smoothly displayed than to a region on which a still image is displayed in a state where flickering is suppressed.

### <<Driver Circuit SD>>

The driver circuit SD is configured to supply an image signal in accordance with the image data V1. For example, the driver circuit SD can generate and supply a first image signal and a second image signal in accordance with the image data V1. Specifically, the driver circuit SD can generate and supply a first image signal for performing display using a first display element 235LC and a second image signal for performing display using a second display element 235EL. Thus, an image that is different from an image displayed using the first display element can be displayed using the second display element, for example.

<<Pixel 232(i, j)>>

The pixel 232(i, j) includes the first display element 235LC and the second display element 235EL overlapping with the first display element 235LC. The pixel 232(i, j) further includes a pixel circuit for driving the first display element 235LC and the second display element 235EL (see FIG. 13C).

### <<First Display Element 235LC>>

For example, a display element having a function of controlling transmission or reflection of light can be used as the display element 235LC. For example, a combined structure of a polarizing plate and a liquid crystal element or a MEMS shutter display element can be used. The use of a reflective display element can reduce power consumption of a display panel. Specifically, a reflective liquid crystal display element can be used as the display element 235LC.

The first display element 235LC includes a first electrode, a second electrode, and a liquid crystal layer. The liquid crystal layer contains a liquid crystal material whose orientation is controlled by voltage applied between the first electrode and the second electrode. For example, the orientation of the liquid crystal material can be controlled by an electric field in the thickness direction of the liquid crystal layer (also referred to as the vertical direction) or an electric field in the direction intersecting the vertical direction (also referred to as the horizontal direction or the diagonal direction).

### <<Second Display Element 235EL>>

A display element having a function of emitting light can be used as the second display element 235EL, for example. Specifically, an organic EL element can be used.

Specifically, an organic EL element having a function of emitting white light can be used as the second display element 235EL. Alternatively, an organic EL element which emits blue light, green light, or red light can be used as the second display element 235EL.

### <<Pixel Circuit>>

A pixel circuit including a circuit that is configured to drive the first display element or the second display element can be used.

A switch, a transistor, a diode, a resistor, an inductor, a capacitor, or the like can be used in the pixel circuit.

For example, one or a plurality of transistors can be used as a switch. Alternatively, a plurality of transistors connected in parallel, in series, or in combination of parallel connection and series connection can be used as a switch.

### <<Transistor>>

For example, semiconductor films formed at the same step can be used for transistors in the driver circuit and the pixel circuit.

For example, bottom-gate transistors, top-gate transistors, or the like can be used.

Incidentally, a manufacturing line for a bottom-gate transistor including amorphous silicon as a semiconductor can be easily remodeled into a manufacturing line for a bottom-gate transistor including an oxide semiconductor as a semiconductor, for example. Furthermore, for example, a manufacturing line for a top-gate transistor including polysilicon as a semiconductor can be easily remodeled into a manufacturing line for a top-gate transistor including an oxide semiconductor as a semiconductor.

For example, a transistor including a semiconductor containing an element of Group 14 can be used. Specifically, a semiconductor containing silicon can be used for a semiconductor film. For example, single crystal silicon, polysilicon, microcrystalline silicon, amorphous silicon, or the like can be used for the semiconductor film of the transistor.

Note that the temperature for forming a transistor using polysilicon as a semiconductor is lower than the temperature for forming a transistor using single crystal silicon as a semiconductor.

In addition, the transistor using polysilicon as a semiconductor has higher field-effect mobility than the transistor using amorphous silicon as a semiconductor, and therefore a pixel including the transistor using polysilicon can have a high aperture ratio. Moreover, pixels arranged at high resolution, a gate driver circuit, and a source driver circuit can be formed over the same substrate. As a result, the number of components included in an electronic device can be reduced.

In addition, the transistor using polysilicon as a semiconductor has higher reliability than the transistor using amorphous silicon as a semiconductor.

For example, a transistor including an oxide semiconductor can be used. Specifically, an oxide semiconductor containing indium or an oxide semiconductor containing indium, gallium, and zinc can be used for a semiconductor film.

For example, a transistor having a lower leakage current in an off state than a transistor that uses amorphous silicon in a semiconductor film can be used. Specifically, a transistor that uses an oxide semiconductor in a semiconductor film can be used.

A pixel circuit including the transistor that uses an oxide semiconductor in the semiconductor film can hold an image signal for a longer time than a pixel circuit including the transistor that uses amorphous silicon in a semiconductor film. Specifically, the selection signal can be supplied at a frequency of lower than 30 Hz, preferably lower than 1 Hz, further preferably less than once per minute while flickering is suppressed. Consequently, eyestrain on a user of the data processing device can be reduced, and power consumption for driving can be reduced.

Alternatively, for example, a transistor including a compound semiconductor can be used. Specifically, a semiconductor containing gallium arsenide can be used in a semiconductor film.

For example, a transistor including an organic semiconductor can be used. Specifically, an organic semiconductor containing any of polyacenes and graphene can be used in the semiconductor film.

### <<Input Portion 240>>

A variety of human interfaces or the like can be used as the input portion 240 (see FIG. 12A).

For example, a keyboard, a mouse, a touch sensor, a microphone, a camera, or the like can be used as the input portion 240. Note that a touch sensor having a region overlapping with the display portion 230 can be used. An input/output device that includes the display portion 230 and a touch sensor having a region overlapping with the display portion 230 can be referred to as a touch panel.

For example, a user can make various gestures (e.g., tap, drag, swipe, and pinch in) using his/her finger as a pointer on the touch panel.

The arithmetic device 210, for example, analyzes data on the position, track, or the like of the finger on the touch panel and determines that a specific gesture is supplied when the analysis results meet predetermined conditions. Therefore, the user can supply a certain operation instruction associated with a certain gesture by using the gesture.

For instance, the user can supply a “scrolling instruction” for changing a portion where image data is displayed by using a gesture of touching and moving his/her finger on the touch panel.

### <<Sensor Portion 250>>

The sensor portion 250 is configured to supply data P2, such as pressure data, by sensing its surroundings.

For example, a camera, an acceleration sensor, a direction sensor, a pressure sensor, a temperature sensor, a humidity sensor, an illuminance sensor, a global positioning system (GPS) signal receiving circuit, or the like can be used as the sensor portion 250.

For example, when the arithmetic device 210 determines that the ambient light level measured by an illuminance sensor of the sensor portion 250 is sufficiently higher than the predetermined illuminance, image data is displayed using the first display element 235LC. When the arithmetic device 210 determines that it is dim, image data is displayed using the first display element 235LC and the second display element 235EL. When the arithmetic device 210 determines that it is dark, image data is displayed using the second display element 235EL.

Specifically, an image is displayed with a reflective liquid crystal element and/or an organic EL element depending on the ambient brightness.

Thus, image data can be displayed in such a manner that, for example, a reflective display element is used under strong ambient light, a reflective display element and a self-luminous display element are used in dim light, and a self-luminous display element is used in dark light. As a result, a novel data processing device that has low power consumption and is highly convenient or reliable can be provided.

For example, a sensor configured to measure the chromaticity of ambient light, such as a CCD camera, can be used in the sensor portion 250. Owing to this, white balance can be adjusted in accordance with the chromaticity of ambient light sensed by the sensor portion 250.

Specifically, in the first step, imbalance disruption of white balance of ambient light is measured.

In the second step, the intensity of light of a color that is insufficient in an image to be displayed by the first display element using reflection of ambient light is estimated.

In the third step, ambient light is reflected by the first display element, and light is emitted from the second display element so that light of the insufficient color is supplemented, whereby the image is displayed.

In this manner, display can be performed with adjusted white balance by utilizing light reflected by the first display element and light emitted from the second display element. Thus, a novel data processing device that can display an image with low power consumption or with adjusted white balance and that is highly convenient and reliable can be provided.

### <<Communication Portion 290>>

The communication portion 290 is configured to supply and acquire data to/from a network.

### <Program>

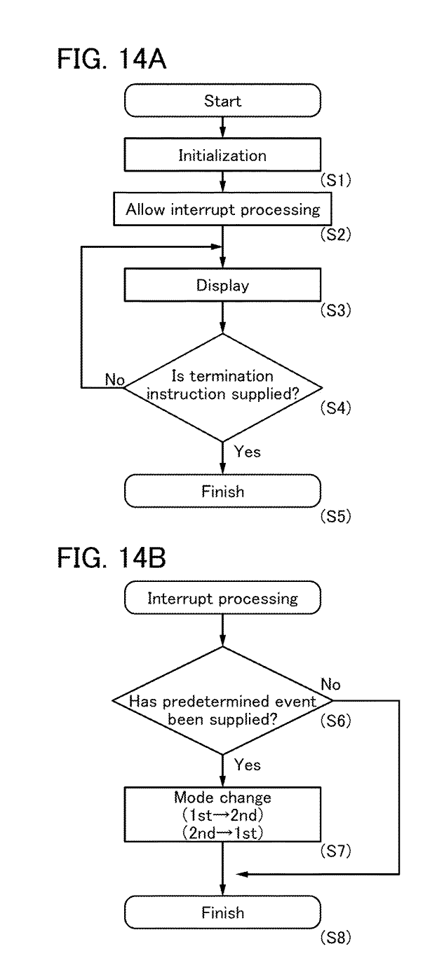

A program of one embodiment of the present invention will be described with reference to FIGS. 14A and 14B.

FIG. 14A is a flow chart showing main processing of the program of one embodiment of the present invention, and FIG. 14B is a flow chart showing interrupt processing.

The program of one embodiment of the present invention is composed of the following steps (see FIG. 14A).

### <<First Step>>

In the first step, setting is initialized (see (S1) in FIG. 14A).

For example, predetermined image data that is to be displayed on starting and data for specifying a method of displaying the image data are acquired from the memory portion 212. Specifically, a still image can be used as the predetermined image data. A method of refreshing image data at a frequency lower than that in the case of using a moving image can be used as the method of displaying image data. For example, the second mode can be used as the method of displaying image data.

### <<Second Step>>

In the second step, interrupt processing is allowed (see (S2) in FIG. 14A). Note that an arithmetic device allowed to execute the interrupt processing can perform the interrupt processing in parallel with the main processing. The arithmetic device that has returned from the interrupt processing to the main processing can reflect the results of the interrupt processing in the main processing.

The arithmetic device may execute the interrupt processing when a counter has an initial value, and the counter may be set at a value other than the initial value when the arithmetic device returns from the interrupt processing. Thus, the interrupt processing is ready to be executed after the program is started up.

### <<Third Step>>

In the third step, image data is displayed in a mode selected in the first step or the interrupt processing (see (S3) in FIG. 14A). Note that the method of displaying image data is specified by the mode.

For example, the first mode or the second mode can be selected.

### <<First Mode>>

Specifically, a method of supplying selection signals to a scan line at a frequency of 30 Hz or more, preferably 60 Hz or more, and performing display in accordance with the selection signals can be used in the first mode.

The supply of selection signals at a frequency of 30 Hz or more, preferably 60 Hz or more, can display a smooth moving image.

For example, when an image is refreshed at a frequency of 30 Hz or more, preferably 60 Hz or more, an image smoothly following the user's operation can be displayed on the data processing device 200 the user is operating.

### <<Second Mode>>

Specifically, a method of supplying selection signals to a scan line at a frequency of less than 30 Hz, preferably less than 1 Hz, further preferably once a minute and performing display in accordance with the selection signals can be used in the second mode.

The supply of selection signals at a frequency of less than 30 Hz, preferably less than 1 Hz, further preferably once a minute, can perform display with flickers reduced. Furthermore, power consumption can be reduced.

Incidentally, for example, when a light-emitting element is used as the second display element, the light-emitting element can be configured to emit light in a pulsed manner so as to display image data. Specifically, an organic EL element can be configured to emit light in a pulsed manner, and its afterglow can be used for display. The organic EL element has excellent frequency characteristics; thus, time for driving the light-emitting element can be shortened, and thus power consumption can be reduced in some cases. Alternatively, heat generation can be inhibited, and thus the deterioration of the light-emitting element can be suppressed in some cases.

For example, when the data processing device 200 is used for a clock or watch, the display can be refreshed at a frequency of once a second or once a minute.

### <<Fourth Step>>

In the fourth step, the program moves to the fifth step when a termination instruction is supplied, and the program moves to the third step when the termination instruction is not supplied (see (S4) in FIG. 14A).

For example, the termination instruction supplied in the interrupt processing can be used.

### <<Fifth Step>>

In the fifth step, the program terminates (see (S5) in FIG. 14A).

### <<Interrupt Processing>>

The interrupt processing includes sixth to eighth steps described below (see FIG. 14B).

### <<Sixth Step>>

In the sixth step, the processing proceeds to the seventh step when a predetermined event has been supplied, whereas the processing proceeds to the eighth step when the predetermined event has not been supplied (see (S6) in FIG. 14B). For example, whether the predetermined event is supplied in a predetermined period or not can be a branch condition. Specifically, the predetermined period can be longer than 0 seconds and shorter than or equal to 5 seconds, preferably shorter than or equal to 1 second, further preferably shorter than or equal to 0.5 seconds, still further preferably shorter than or equal to 0.1 seconds.

### <<Seventh Step>>

In the seventh step, the mode is changed (see (S7) in FIG. 14B). Specifically, the mode is changed to the second mode when the first mode has been selected, or the mode is changed to the first mode when the second mode has been selected.

### <<Eighth Step>>

In the eighth step, the interrupt processing terminates (see (S8) in FIG. 14B).

### <<Predetermined Event>>

For example, the following events can be used: events supplied using a pointing device such as a mouse (e.g., “click” and “drag”) and events supplied to a touch panel with a finger or the like used as a pointer (e.g., “tap”, “drag”, or “swipe”).

For example, the position of a slide bar pointed by a pointer, the swipe speed, and the drag speed can be used for parameters assigned to an instruction associated with the predetermined event.

For example, data sensed by the sensor portion 250 is compared to the set threshold, and the compared results can be used for the event.

Specifically, a crown that can be pushed in a housing, a pressure sensor in contact with the crown or the like, or the like can be used (see FIG. 12B).

For example, a photoelectric conversion element provided in a housing can be used (see FIG. 12C).

<<Instruction Associated with Predetermined Event>>

For example, the termination instruction can be associated with a predetermined event.

For example, “page-turning instruction” for switching displayed image data from one to another can be associated with a predetermined event. Note that a parameter for determining the page-turning speed or the like when the “page-turning instruction” is executed can be supplied using the predetermined event.

For example, “scroll instruction” for moving the display position of part of image data and displaying another part continuing from that part can be associated with a predetermined event. Note that a parameter for determining the moving speed of the display position or the like when the “scroll instruction” is executed can be supplied using the predetermined event.

For example, an instruction for generating image data can be associated with a predetermined event. Note that the ambient luminance sensed by the sensor portion 250 may be used for a parameter for determining the brightness of a generated image.

For example, an instruction or the like for acquiring data distributed via a push service using the communication portion 290 can be associated with a predetermined event. Note that positional data sensed by the sensor portion 250 may be used for the determination of the presence or absence of a qualification for acquiring data. Specifically, it may be determined that there is a qualification for acquiring data when the user is in a predetermined class room, school, conference room, office, or building (see FIG. 12C). For example, educational materials can be fed from a classroom of, for example, a school or a university and displayed, so that the data processing device 200 can be used as a schoolbook or the like. Alternatively, materials distributed from a conference room in, for example, a company can be received and displayed.

Note that this embodiment can be combined with any of the other embodiments in this specification as appropriate.

### Embodiment 5

In this embodiment, a semiconductor device (memory device) that can retain stored data even when not powered and that has an unlimited number of write cycles, and a CPU including the semiconductor device are described. The CPU described in this embodiment can be used for the data processing device described in Embodiment 6, for example.

### <Memory Device>

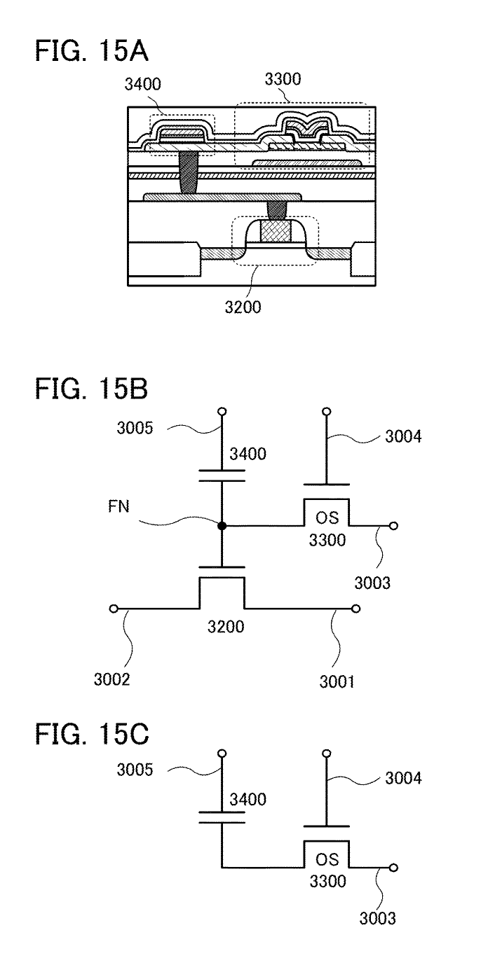

An example of a semiconductor device (memory device) that can retain stored data even when not powered and that has an unlimited number of write cycles is shown in FIGS. 15A to 15C. Note that FIG. 15B is a circuit diagram of the structure in FIG. 15A.

The semiconductor device illustrated in FIGS. 15A and 15B includes a transistor 3200 using a first semiconductor material, a transistor 3300 using a second semiconductor material, and a capacitor 3400.

The first and second semiconductor materials preferably have different energy gaps. For example, the first semiconductor material can be a semiconductor material other than an oxide semiconductor (examples of such a semiconductor material include silicon (including strained silicon), germanium, silicon germanium, silicon carbide, gallium arsenide, aluminum gallium arsenide, indium phosphide, gallium nitride, and an organic semiconductor), and the second semiconductor material can be an oxide semiconductor. A transistor using a material other than an oxide semiconductor, such as single crystal silicon, can operate at high speed easily. On the other hand, a transistor including an oxide semiconductor has a low off-state current.

The transistor 3300 is a transistor in which a channel is formed in a semiconductor film including an oxide semiconductor. Since the off-state current of the transistor 3300 is small, stored data can be retained for a long period. In other words, power consumption can be sufficiently reduced because a semiconductor memory device in which refresh operation is unnecessary or the frequency of refresh operation is extremely low can be provided.

In FIG. 15B, a first wiring 3001 is electrically connected to a source electrode of the transistor 3200. A second wiring 3002 is electrically connected to a drain electrode of the transistor 3200. A third wiring 3003 is electrically connected to one of a source electrode and a drain electrode of the transistor 3300. A fourth wiring 3004 is electrically connected to a gate electrode of the transistor 3300. A gate electrode of the transistor 3200 and the other of the source electrode and the drain electrode of the transistor 3300 are electrically connected to one electrode of the capacitor 3400. A fifth wiring 3005 is electrically connected to the other electrode of the capacitor 3400.

The semiconductor device in FIG. 15A has a feature that the potential of the gate electrode of the transistor 3200 can be retained, and thus enables writing, retaining, and reading of data as follows.

Writing and retaining of data are described. First, the potential of the fourth wiring 3004 is set to a potential at which the transistor 3300 is turned on, so that the transistor 3300 is turned on. Accordingly, the potential of the third wiring 3003 is supplied to the gate electrode of the transistor 3200 and the capacitor 3400. That is, a predetermined charge is supplied to the gate electrode of the transistor 3200 (writing). Here, one of two kinds of charges providing different potential levels (hereinafter referred to as a low-level charge and a high-level charge) is supplied. After that, the potential of the fourth wiring 3004 is set to a potential at which the transistor 3300 is turned off, so that the transistor 3300 is turned off. Thus, the charge supplied to the gate electrode of the transistor 3200 is held (retaining).

Since the off-state current of the transistor 3300 is extremely small, the charge of the gate electrode of the transistor 3200 is retained for a long time.

Next, reading of data is described. An appropriate potential (a reading potential) is supplied to the fifth wiring 3005 while a predetermined potential (a constant potential) is supplied to the first wiring 3001, whereby the potential of the second wiring 3002 varies depending on the amount of charge retained in the gate electrode of the transistor 3200. This is because in the case of using an n-channel transistor as the transistor 3200, an apparent threshold voltage Vₜₕ_{_}_{H} at the time when the high-level charge is given to the gate electrode of the transistor 3200 is lower than an apparent threshold voltage Vₜₕ_{_}_{L} at the time when the low-level charge is given to the gate electrode of the transistor 3200. Here, an apparent threshold voltage refers to the potential of the fifth wiring 3005 that is needed to turn on the transistor 3200. Thus, the potential of the fifth wiring 3005 is set to a potential V₀ that is between Vₜₕ_{_}_{H} and Vₜₕ_{_}_{L}, whereby charge supplied to the gate electrode of the transistor 3200 can be determined. For example, in the case where the high-level charge is supplied to the gate electrode of the transistor 3200 in writing and the potential of the fifth wiring 3005 is V₀ (>Vₜₕ_{_}_{H}), the transistor 3200 is turned on. In the case where the low-level charge is supplied to the gate electrode of the transistor 3200 in writing, even when the potential of the fifth wiring 3005 is V₀ (<Vₜₕ_{_}_{L}), the transistor 3200 remains off. Thus, the data retained in the gate electrode of the transistor 3200 can be read by determining the potential of the second wiring 3002.

Note that in the case where memory cells are arrayed, it is necessary that only data of a designated memory cell(s) can be read. For example, the fifth wiring 3005 of memory cells from which data is not read may be supplied with a potential at which the transistor 3200 is turned off regardless of the potential supplied to the gate electrode, that is, a potential lower than Vₜₕ_{_}_{H}, whereby only data of a designated memory cell(s) can be read. Alternatively, the fifth wiring 3005 of the memory cells from which data is not read may be supplied with a potential at which the transistor 3200 is turned on regardless of the potential supplied to the gate electrode, that is, a potential higher than Vₜₕ_{_}_{L}, whereby only data of a designated memory cell(s) can be read.

The semiconductor device illustrated in FIG. 15C is different from the semiconductor device illustrated in FIG. 15A in that the transistor 3200 is not provided. Also in this case, writing and retaining operation of data can be performed in a manner similar to those of the semiconductor device illustrated in FIG. 15A.

Next, reading of data of the semiconductor device illustrated in FIG. 15C is described. When the transistor 3300 is turned on, the third wiring 3003 that is in a floating state and the capacitor 3400 are electrically connected to each other, and the charge is redistributed between the third wiring 3003 and the capacitor 3400. As a result, the potential of the third wiring 3003 is changed. The amount of change in the potential of the third wiring 3003 varies depending on the potential of the one electrode of the capacitor 3400 (or the charge accumulated in the capacitor 3400).

For example, the potential of the third wiring 3003 after the charge redistribution is (C_{B}×V_{B0}C×V)/(C_{B}+C), where V is the potential of the one electrode of the capacitor 3400, C is the capacitance of the capacitor 3400, C_{B} is the capacitance component of the third wiring 3003, and V_{B0} is the potential of the third wiring 3003 before the charge redistribution. Thus, it can be found that, assuming that the memory cell is in either of two states in which the potential of the one electrode of the capacitor 3400 is V₁ and V₀ (V₁>V₀), the potential of the third wiring 3003 in the case of retaining the potential V₁ (=(C_{B}×V_{B0}+C×V₁)/(C_{B}+C)) is higher than the potential of the third wiring 3003 in the case of retaining the potential V₀ (=(C_{B}×V_{B0}+C×V₀)/(C_{B}+C)).

Then, by comparing the potential of the third wiring 3003 with a predetermined potential, data can be read.

In this case, a transistor including the first semiconductor material may be used for a driver circuit for driving a memory cell, and a transistor including the second semiconductor material may be stacked over the driver circuit as the transistor 3300.

When including a transistor in which a channel formation region is formed using an oxide semiconductor and which has an extremely small off-state current, the semiconductor device described in this embodiment can retain stored data for an extremely long time. In other words, refresh operation becomes unnecessary or the frequency of the refresh operation can be extremely low, which leads to a sufficient reduction in power consumption. Moreover, stored data can be retained for a long time even when power is not supplied (note that a potential is preferably fixed).

Furthermore, in the semiconductor device described in this embodiment, high voltage is not needed for writing data and there is no problem of deterioration of elements. Unlike in a conventional nonvolatile memory, for example, it is not necessary to inject and extract electrons into and from a floating gate; thus, a problem such as deterioration of a gate insulating film is not caused. That is, the semiconductor device described in this embodiment does not have a limit on the number of times data can be rewritten, which is a problem of a conventional nonvolatile memory, and the reliability thereof is drastically improved. Furthermore, data is written depending on the state of the transistor (on or off), whereby high-speed operation can be easily achieved.

The above memory device can also be used in an LSI such as a digital signal processor (DSP), a custom LSI, or a programmable logic device (PLD) and a radio frequency identification (RF-ID) tag, in addition to a central processing unit (CPU), for example.

### <CPU>

A CPU including the above memory device is described below.

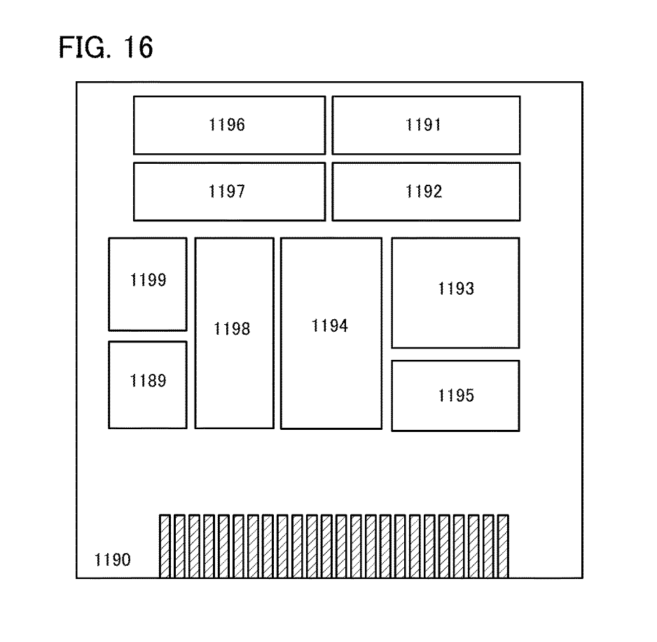

FIG. 16 is a block diagram illustrating a structural example of the CPU including the above memory device.

The CPU illustrated in FIG. 16 includes, over a substrate 1190, an arithmetic logic unit (ALU) 1191, an ALU controller 1192, an instruction decoder 1193, an interrupt controller 1194, a timing controller 1195, a register 1196, a register controller 1197, a bus interface (BUS I/F) 1198, a rewritable ROM 1199, and a ROM interface (ROM I/F) 1189. A semiconductor substrate, an SOI substrate, a glass substrate, or the like is used as the substrate 1190. The ROM 1199 and the ROM interface 1189 may be provided over a separate chip. Needless to say, the CPU in FIG. 16 is just an example in which the structure is simplified, and an actual CPU may have a variety of structures depending on the application. For example, the CPU may have the following structure: a structure including the CPU illustrated in FIG. 16 or an arithmetic circuit is considered as one core; a plurality of such cores are included; and the cores operate in parallel. The number of bits that the CPU can process in an internal arithmetic circuit or in a data bus can be, for example, 8, 16, 32, or 64.

An instruction that is input to the CPU through the bus interface 1198 is input to the instruction decoder 1193 and decoded therein, and then, input to the ALU controller 1192, the interrupt controller 1194, the register controller 1197, and the timing controller 1195.

The ALU controller 1192, the interrupt controller 1194, the register controller 1197, and the timing controller 1195 conduct various controls in accordance with the decoded instruction. Specifically, the ALU controller 1192 generates signals for controlling the operation of the ALU 1191. While the CPU is executing a program, the interrupt controller 1194 processes an interrupt request from an external input/output device or a peripheral circuit depending on its priority or a mask state. The register controller 1197 generates an address of the register 1196, and reads/writes data from/to the register 1196 depending on the state of the CPU.

The timing controller 1195 generates signals for controlling operation timings of the ALU 1191, the ALU controller 1192, the instruction decoder 1193, the interrupt controller 1194, and the register controller 1197. For example, the timing controller 1195 includes an internal clock generator for generating an internal clock signal on the basis of a reference clock signal, and supplies the internal clock signal to the above circuits.

In the CPU illustrated in FIG. 16, a memory cell is provided in the register 1196.

In the CPU illustrated in FIG. 16, the register controller 1197 selects operation of retaining data in the register 1196 in accordance with an instruction from the ALU 1191. That is, the register controller 1197 selects whether data is retained by a flip-flop or by a capacitor in the memory cell included in the register 1196. When data retaining by the flip-flop is selected, a power supply voltage is supplied to the memory cell in the register 1196. When data retaining by the capacitor is selected, the data is rewritten in the capacitor, and supply of the power supply voltage to the memory cell in the register 1196 can be stopped.

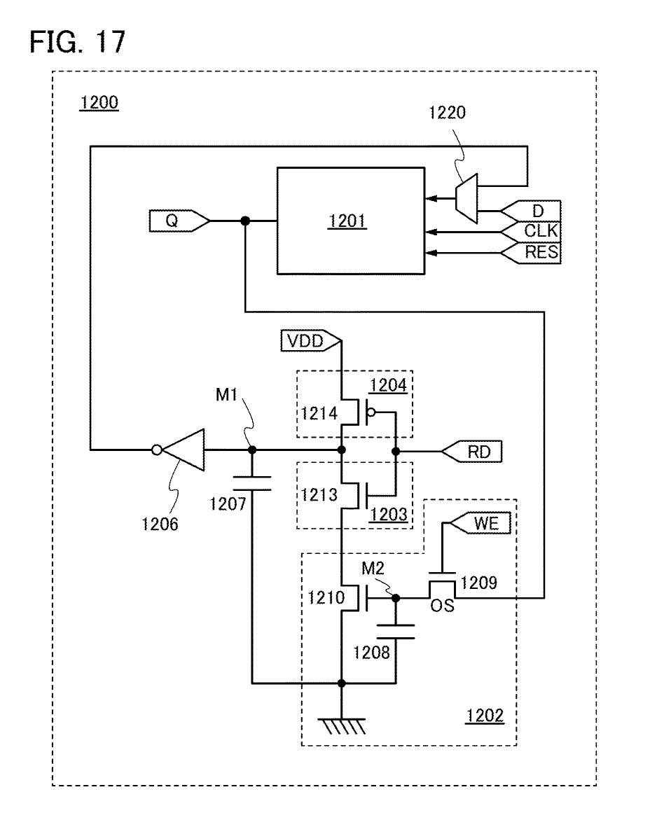

FIG. 17 is an example of a circuit diagram of a memory element that can be used for the register 1196. A memory element 1200 includes a circuit 1201 in which stored data is volatile when power supply is stopped, a circuit 1202 in which stored data is nonvolatile even when power supply is stopped, a switch 1203, a switch 1204, a logic element 1206, a capacitor 1207, and a circuit 1220 having a selecting function. The circuit 1202 includes a capacitor 1208, a transistor 1209, and a transistor 1210. Note that the memory element 1200 may further include another element such as a diode, a resistor, or an inductor, as needed.

Here, the above-described memory device can be used as the circuit 1202. When supply of a power supply voltage to the memory element 1200 is stopped, a ground potential (0 V) or a potential at which the transistor 1209 in the circuit 1202 is turned off continues to be input to a gate of the transistor 1209. For example, the gate of the transistor 1209 is grounded through a load such as a resistor.

Shown here is an example in which the switch 1203 is a transistor 1213 having one conductivity type (e.g., an n-channel transistor) and the switch 1204 is a transistor 1214 having a conductivity type opposite to the one conductivity type (e.g., a p-channel transistor). A first terminal of the switch 1203 corresponds to one of a source and a drain of the transistor 1213, a second terminal of the switch 1203 corresponds to the other of the source and the drain of the transistor 1213, and conduction or non-conduction between the first terminal and the second terminal of the switch 1203 (i.e., the on/off state of the transistor 1213) is selected by a control signal RD input to a gate of the transistor 1213. A first terminal of the switch 1204 corresponds to one of a source and a drain of the transistor 1214, a second terminal of the switch 1204 corresponds to the other of the source and the drain of the transistor 1214, and conduction or non-conduction between the first terminal and the second terminal of the switch 1204 (i.e., the on/off state of the transistor 1214) is selected by the control signal RD input to a gate of the transistor 1214.

One of a source and a drain of the transistor 1209 is electrically connected to one of a pair of electrodes of the capacitor 1208 and a gate of the transistor 1210. Here, the connection portion is referred to as a node M2. One of a source and a drain of the transistor 1210 is electrically connected to a wiring that can supply a low power supply potential (e.g., a GND line), and the other thereof is electrically connected to the first terminal of the switch 1203 (the one of the source and the drain of the transistor 1213). The second terminal of the switch 1203 (the other of the source and the drain of the transistor 1213) is electrically connected to the first terminal of the switch 1204 (the one of the source and the drain of the transistor 1214). The second terminal of the switch 1204 (the other of the source and the drain of the transistor 1214) is electrically connected to a wiring that can supply a power supply potential VDD. The second terminal of the switch 1203 (the other of the source and the drain of the transistor 1213), the first terminal of the switch 1204 (the one of the source and the drain of the transistor 1214), an input terminal of the logic element 1206, and one of a pair of electrodes of the capacitor 1207 are electrically connected to each other. Here, the connection portion is referred to as a node M1. The other of the pair of electrodes of the capacitor 1207 can be supplied with a constant potential. For example, the other of the pair of electrodes of the capacitor 1207 can be supplied with a low power supply potential (e.g., GND) or a high power supply potential (e.g., VDD). The other of the pair of electrodes of the capacitor 1207 is electrically connected to the wiring that can supply a low power supply potential (e.g., a GND line). The other of the pair of electrodes of the capacitor 1208 can be supplied with a constant potential. For example, the other of the pair of electrodes of the capacitor 1208 can be supplied with a low power supply potential (e.g., GND) or a high power supply potential (e.g., VDD). The other of the pair of electrodes of the capacitor 1208 is electrically connected to the wiring that can supply a low power supply potential (e.g., a GND line).

The capacitor 1207 and the capacitor 1208 are not necessarily provided as long as the parasitic capacitance of the transistor, the wiring, or the like is actively utilized.

A control signal WE is input to a first gate (first gate electrode) of the transistor 1209. As for each of the switch 1203 and the switch 1204, a conduction state or a non-conduction state between the first terminal and the second terminal is selected by the control signal RD that is different from the control signal WE. When the first terminal and the second terminal of one of the switches are in the conduction state, the first terminal and the second terminal of the other of the switches are in the non-conduction state.

A signal corresponding to data retained in the circuit 1201 is input to the other of the source and the drain of the transistor 1209. FIG. 17 illustrates an example in which a signal output from the circuit 1201 is input to the other of the source and the drain of the transistor 1209. The logic value of a signal output from the second terminal of the switch 1203 (the other of the source and the drain of the transistor 1213) is inverted by the logic element 1206, and the inverted signal is input to the circuit 1201 through the circuit 1220.

In the example of FIG. 17, a signal output from the second terminal of the switch 1203 (the other of the source and the drain of the transistor 1213) is input to the circuit 1201 through the logic element 1206 and the circuit 1220; however, one embodiment of the present invention is not limited thereto. The signal output from the second terminal of the switch 1203 (the other of the source and the drain of the transistor 1213) may be input to the circuit 1201 without its logic value being inverted. For example, in the case where the circuit 1201 includes a node in which a signal obtained by inversion of the logic value of a signal input from the input terminal is retained, the signal output from the second terminal of the switch 1203 (the other of the source and the drain of the transistor 1213) can be input to the node.

In FIG. 17, the transistors included in the memory element 1200 except for the transistor 1209 can each be a transistor in which a channel is formed in a layer formed using a semiconductor other than an oxide semiconductor or in the substrate 1190. For example, the transistor can be a transistor whose channel is formed in a silicon layer or a silicon substrate. Alternatively, a transistor in which a channel is formed in an oxide semiconductor film can be used for all the transistors in the memory element 1200. Further alternatively, in the memory element 1200, a transistor in which a channel is formed in an oxide semiconductor film can be included besides the transistor 1209, and a transistor in which a channel is formed in a layer formed using a semiconductor other than an oxide semiconductor or the substrate 1190 can be used for the rest of the transistors.

As the circuit 1201 in FIG. 17, for example, a flip-flop circuit can be used. As the logic element 1206, for example, an inverter or a clocked inverter can be used.

In a period during which the memory element 1200 is not supplied with the power supply voltage, the semiconductor device described in this embodiment can retain data stored in the circuit 1201 by the capacitor 1208 that is provided in the circuit 1202.

The off-state current of a transistor in which a channel is formed in an oxide semiconductor film is extremely small. For example, the off-state current of a transistor in which a channel is formed in an oxide semiconductor film is significantly smaller than that of a transistor in which a channel is formed in silicon having crystallinity. Thus, when the transistor in which a channel is formed in an oxide semiconductor film is used as the transistor 1209, a signal is retained in the capacitor 1208 for a long time also in a period during which the power supply voltage is not supplied to the memory element 1200. The memory element 1200 can accordingly retain the stored content (data) also in a period during which the supply of the power supply voltage is stopped.

Since the memory element performs pre-charge operation with the switch 1203 and the switch 1204, the time required for the circuit 1201 to retain original data again after the supply of the power supply voltage is restarted can be shortened.

In the circuit 1202, a signal retained by the capacitor 1208 is input to the gate of the transistor 1210. Thus, after supply of the power supply voltage to the memory element 1200 is restarted, the state (the on state or the off state) of the transistor 1210 is determined in accordance with the signal retained by the capacitor 1208 and can be read from the circuit 1202. Consequently, an original signal can be accurately read even when a potential corresponding to the signal retained by the capacitor 1208 changes to some degree.

By using the above-described memory element 1200 in a memory device such as a register or a cache memory included in a processor, data in the memory device can be prevented from being lost owing to the stop of the supply of the power supply voltage. Furthermore, shortly after the supply of the power supply voltage is restarted, the memory device can be returned to the same state as that before the power supply is stopped. Thus, the power supply can be stopped even for a short time in the processor or one or a plurality of logic circuits included in the processor, resulting in lower power consumption.

Although the memory element 1200 is used in a CPU in this embodiment, the memory element 1200 can also be used in an LSI such as a digital signal processor (DSP), a custom LSI, or a programmable logic device (PLD), and a radio frequency identification (RF-ID) tag.

At least part of this embodiment can be implemented in combination with any of the other embodiments described in this specification as appropriate.

### Embodiment 6

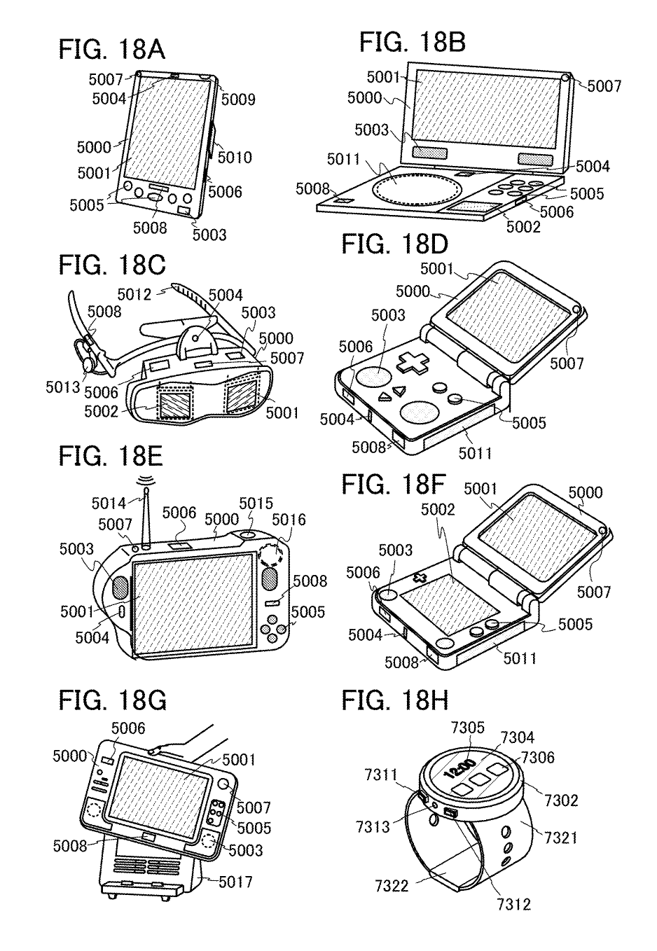

In this embodiment, a display module and electronic devices that include a display panel of one embodiment of the present invention are described with reference to FIGS. 18A to 18H.

FIGS. 18A to 18G illustrate electronic devices. These electronic devices can include a housing 5000, a display portion 5001, a speaker 5003, an LED lamp 5004, operation keys 5005 (including a power switch and an operation switch), a connection terminal 5006, a sensor 5007 (a sensor having a function of measuring force, displacement, position, speed, acceleration, angular velocity, rotational frequency, distance, light, liquid, magnetism, temperature, chemical substance, sound, time, hardness, electric field, current, voltage, electric power, radiation, flow rate, humidity, gradient, oscillation, odor, or infrared ray), a microphone 5008, and the like.

FIG. 18A illustrates a mobile computer that can include a switch 5009, an infrared port 5010, and the like in addition to the above components. FIG. 18B illustrates a portable image reproducing device (e.g., a DVD reproducing device) provided with a recording medium, and the portable image reproducing device can include a second display portion 5002, a recording medium reading portion 5011, and the like in addition to the above components. FIG. 18C illustrates a goggle-type display that can include the second display portion 5002, a support portion 5012, an earphone 5013, and the like in addition to the above components. FIG. 18D illustrates a portable game console that can include the recording medium reading portion 5011 and the like in addition to the above components. FIG. 18E illustrates a digital camera with a television reception function, and the digital camera can include an antenna 5014, a shutter button 5015, an image receiving portion 5016, and the like in addition to the above components. FIG. 18F illustrates a portable game console that can include the second display portion 5002, the recording medium reading portion 5011, and the like in addition to the above components. FIG. 18G illustrates a portable television receiver that can include a charger 5017 capable of transmitting and receiving signals, and the like in addition to the above components.

The electronic devices in FIGS. 18A to 18G can have a variety of functions such as a function of displaying a variety of data (e.g., a still image, a moving image, and a text image) on the display portion, a touch panel function, a function of displaying a calendar, date, time, and the like, a function of controlling processing with a variety of software (programs), a wireless communication function, a function of being connected to a variety of computer networks with a wireless communication function, a function of transmitting and receiving a variety of data with a wireless communication function, and a function of reading out a program or data stored in a recording medium and displaying it on the display portion. Furthermore, the electronic device including a plurality of display portions can have a function of displaying image data mainly on one display portion while displaying text data mainly on another display portion, a function of displaying a three-dimensional image by displaying images on a plurality of display portions with a parallax taken into account, or the like. Furthermore, the electronic device including an image receiving portion can have a function of shooting a still image, a function of taking moving images, a function of automatically or manually correcting a shot image, a function of storing a shot image in a recording medium (an external recording medium or a recording medium incorporated in the camera), a function of displaying a shot image on the display portion, or the like. Note that functions of the electronic devices in FIGS. 18A to 18G are not limited thereto, and the electronic devices can have a variety of functions.

FIG. 18H illustrates a smart watch, which includes a housing 7302, a display panel 7304, operation buttons 7311 and 7312, a connection terminal 7313, a band 7321, a clasp 7322, and the like.

The display panel 7304 mounted in the housing 7302 serving as a bezel includes a non-rectangular display region. The display panel 7304 may have a rectangular display region. The display panel 7304 can display an icon 7305 indicating time, another icon 7306, and the like.

The smart watch in FIG. 18H can have a variety of functions such as a function of displaying a variety of data (e.g., a still image, a moving image, and a text image) on the display portion, a touch panel function, a function of displaying a calendar, date, time, and the like, a function of controlling processing with a variety of software (programs), a wireless communication function, a function of being connected to a variety of computer networks with a wireless communication function, a function of transmitting and receiving a variety of data with a wireless communication function, and a function of reading out a program or data stored in a recording medium and displaying it on the display portion.

The housing 7302 can include a speaker, a sensor (a sensor having a function of measuring force, displacement, position, speed, acceleration, angular velocity, rotational frequency, distance, light, liquid, magnetism, temperature, chemical substance, sound, time, hardness, electric field, current, voltage, electric power, radiation, flow rate, humidity, gradient, oscillation, odor, or infrared rays), a microphone, and the like. Note that the smart watch can be manufactured using the light-emitting element for the display panel 7304.

This embodiment can be combined with any of the other embodiments in this specification as appropriate.

For example, in this specification and the like, an explicit description “X and Y are connected” means that X and Y are electrically connected, X and Y are functionally connected, and X and Y are directly connected. Accordingly, without being limited to a predetermined connection relationship, for example, a connection relationship shown in drawings or texts, another connection relationship is included in the drawings or the texts.

Here, X and Y each denote an object (e.g., a device, an element, a circuit, a wiring, an electrode, a terminal, a conductive film, or a layer).

Examples of the case where X and Y are directly connected include the case where an element that allows an electrical connection between X and Y (e.g., a switch, a transistor, a capacitor, an inductor, a resistor, a diode, a display element, a light-emitting element, or a load) is not connected between X and Y, and the case where X and Y are connected without the element that allows the electrical connection between X and Y provided therebetween.

For example, in the case where X and Y are electrically connected, one or more elements that enable an electrical connection between X and Y (e.g., a switch, a transistor, a capacitor, an inductor, a resistor, a diode, a display element, a light-emitting element, or a load) can be connected between X and Y. Note that the switch is controlled to be turned on or off. That is, the switch is conducting or not conducting (is turned on or off) to determine whether current flows therethrough or not. Alternatively, the switch has a function of selecting and changing a current path. Note that the case where X and Y are electrically connected includes the case where X and Y are directly connected.

For example, in the case where X and Y are functionally connected, one or more circuits that enable a functional connection between X and Y (e.g., a logic circuit such as an inverter, a NAND circuit, or a NOR circuit; a signal converter circuit such as a D/A converter circuit, an A/D converter circuit, or a gamma correction circuit; a potential level converter circuit such as a power supply circuit (e.g., a step-up circuit or a step-down circuit) or a level shifter circuit for changing the potential level of a signal; a voltage source; a current source; a switching circuit; an amplifier circuit such as a circuit that can increase signal amplitude, the amount of current, or the like, an operational amplifier, a differential amplifier circuit, a source follower circuit, and a buffer circuit; a signal generation circuit; a memory circuit; or a control circuit) can be connected between X and Y. For example, even when another circuit is interposed between X and Y, X and Y are functionally connected if a signal output from X is transmitted to Y. Note that the case where X and Y are functionally connected includes the case where X and Y are directly connected and the case where X and Y are electrically connected.

Note that in this specification and the like, an explicit description “X and Y are electrically connected” means that X and Y are electrically connected (i.e., the case where X and Y are connected with another element or another circuit provided therebetween), X and Y are functionally connected (i.e., the case where X and Y are functionally connected with another circuit provided therebetween), and X and Y are directly connected (i.e., the case where X and Y are connected without another element or another circuit provided therebetween). That is, in this specification and the like, the explicit description “X and Y are electrically connected” is the same as the description “X and Y are connected”.

For example, any of the following expressions can be used for the case where a source (or a first terminal or the like) of a transistor is electrically connected to X through (or not through) Z1 and a drain (or a second terminal or the like) of the transistor is electrically connected to Y through (or not through) Z2, or the case where a source (or a first terminal or the like) of a transistor is directly connected to one part of Z1 and another part of Z1 is directly connected to X while a drain (or a second terminal or the like) of the transistor is directly connected to one part of Z2 and another part of Z2 is directly connected to Y.

Examples of the expressions include, “X, Y, a source (or a first terminal or the like) of a transistor, and a drain (or a second terminal or the like) of the transistor are electrically connected to each other, and X, the source (or the first terminal or the like) of the transistor, the drain (or the second terminal or the like) of the transistor, and Y are electrically connected to each other in this order”, “a source (or a first terminal or the like) of a transistor is electrically connected to X, a drain (or a second terminal or the like) of the transistor is electrically connected to Y, and X, the source (or the first terminal or the like) of the transistor, the drain (or the second terminal or the like) of the transistor, and Y are electrically connected to each other in this order”, and “X is electrically connected to Y through a source (or a first terminal or the like) and a drain (or a second terminal or the like) of a transistor, and X, the source (or the first terminal or the like) of the transistor, the drain (or the second terminal or the like) of the transistor, and Y are provided to be connected in this order”. When the connection order in a circuit configuration is defined by an expression similar to the above examples, a source (or a first terminal or the like) and a drain (or a second terminal or the like) of a transistor can be distinguished from each other to specify the technical scope.

Other examples of the expressions include, “a source (or a first terminal or the like) of a transistor is electrically connected to X through at least a first connection path, the first connection path does not include a second connection path, the second connection path is a path between the source (or the first terminal or the like) of the transistor and a drain (or a second terminal or the like) of the transistor, Z1 is on the first connection path, the drain (or the second terminal or the like) of the transistor is electrically connected to Y through at least a third connection path, the third connection path does not include the second connection path, and Z2 is on the third connection path” and “a source (or a first terminal or the like) of a transistor is electrically connected to X at least with a first connection path through Z1, the first connection path does not include a second connection path, the second connection path includes a connection path through which the transistor is provided, a drain (or a second terminal or the like) of the transistor is electrically connected to Y at least with a third connection path through Z2, and the third connection path does not include the second connection path.” Still another example of the expression is “a source (or a first terminal or the like) of a transistor is electrically connected to X through at least Z1 on a first electrical path, the first electrical path does not include a second electrical path, the second electrical path is an electrical path from the source (or the first terminal or the like) of the transistor to a drain (or a second terminal or the like) of the transistor, the drain (or the second terminal or the like) of the transistor is electrically connected to Y through at least Z2 on a third electrical path, the third electrical path does not include a fourth electrical path, and the fourth electrical path is an electrical path from the drain (or the second terminal or the like) of the transistor to the source (or the first terminal or the like) of the transistor”. When the connection path in a circuit structure is defined by an expression similar to the above examples, a source (or a first terminal or the like) and a drain (or a second terminal or the like) of a transistor can be distinguished from each other to specify the technical scope.

Note that these expressions are examples and there is no limitation on the expressions. Here, X, Y, Z1, and Z2 each denote an object (e.g., a device, an element, a circuit, a wiring, an electrode, a terminal, a conductive film, and a layer).

Even when independent components are electrically connected to each other in a circuit diagram, one component has functions of a plurality of components in some cases. For example, when part of a wiring also functions as an electrode, one conductive film functions as the wiring and the electrode. Thus, “electrical connection” in this specification includes in its category such a case where one conductive film has functions of a plurality of components.

### EXPLANATION OF REFERENCE

AF1: alignment film, AF2: alignment film, ANO: wiring, BR: conductive film, C1: capacitor, C2: capacitor, CF1: coloring film, C(g): electrode, CL(g): control line, CSCOM: wiring, DC: detection circuit, FPC1: flexible printed circuit, FPC2: flexible printed circuit, GD: driver circuit, GDA: driver circuit, GDB: driver circuit, G1: scan line, G2: scan line, KB1: structure body, M1: node, M2: node, ME: transistor, MF: transistor, MDE: transistor, MDF: transistor, M(h): electrode, ML(h): signal line, OSC: oscillator circuit, P1: positional data, P2: data, S1(j): signal line, S2(j): signal line, SD: driver circuit, SW1: switch, SW2: switch, V1: image data, VCOM1: wiring, VCOM2: wiring, 100: transistor, 102: substrate, 104: conductive film, 106: insulating film, 107: insulating film, 108: oxide semiconductor film, 108a: oxide semiconductor film, 108b: oxide semiconductor film, 108c: oxide semiconductor film, 112a: conductive film, 112b: conductive film, 114: insulating film, 116: insulating film, 118: insulating film, 120a: conductive film, 120b: conductive film, 150: transistor, 200: data processing device, 210: arithmetic device, 211: arithmetic portion, 212: memory portion, 214: transmission path, 215: input/output interface, 220: input/output device, 230: display portion, 230B: display portion, 231: display region, 232: pixel, 235EL: display element, 235LC: display element, 240: input portion, 250: sensor portion, 290: communication portion, 501C: insulating film, 504: conductive film, 505: bonding layer, 506: insulating film, 508: semiconductor film, 508A: region, 508B: region, 508C: region, 511C: conductive film, 511D: conductive film, 511E: conductive film, 512A: conductive film, 512B: conductive film, 516: insulating film, 518: insulating film, 519B: terminal, 519C: terminal, 519D: terminal, 520: functional layer, 521: insulating film, 522: contact portion, 524: conductive film, 528: insulating film, 530: pixel circuit, 550: display element, 551: electrode, 552: electrode, 553: layer, 570: substrate, 591A: opening, 591B: opening, 591C: opening, 591E: opening, 604: conductive film, 606: insulating film, 608: semiconductor film, 608A: region, 608B: region, 608C: region, 611B: conductive film, 611E: conductive film, 612A: conductive film, 612B: conductive film, 620: functional layer, 621: insulating film, 627A: conductive film, 627B: conductive film, 627C: conductive film, 627E: conductive film, 691E: opening, 700TPE: input/output device, 700TPF: input/output device, 702: pixel, 705: sealant, 706: insulating film, 709: bonding layer, 710: substrate, 719: terminal, 720: functional layer, 750: display element, 751: electrode, 751H: opening, 752: electrode, 753: layer, 760: functional layer, 770: substrate, 770D: functional film, 770P: functional film, 771: insulating film, 775: sensing element, 1189: ROM interface, 1190: substrate, 1191: ALU, 1192: ALU controller, 1193: instruction decoder, 1194: interrupt controller, 1195: timing controller, 1196: register, 1197: register controller, 1198: bus interface, 1199: ROM, 1200: memory element, 1201: circuit, 1202: circuit, 1203: switch, 1204: switch, 1206: logic element, 1207: capacitor, 1208: capacitor, 1209: transistor, 1210: transistor, 1213: transistor, 1214: transistor, 1220: circuit, 3001: wiring, 3002: wiring, 3003: wiring, 3004: wiring, 3005: wiring, 3200: transistor, 3300: transistor, 3400: capacitor, 5000: housing, 5001: display portion, 5002: display portion, 5003: speaker, 5004: LED lamp, 5005: operation keys, 5006: connection terminal, 5007: sensor, 5008: microphone, 5009: switch, 5010: infrared port, 5011: recording medium reading portion, 5012: support portion, 5013: earphone, 5014: antenna, 5015: shutter button, 5016: image receiving portion, 5017: charger, 7302: housing, 7304: display panel, 7305: icon, 7306: icon, 7311: operation button, 7312: operation button, 7313: connection terminal, 7321: band, 7322: clasp.

This application is based on Japanese Patent Application serial no. 2015-223025 filed with Japan Patent Office on Nov. 13, 2015, the entire contents of which are hereby incorporated by reference.

1. A display device comprising:
a signal line;
a pixel electrically connected to the signal line;
a first conductive film electrically connected to the signal line;
a second conductive film comprising a region overlapping with the first conductive film; and
a first insulating film provided between the first conductive film and the second conductive film,
wherein the first insulating film comprises a second opening,
wherein the second conductive film is electrically connected to the first conductive film through the second opening,
wherein the pixel comprises a pixel circuit, a third conductive film, a fourth conductive film, a second insulating film, a first display element, and a second display element,
wherein the pixel circuit is electrically connected to the signal line, the third conductive film, and the second display element,
wherein the third conductive film and the fourth conductive film overlap with each other with the second insulating film interposed therebetween,
wherein the second insulating film comprises an opening,
wherein the third conductive film is electrically connected to the fourth conductive film through the opening, and
wherein the first display element is electrically connected to the fourth conductive film.

2. The display device according to claim 1, further comprising a first transistor comprising a first semiconductor film and a second transistor comprising a second semiconductor film,
wherein the first insulating film is provided between the first transistor and the second transistor,
wherein the first transistor is electrically connected to the first conductive film,
wherein the second transistor is electrically connected to the second conductive film, and
wherein the second semiconductor film is different from the first semiconductor film.

3. The display device according to claim 2, wherein the second transistor comprises a region overlapping with the first transistor.

4. The display device according to claim 1, further comprising:
a first plurality of pixels;
a second plurality of pixels; and
a scan line,
wherein the first plurality of pixels comprise the pixel,
wherein the first plurality of pixels are provided in a row direction,
wherein the second plurality of pixels are provided in a column direction,
wherein the scan line is electrically connected to the first plurality of pixels, and
wherein the second plurality of pixels are electrically connected to the signal line.

5. The display device according to claim 4, further comprising a driver circuit comprising a transistor,
wherein the driver circuit is electrically connected to the scan line,
wherein the driver circuit is configured to supply a selection signal, and
wherein the transistor comprises silicon in a semiconductor film.

6. The display device according to claim 1,
wherein the second display element is provided so that display using the second display element can be seen from part of a region from which display using the first display element can be seen.

7. The display device according to claim 1,
wherein the second display element is configured to perform display in a region surrounded by a region where the first display element performs display.

8. The display device according to claim 1,
wherein the second display element is configured to emit light toward the second insulating film and the first insulating film,
wherein the first display element comprises a reflective film and is configured to control the intensity of reflected light,
wherein the reflective film is configured to reflect incident light, and
wherein the reflective film has a shape comprising a region that does not block light emitted from the second display element.

9. An input/output device comprising:
the display device according to claim 1; and
an input portion,
wherein the input portion comprises a region overlapping with the display device,
wherein the input portion is configured to sense an object that comes in the vicinity of the region overlapping with the display device,
wherein the input portion comprises a control line, a signal line, and a sensing element,
wherein the control line extends in a row direction,
wherein the signal line extends in a column direction,
wherein the sensing element has a light-transmitting property,
wherein the sensing element comprises an electrode electrically connected to the control line and an electrode electrically connected to the signal line, and
wherein the electrode electrically connected to the signal line is provided so that an electric field part of which is blocked by the object that comes in the vicinity of the region overlapping with the display device is generated between the electrode electrically connected to the signal line and the electrode electrically connected to the control line.

10. The input/output device according to claim 9,
wherein the electrode electrically connected to the control line comprises a light-transmitting conductive film comprising a region overlapping with the pixel, and
wherein the electrode electrically connected to the signal line comprises a light-transmitting conductive film comprising a region overlapping with the pixel.

11. The input/output device according to claim 9,
wherein the electrode electrically connected to the control line comprises a conductive film provided with an opening comprising a region overlapping with the pixel,
wherein the electrode electrically connected to the signal line comprises a conductive film provided with an opening comprising a region overlapping with the pixel,
wherein the first display element comprises a first electrode and a second electrode,
wherein the first electrode is electrically connected to the fourth conductive film, and
wherein a gap between the electrode electrically connected to the control line and the second electrode or between the electrode electrically connected to the signal line and the second electrode is more than or equal to 0.2 μm and less than or equal to 16 μm.

12. The input/output device according to claim 10, further comprising:
a first film; and
a second film,
wherein the first film comprises a region that overlaps with the first display element with the sensing element positioned therebetween,
wherein the first film comprises a circular polarizing film,
wherein the second film comprises a region positioned between the first film and the first display element, and
wherein the second film comprises a light diffusion film.

13. A data processing device comprising:
at least one of a keyboard, a hardware button, a pointing device, a touch sensor, an illuminance sensor, an imaging device, an audio input device, a viewpoint input device, and an attitude determination device; and
the input/output device according to claim 10.

14. A display device comprising:
a pixel comprising a pixel circuit, a first display element, and a second display element;
a signal line electrically connected to the pixel circuit;
a first conductive film electrically connected to the signal line and a first transistor;
a second conductive film comprising a region overlapping with the first conductive film; and
a first insulating film provided between the first conductive film and the second conductive film,
wherein the first insulating film comprises a second opening,
wherein the second conductive film is electrically connected to the first conductive film through the second opening,
wherein the first display element is provided over the first insulating film, and
wherein the first insulating film is provided over the second display element.

15. The display device according to claim 14, further comprising the first transistor comprising a first semiconductor film and a second transistor comprising a second semiconductor film,
wherein the first insulating film is provided between the first transistor and the second transistor,
wherein the first transistor is electrically connected to the first conductive film, and
wherein the second transistor is electrically connected to the second conductive film.

16. The display device according to claim 15, wherein a material included in the second semiconductor film is different from a material included in the first semiconductor film.

17. The display device according to claim 15, wherein the first transistor and the second transistor overlap with each other.

18. The display device according to claim 14, further comprising:
a first plurality of pixels;
a second plurality of pixels; and
a scan line,
wherein the first plurality of pixels comprise the pixel,
wherein the first plurality of pixels are provided in a row direction,
wherein the second plurality of pixels are provided in a column direction,
wherein the scan line is electrically connected to the first plurality of pixels, and
wherein the second plurality of pixels are electrically connected to the signal line.

19. The display device according to claim 18, further comprising a driver circuit comprising a transistor,
wherein the driver circuit is electrically connected to the scan line,
wherein the driver circuit is configured to supply a selection signal, and
wherein the transistor comprises silicon in a semiconductor film.

20. The display device according to claim 14,
wherein the second display element is provided so that display using the second display element can be seen from part of a region from which display using the first display element can be seen.

21. The display device according to claim 14,
wherein the second display element is configured to perform display in a region surrounded by a region where the first display element performs display.

22. The display device according to claim 14,
wherein the second display element is configured to emit light toward the first insulating film,
wherein the first display element comprises a reflective film and is configured to control the intensity of reflected light,
wherein the reflective film is configured to reflect incident light, and
wherein the reflective film has a shape comprising a region that does not block light emitted from the second display element.

23. An input/output device comprising:
the display device according to claim 14; and
an input portion,
wherein the input portion comprises a region overlapping with the display device,
wherein the input portion is configured to sense an object that comes in the vicinity of the region overlapping with the display device,
wherein the input portion comprises a control line, a signal line, and a sensing element,
wherein the control line extends in a row direction,
wherein the signal line extends in a column direction that intersects the row direction,
wherein the sensing element has a light-transmitting property,
wherein the sensing element comprises an electrode electrically connected to the control line and an electrode electrically connected to the signal line, and
wherein the electrode electrically connected to the signal line is provided so that an electric field part of which is blocked by the object that comes in the vicinity of the region overlapping with the display device is generated between the electrode electrically connected to the signal line and the electrode electrically connected to the control line.

24. The input/output device according to claim 23,
wherein the electrode electrically connected to the control line comprises a light-transmitting conductive film comprising a region overlapping with the pixel, and
wherein the electrode electrically connected to the signal line comprises a light-transmitting conductive film comprising a region overlapping with the pixel.

25. The input/output device according to claim 23,
wherein the electrode electrically connected to the control line comprises a conductive film provided with an opening comprising a region overlapping with the pixel,
wherein the electrode electrically connected to the signal line comprises a conductive film provided with an opening comprising a region overlapping with the pixel,
wherein the first display element comprises a first electrode and a second electrode, and
wherein a gap between the electrode electrically connected to the control line and the second electrode or between the electrode electrically connected to the signal line and the second electrode is more than or equal to 0.2 μm and less than or equal to 16 μm.

26. The input/output device according to claim 24, further comprising:
a first film; and
a second film,
wherein the first film comprises a region that overlaps with the first display element with the sensing element positioned therebetween,
wherein the first film comprises a circular polarizing film,
wherein the second film comprises a region positioned between the first film and the first display element, and
wherein the second film comprises a light diffusion film.

27. A data processing device comprising:
at least one of a keyboard, a hardware button, a pointing device, a touch sensor, an illuminance sensor, an imaging device, an audio input device, a viewpoint input device, and an attitude determination device; and
the input/output device according to claim 23.
